(19) United States
(12) Patent Application Publication
(10) Pub. No.: US 2026/0231609 A1
(43) Pub. Date: Aug. 6, 2026

(54) METHOD FOR MANUFACTURING DISPLAY DEVICE

(71) Applicant: Semiconductor Energy Laboratory Co., Ltd., Atsugi-shi (JP)

(72) Inventors: Yasutaka NAKAZAWA, Tochigi (JP); Rai SATO, Tochigi (JP); Satoru IDOJIRI, Tochigi (JP); Kenichi OKAZAKI, Atsugi (JP); Shingo EGUCHI, Atsugi (JP); Sachiko KAWAKAMI, Atsugi (JP); Nobuharu OHSAWA, Zama (JP); Shunpei YAMAZAKI, Setagaya (JP)

(21) Appl. No.: 19/462,176

(22) Filed: Jan. 28, 2026

(30) Foreign Application Priority Data
Feb. 6, 2025 (JP) 2025-018673
Feb. 6, 2025 (JP) 2025-018751
Nov. 25, 2025 (JP) 2025-202873

(51) Int. Cl. H10K 59/12; H10K 59/122; H10K 71/00

(52) U.S. Cl. CPC H10K 59/1201; H10K 59/122; H10K 71/621

(57) ABSTRACT

A display device that can easily achieve higher resolution is provided. A display device having high display quality and high resolution is provided. A display device with high contrast is provided. A highly reliable display device is provided. The display device is manufactured in the following manner: a first pixel electrode and a second pixel electrode are formed over a substrate; an insulating layer is formed between the first pixel electrode and the second pixel electrode; a conductive film is formed over the first pixel electrode, the second pixel electrode, and the insulating layer; a first side surface of the conductive film is formed by removing a portion of the conductive film overlapping with the first pixel electrode; a first organic compound layer is formed over the first pixel electrode and the conductive film; a sacrificial layer is formed over the first organic compound layer; a second side surface of the conductive film is formed by removing a portion of the conductive film overlapping with the second pixel electrode; a second organic compound layer is formed over the sacrificial layer and the second pixel electrode; the sacrificial layer is removed; and an upper electrode is formed over the first organic compound layer and the second organic compound layer to be in contact with the first side surface and the second side surface.

### BACKGROUND OF THE INVENTION

### 1. Field of the Invention

One embodiment of the present invention relates to a display device. One embodiment of the present invention relates to a method for manufacturing a display device.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device generally means a device that can function by utilizing semiconductor characteristics.

### 2. Description of the Related Art

In recent years, higher-resolution display panels have been required. Examples of devices that require high-resolution display panels include a smartphone, a tablet terminal, and a laptop computer. Furthermore, higher resolution has been required for a stationary display device such as a television device or a monitor device along with an increase in definition. A device absolutely required to have the highest resolution display panel is a device for virtual reality (VR) or augmented reality (AR).

Examples of the display device that can be used for a display panel include, typically, a liquid crystal display device, a light-emitting apparatus including a light-emitting element such as an organic electroluminescent (EL) element or a light-emitting diode (LED), and electronic paper performing display by an electrophoretic method or the like.

The organic EL element generally has a structure in which a layer containing a light-emitting organic compound is provided between a pair of electrodes. By voltage application to this element, light emission can be obtained from the light-emitting organic compound. A display device using such an organic EL element does not need a backlight that is necessary for a liquid crystal display device or the like; thus, a thin, lightweight, high-contrast, and low-power-consumption display device can be achieved. Patent Document 1, for example, discloses an example of a display device using an organic EL element.

A method using a metal mask is known as a method for separately forming organic EL elements but has problems with an aperture ratio, a resolution, and an increase in the substrate area, and the like. Patent Document 2 discloses a method for separately forming organic EL elements by a photolithography method without using a metal mask.

### REFERENCES

[Patent Document 1] Japanese Published Patent Application No. 2002-324673
[Patent Document 2] PCT International Publication No. 2023/285907

### SUMMARY OF THE INVENTION

An object of one embodiment of the present invention is to provide a display device that can easily achieve higher resolution and a method for manufacturing the display device. An object of one embodiment of the present invention is to provide a display device having both high display quality and high resolution. An object of one embodiment of the present invention is to provide a display device with high contrast. An object of one embodiment of the present invention is to provide a highly reliable display device.

An object of one embodiment of the present invention is to provide a display device having a novel structure or a method for manufacturing the display device. An object of one embodiment of the present invention is to provide a method for manufacturing the above display device with high yield. An object of one embodiment of the present invention is to at least alleviate at least one of problems in the conventional art.

One embodiment of the present invention is a method for manufacturing a display device, including formation of a first pixel electrode and a second pixel electrode over a substrate; formation of an insulating layer between the first pixel electrode and the second pixel electrode; formation of a conductive film over the first pixel electrode, the second pixel electrode, and the insulating layer; removal of a portion of the conductive film overlapping with the first pixel electrode to form a first side surface of the conductive film; formation of a first organic compound layer over the first pixel electrode and the conductive film; formation of a sacrificial layer over the first organic compound layer; removal of a portion of the conductive film overlapping with the second pixel electrode to form a second side surface of the conductive film; formation of a second organic compound layer over the sacrificial layer and the second pixel electrode; removal of the sacrificial layer; and formation of an upper electrode over the first organic compound layer and the second organic compound layer to be in contact with the first side surface and the second side surface.

In the above embodiment, preferably, the first side surface and the second side surface are formed by etching the conductive film by a wet etching method; and an etching rate of the conductive film is higher in a lower portion than in an upper portion of the conductive film.

In the above embodiment, preferably, the first side surface formed over the insulating layer has an angle greater than or equal to 105° and less than or equal to 175° with respect to a top surface of the insulating layer.

In the above embodiment, preferably, the conductive film contains indium and oxygen.

In the above embodiment, preferably, force required for separation of a material used for the conductive film from a material used for the insulating layer is lower than 8 N.

In the above embodiment, preferably, the conductive film has a larger thickness than at least one of the first organic compound layer and the second organic compound layer.

In the above embodiment, preferably, the first organic compound layer is formed by a first material traveling with a first angle with respect to a perpendicular direction to a formation surface of the substrate; the upper electrode is formed by a second material traveling with a second angle with respect to the perpendicular direction; the first angle is greater than or equal to 0°; and the second angle is larger than the first angle.

In the above embodiment, preferably, the first material travels from an evaporation source; and a direction and a position of the evaporation source with respect to the substrate are determined so that the first material travels from the evaporation source with the first angle with respect to the perpendicular direction.

Another embodiment of the present invention is a method for manufacturing a display device, including formation of a first pixel electrode and a second pixel electrode over a substrate; formation of an insulating layer between the first pixel electrode and the second pixel electrode; formation of a conductive film over the first pixel electrode, the second pixel electrode, and the insulating layer; removal of a portion of the conductive film overlapping with the first pixel electrode to form a first side surface of the conductive film; formation of a first organic compound layer over the first pixel electrode and the conductive film; formation of a sacrificial layer over the first organic compound layer; removal of a portion of the conductive film overlapping with the second pixel electrode to form a second side surface of the conductive film; formation of a second organic compound layer over the sacrificial layer and the second pixel electrode; removal of the sacrificial layer; formation of a third organic compound layer over the first organic compound layer and the second organic compound layer; and formation of an upper electrode over the third organic compound layer to be in contact with the first side surface and the second side surface.

In the above embodiment, preferably, the first side surface and the second side surface are formed by etching the conductive film by a wet etching method; and an etching rate of the conductive film is higher in a lower portion than in an upper portion of the conductive film.

In the above embodiment, preferably, the first side surface formed over the insulating layer has an angle greater than or equal to 105° and less than or equal to 175° with respect to a top surface of the insulating layer.

In the above embodiment, preferably, the conductive film contains indium and oxygen.

In the above embodiment, preferably, force required for separation of a material used for the conductive film from a material used for the insulating layer is lower than 8 N.

In the above embodiment, preferably, the conductive film has a larger thickness than at least one of the first organic compound layer and the second organic compound layer.

In the above embodiment, preferably, the first organic compound layer is formed by a first material traveling with a first angle with respect to a perpendicular direction to a formation surface of the substrate; the third organic compound layer is formed by a second material traveling with a second angle with respect to the perpendicular direction; the upper electrode is formed by a third material traveling with a third angle with respect to the perpendicular direction; the first angle is greater than or equal to 0°; the second angle is larger than the first angle; and the third angle is larger than the second angle.

According to one embodiment of the present invention, a display device that can easily achieve higher resolution and a method for manufacturing the display device can be provided. A display device having both high display quality and high resolution can be provided. A display device with high contrast can be provided. A highly reliable display device can be provided.

According to one embodiment of the present invention, a display device having a novel structure or a method for manufacturing the display device can be provided. A method for manufacturing the above display device with high yield can be provided. According to one embodiment of the present invention, at least one of problems in the conventional art can be at least alleviated.

Note that the description of these effects does not preclude the existence of other effects. One embodiment of the present invention does not necessarily have all these effects. Effects other than these can be derived from the description of the specification, the drawings, the claims, and the like.

### BRIEF DESCRIPTION OF THE DRAWINGS

In the accompanying drawings:

FIGS. 1A and 1B show structure examples of a display device;

FIGS. 2A to 2D show structure examples of a display device;

FIGS. 3A to 3D show structure examples of a display device;

FIGS. 4A to 4I show structure examples of a display device;

FIGS. 5A to 5D show structure examples of a display device;

FIG. 6 shows a structure example of a display device;

FIGS. 7A to 7C show structure examples of a display device;

FIGS. 8A to 8C show structure examples of a display device;

FIGS. 9A to 9F show an example of a method for manufacturing a display device;

FIGS. 10A to 10C show an example of a method for manufacturing a display device;

FIGS. 11A and 11B show an example of a method for manufacturing a display device;

FIGS. 12A to 12D show an example of a method for manufacturing a display device;

FIGS. 13A to 13C show an example of a method for manufacturing a display device;

FIGS. 14A to 14C show an example of a method for manufacturing a display device;

FIGS. 15A to 15C show an example of a method for manufacturing a display device;

FIGS. 16A to 16C show an example of a method for manufacturing a display device;

FIGS. 17A and 17B show an example of a method for manufacturing a display device;

FIGS. 18A and 18B show an example of a method for manufacturing a display device;

FIG. 19 shows an example of a method for manufacturing a display device;

FIGS. 20A and 20B show an example of a method for manufacturing a display device;

FIGS. 21A to 21E show an example of a method for manufacturing a display device;

FIGS. 22A and 22B show structure examples of a manufacturing apparatus for a display device;

FIG. 23A shows a structure example of a manufacturing apparatus for a display device, and FIG. 23B shows a structure example of a display device;

FIG. 24 shows a structure example of a display device;

FIG. 25 shows a structure example of a display device;

FIG. 26 shows a structure example of a display device;

FIGS. 27A to 27D show structure examples of a display device;

FIG. 28 shows a structure example of a display device;

FIGS. 29A and 29B show a structure example of a display device;

FIG. 30 shows a structure example of a display device;

FIGS. 31A and 31B show structure examples of a display device;

FIG. 32 shows a structure example of a display device;

FIG. 33 shows a structure example of a display device;

FIGS. 34A to 34F show structure examples of a light-emitting device;

FIGS. 35A to 35C show structure examples of a light-emitting device;

FIGS. 36A to 36D show structure examples of an electronic device;

FIGS. 37A to 37F show structure examples of an electronic device;

FIGS. 38A to 38G show structure examples of an electronic device; and

FIGS. 39A and 39B show a structure example of an electronic device, and FIG. 39C shows a state where the electronic device is used.

### DETAILED DESCRIPTION OF THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of the embodiments below.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases. Note that in each drawing described in this specification, the size, the layer thickness, or the region of each component is exaggerated for clarity in some cases. Thus, the size, the layer thickness, or the region is not limited to the shown scale.

Note that in this specification and the like, ordinal numbers such as “first” and “second” are used in order to avoid confusion among components and do not limit the number of components.

In this specification and the like, the expression “having substantially the same top surface shapes” means that the outlines of stacked layers at least partly overlap with each other. For example, the case of patterning an upper layer and a lower layer with the use of the same mask pattern or mask patterns that are partly the same is included. The expression “having substantially the same top surface shapes” also sometimes includes the case where the outlines do not completely overlap with each other; for instance, the edge of the upper layer may be positioned on the inner side or the outer side of the edge of the lower layer.

Note that in this specification and the like, a top surface shape of a component means the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the term “over” or “under” in the specification indicates a direction that does not correspond to the apparent direction in the drawings, for the purpose of easy description or the like. For example, in the description of the stacked order (or the formation order) of a stacked body or the like, even in the case where a surface on which the stacked body is provided (e.g., a formation surface, a support surface, a bonding surface, or a planarization surface) is located over the stacked body in the drawings, the following expressions are used in some cases: the formation surface side is under the stacked body or the stacked body side is over the formation surface side.

In this specification and the like, the terms “film” and “layer” can be interchanged with each other. For example, in some cases, the term “insulating layer” can be interchanged with the term “insulating film”.

Note that in this specification, an EL layer means a layer containing at least a light-emitting substance (also referred to as a light-emitting layer) or a stack including the light-emitting layer provided between a pair of electrodes of a light-emitting element.

In this specification and the like, a structure in which a connector such as a flexible printed circuit (FPC) or a tape carrier package (TCP) is attached to a substrate of a display panel, or a structure in which an IC is mounted on the substrate by a chip on glass (COG) method or the like is referred to as a display panel module or a display module, or simply referred to as a display panel or the like in some cases.

### Embodiment 1

In this embodiment, structure examples and manufacturing method examples of a display device of one embodiment of the present invention will be described.

One embodiment of the present invention is a display device including a light-emitting element (also referred to as a light-emitting device). The display device includes at least two light-emitting elements that emit light of different colors. The light-emitting elements each include a pair of electrodes and an EL layer therebetween. The light-emitting elements are preferably organic electroluminescent elements (organic EL elements). Two or more light-emitting elements that emit light of different colors include respective EL layers containing different light-emitting materials. For example, three kinds of light-emitting elements that emit red (R), green (G), and blue (B) light achieves a full-color display device.

As a way of separately forming part or the whole of an EL layer between light-emitting elements of different colors, an evaporation method using a shadow mask such as a metal mask is known. However, this method has difficulty in achieving high resolution and a high aperture ratio of a display device because in this method, a deviation from the designed shape and position of the island-shaped organic film is caused by various influences such as low accuracy of the metal mask position, positional deviation between the metal mask and a substrate, a warp of the metal mask, and the vapor-scattering-induced expansion of the outline of the formed film. Thus, a measure has been taken for pseudo improvement in resolution (also referred to pixel density). As a specific measure, a unique pixel arrangement such as a PenTile pattern has been employed.

In one embodiment of the present invention, fine patterning of an EL layer is performed without a shadow mask such as a metal mask. Thus, it is possible to obtain a display device having high resolution and a high aperture ratio, which has been difficult to achieve. Moreover, EL layers can be formed separately, enabling the display device to perform extremely clear display with high contrast and high display quality.

In one embodiment of the present invention, a partition for dividing the EL layers are provided between two adjacent light-emitting elements (a first light-emitting element and a second light-emitting element). The partition is a conductive structure having an inverse tapered shape. In other words, the partition has a shape such that its upper portion extends in the horizontal direction beyond the lower portion. The partition is formed to be positioned between two adjacent pixel electrodes.

The partition is provided to surround one pixel electrode. For example, when an EL layer of the first light-emitting element is formed in such a structure that the partition is provided to surround the pixel electrode of the first light-emitting element, disconnection is caused by the partition, and then a disconnected EL layer can be provided over the pixel electrode.

In this specification and the like, disconnection refers to a phenomenon in which a layer, a film, an electrode, or the like is split because of the shape of its formation surface (e.g., a step).

After that, a resist mask is formed to cover the target pixel electrode and part of the partition, and an EL layer positioned in a region not covered with the resist mask is removed by etching. It is preferable that a film to be a mask layer be formed after the formation of the EL layer and etched in the etching of the EL layer to form a mask layer over the EL layer. The mask layer can function as a hard mask. After the resist mask is removed, the mask layer is preferably left. In that case, the EL layer of the first light-emitting element can be protected in a later etching step. Note that the mask layer is referred to as a sacrificial layer in some cases.

Next, the partition is provided to surround a pixel electrode of the second light-emitting element. After that, an EL layer of the second light-emitting element is formed.

Subsequently, a resist mask is formed to cover the target pixel electrode and part of the partition, and an EL layer positioned in a region not covered with the resist mask is removed by etching. In the etching of the EL layer of the second light-emitting element, the mask layer preferably remains over the EL layer of the first light-emitting element. In that case, the EL layer of the first light-emitting element can be protected in the etching of the EL layer of the second light-emitting element.

Next, the partition is provided to surround a pixel electrode of a third light-emitting element, and an EL layer of the third light-emitting element is formed using a step similar to that for the formation of the EL layer of the second light-emitting element.

Note that layers other than a light-emitting layer in an EL layer, such as an electron-injection layer, a hole-injection layer, an electron-transport layer, and a hole-transport layer, can be shared by light-emitting elements of different colors in some cases. Thus, these layers may be formed using the same steps in manufacturing a plurality of light-emitting elements.

After the EL layer of each light-emitting element is formed through the above steps, an upper electrode is formed to cover the EL layers and the partition. In this case, the upper electrode is formed by a film formation method that achieves higher step coverage than that for the EL layers. Accordingly, part of the upper electrode covers end portions of the EL layers and is in contact with part of the partition.

In this manner, a light-emitting element including a pixel electrode, an island-shaped EL layer, and an upper electrode in contact with the partition is formed in a region surrounded by the partition. The partition in contact with the upper electrode can function as a wiring for supplying a potential to the upper electrode.

With the use of the above-described method, light-emitting elements can be formed separately by a photolithography method that enables microfabrication without using a metal mask; thus, a display device achieving extremely high resolution and a high aperture ratio can be manufactured.

It is difficult to set the distance between EL layers for different colors to be less than 10 μm with a formation method using a metal mask, for example. In contrast, with use of the above method, the distance can be reduced to be less than or equal to 3 μm, less than or equal to 2 μm, or less than or equal to 1 μm. For example, with the use of a light exposure apparatus for LSI devices, the distance can be reduced to be less than or equal to 500 nm, less than or equal to 200 nm, less than or equal to 100 nm, or even less than or equal to 50 nm. Accordingly, the area of a non-light-emitting region that may exist between two light-emitting elements can be significantly reduced, and the aperture ratio can be close to 100%. For example, the aperture ratio may be higher than or equal to 50%, higher than or equal to 60%, higher than or equal to 70%, higher than or equal to 80%, or higher than or equal to 90%; that is, the aperture ratio lower than 100% can be achieved.

Furthermore, the size of the EL layer itself can be made much smaller than that of the case of using a metal mask. For example, in the case of using a metal mask for forming EL layers separately, a variation in the thickness occurs between the center and the edge of the island-shaped EL layer. This causes a reduction in an effective area that can be used as a light-emitting region with respect to the area of the entire EL layer. By contrast, in the above manufacturing method, a film formed to have a uniform thickness is processed to form an island-shaped EL layer with a uniform thickness. Thus, even when the EL layer has a minute size, almost the whole area can be used as a light-emitting region. Thus, the above manufacturing method achieves both high resolution and a high aperture ratio.

As described above, with the above manufacturing method, a display device in which minute light-emitting elements are integrated can be obtained, and it is not necessary to conduct a pseudo improvement in resolution with a unique pixel arrangement such as a PenTile arrangement. Thus, the display device can achieve resolution higher than or equal to 500 ppi, higher than or equal to 1000 ppi, higher than or equal to 2000 ppi, higher than or equal to 3000 ppi, higher than or equal to 5000 ppi, or higher than or equal to 8000 ppi while having a structure where one pixel includes light-emitting elements of three different colors.

More specific examples are described below with reference to drawings.

### STRUCTURE EXAMPLE

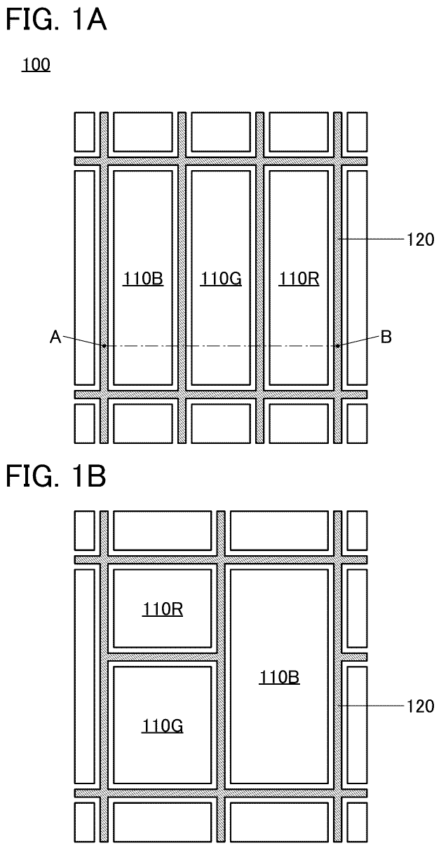

FIG. 1A is a schematic top view of a display device 100. The display device 100 includes a plurality of light-emitting elements 110R exhibiting red, a plurality of light-emitting elements 110G exhibiting green, and a plurality of light-emitting elements 110B exhibiting blue.

The light-emitting elements 110R, 110G, and 110B are arranged in a matrix. FIG. 1A shows what is called a stripe arrangement, in which light-emitting elements of the same color are arranged in one direction. Note that the arrangement of the light-emitting elements is not limited thereto; another arrangement such as an S-stripe, delta, zigzag, or PenTile arrangement may also be used. FIG. 1B shows an example in which an S-stripe arrangement is employed.

As each of the light-emitting elements 110R, 110G, and 110B, an EL element such as an organic light-emitting diode (OLED) or a quantum-dot light-emitting diode (QLED) is preferably used. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Examples of the light-emitting substance contained in the EL element include not only organic compounds but also inorganic compounds (e.g., quantum dot materials).

Note that in this embodiment, in the description of matters common to components that are distinguished from each other using alphabets or numbers added to reference numerals (e.g., a first EL layer 112R and a first EL layer 112G), reference numerals without alphabets or numbers (e.g., a first EL layer 112) are sometimes used.

A partition 120 is provided between light-emitting elements 110. The partition 120 has a lattice-shaped top surface. It can also be said that the light-emitting elements 110 are provided in a region surrounded by the partition 120.

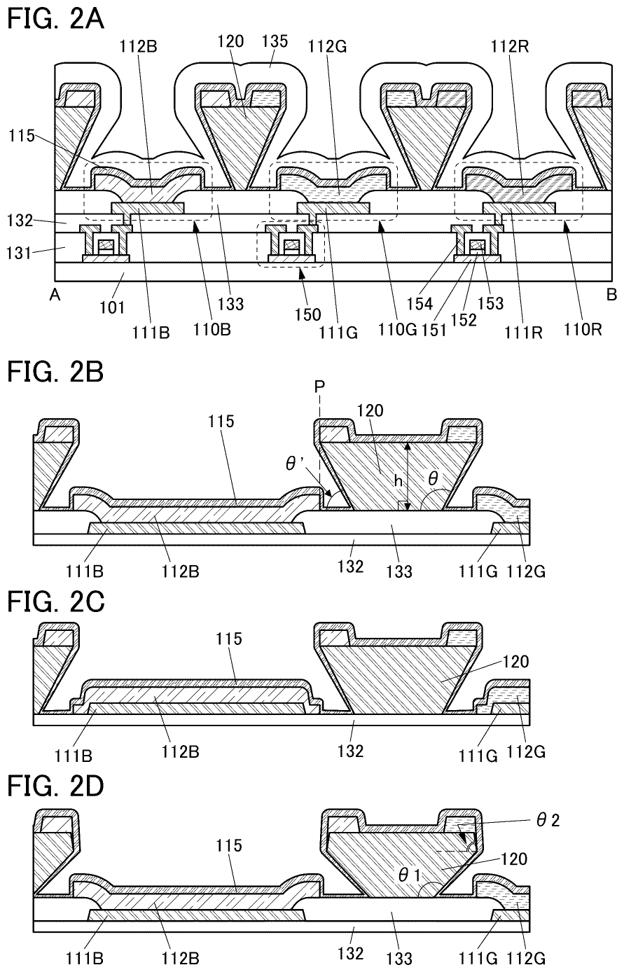

FIG. 2A is a schematic cross-sectional view of the display device 100 taken along line A-B shown in FIG. 1A. The display device 100 includes a plurality of transistors 150, the light-emitting element 110R, the light-emitting element 110G, and the light-emitting element 110B.

The transistor 150 is provided over a substrate 101. The transistor 150 includes a semiconductor layer 151 in which a channel is formed, an insulating layer 152 functioning as a gate insulating layer, a conductive layer 153 functioning as a gate electrode, and a pair of conductive layers 154 that are in contact with the semiconductor layer 151 and function as a source electrode and a drain electrode. The conductive layer 154 is provided over an insulating layer 131 covering the semiconductor layer 151, the insulating layer 152, and the conductive layer 153 and is in contact with the semiconductor layer 151 in an opening portion provided in the insulating layer 131.

For the semiconductor layer 151, a metal oxide (also referred to as an oxide semiconductor) exhibiting semiconductor characteristics is preferably used. As the oxide semiconductor, an oxide semiconductor typified by indium oxide or In—Ga—Zn oxide (IGZO) can be used. Alternatively, the semiconductor layer of the transistor may contain silicon. Examples of silicon include amorphous silicon and crystalline silicon (e.g., low-temperature polysilicon or single crystal silicon).

Other examples of the metal oxide that can be used for the semiconductor layer 151 include tin oxide, zinc oxide, indium tin oxide, indium titanium oxide, indium gallium oxide, indium tungsten oxide, indium zinc oxide, indium gallium aluminum oxide, indium gallium tin oxide, gallium zinc oxide, aluminum zinc oxide, indium aluminum zinc oxide, indium tin zinc oxide, indium titanium zinc oxide, indium gallium zinc oxide, indium gallium tin zinc oxide, and indium gallium aluminum zinc oxide. Alternatively, indium tin oxide containing silicon, gallium tin oxide, aluminum tin oxide, or the like can also be used.

Although an example of what is called a top-gate transistor in which the gate electrode is positioned above the semiconductor layer is shown here as an example of the transistor 150, one embodiment of the present invention is not limited thereto. For example, a bottom-gate transistor in which a gate electrode is positioned below a semiconductor layer can also be used.

An insulating layer 132 is provided to cover the conductive layer 154 and the insulating layer 131, and the light-emitting elements 110R, 110G, and 110B are provided over the insulating layer 132.

The light-emitting element 110R includes an EL layer between a pixel electrode 111R and an upper electrode 115. The light-emitting elements 110G includes an EL layer between a pixel electrode 111G and the upper electrode 115. The light-emitting elements 110B includes an EL layer between a pixel electrode 111B and the upper electrode 115.

As the EL layer of the light-emitting element 110R, the first EL layer 112R can be used. As the EL layer of the light-emitting element 110G, the first EL layer 112G can be used. As the EL layer of the light-emitting element 110B, a first EL layer 112B can be used.

The upper electrodes 115 of the light-emitting element 110R, the light-emitting element 110G, and the light-emitting element 110B are preferably electrically connected to each other. In FIG. 2A, a structure in which a continuous conductive layer covers the EL layers of three light-emitting elements is used in common as the upper electrodes 115 of the light-emitting element 110R, the light-emitting element 110G, and the light-emitting element 110B.

Although FIG. 2A shows an example in which a plurality of light-emitting elements each include an EL layer, it is also possible to provide an EL layer to be shared by the plurality of light-emitting elements. For example, a stacked-layer structure of a first EL layer provided in each of a plurality of light-emitting elements and a second EL layer shared by the plurality of light-emitting elements can be used as an EL layer of the light-emitting elements. The second EL layer is referred to as a common layer in some cases.

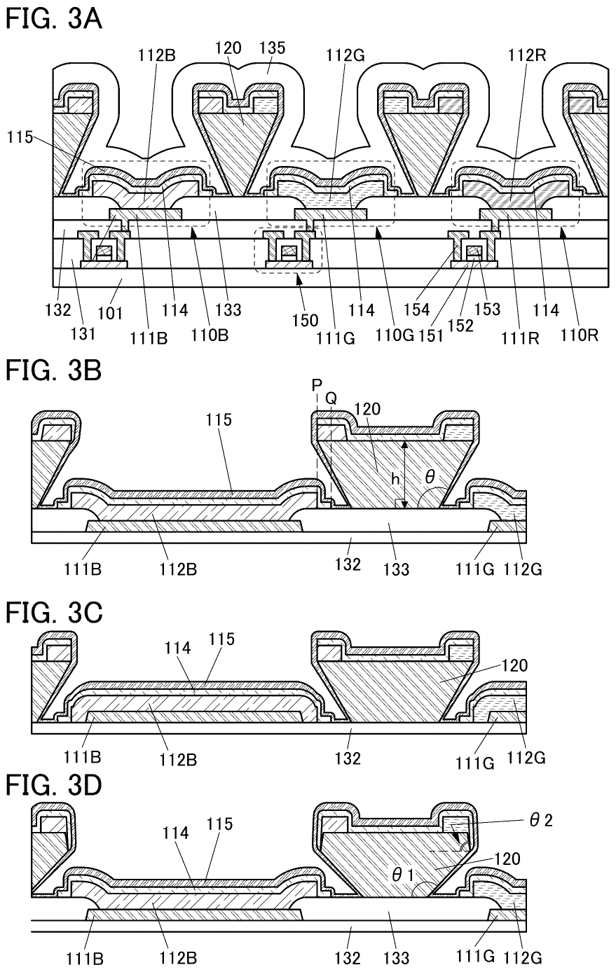

FIG. 3A shows an example in which the light-emitting element 110R has a stacked-layer structure of the first EL layer 112R and a second EL layer 114 over the first EL layer 112R as the EL layer between the pixel electrode 111R and the upper electrode 115. The light-emitting element 110G includes the first EL layer 112G and the second EL layer 114 over the first EL layer 112G between the pixel electrode 111G and the upper electrode 115. The light-emitting element 110B includes the first EL layer 112B and the second EL layer 114 over the first EL layer 112B between the pixel electrode 111B and the upper electrode 115.

In FIG. 3A, a structure in which a continuous conductive layer covers the EL layers of three light-emitting elements is used in common as the upper electrodes 115 of the light-emitting element 110R, the light-emitting element 110G, and the light-emitting element 110B.

In the light-emitting element 110R, the second EL layer 114 preferably covers a side surface of the first EL layer 112R. In that case, a structure can be obtained in which the first EL layer 112R and the upper electrode 115 are not in contact with each other. In the case where the side surface of the first EL layer 112R is in contact with the upper electrode 115, leakage current might flow between the upper electrode 115 and a layer of the first EL layer 112R that has high conductivity. Such leakage current might cause a malfunction in the operation of the light-emitting element 110R. For example, a carrier-injection layer such as an electron-injection layer or a hole-injection layer has high conductivity in some cases. In particular, when the first EL layer 112R includes a hole-injection layer, the hole-injection layer is preferably not in contact with the upper electrode 115. Furthermore, in the case where the first EL layer 112R has a tandem structure, a charge-generation layer, which has high conductivity, is preferably not in contact with the upper electrode 115.

Similarly, in the light-emitting element 110G, the second EL layer 114 preferably covers a side surface of the first EL layer 112G. Similarly, in the light-emitting element 110B, the second EL layer 114 preferably covers a side surface of the first EL layer 112B.

The second EL layer 114 of each of the light-emitting elements 110R, 110G, and 110B can be formed using the same material in the same step. Although the second EL layer 114 shown in the range of FIG. 3A is separated between the three light-emitting elements, the second EL layer 114 may be connected between different light-emitting elements in some regions of the display device 100.

Each pixel electrode 111 is provided over the insulating layer 132 and is connected to the conductive layer 154 through an opening portion provided in the insulating layer 132. Accordingly, each pixel electrode 111 is connected to one of the source electrode and the drain electrode of the transistor 150.

The first EL layer 112R included in the light-emitting element 110R contains at least a light-emitting organic compound that emits red light. The first EL layer 112G included in the light-emitting element 110G contains at least a light-emitting organic compound emitting green light. The first EL layer 112B included in the light-emitting element 110B contains at least a light-emitting organic compound emitting blue light. Blue light has an emission peak in the wavelength range greater than or equal to 450 nm and less than 500 nm, for example. Green light has an emission peak in the wavelength range greater than or equal to 500 nm and less than 600 nm, for example. Red light has an emission peak in the wavelength range greater than or equal to 600 nm and less than 700 nm, for example.

The EL layers included in the light-emitting elements 110R, 110G, and 110B may each include one or more of an electron-injection layer, an electron-transport layer, an electron-blocking layer, a hole-injection layer, a hole-transport layer, and a hole-blocking layer in addition to a layer containing a light-emitting substance (a light-emitting layer). Thus, the first EL layers 112R, 112G, and 112B each include one or more of an electron-injection layer, an electron-transport layer, an electron-blocking layer, a hole-injection layer, a hole-transport layer, and a hole-blocking layer in addition to a light-emitting layer, for example. As the light-emitting substance, an organic compound can be used, for example.

In the case where the light-emitting elements 110R, 110G, and 110B each include the second EL layer 114, one or more of an electron-injection layer, an electron-transport layer, an electron-blocking layer, a hole-injection layer, a hole-transport layer, and a hole-blocking layer may be included in the second EL layer 114. As the second EL layer 114, a layer containing an organic compound can be used, for example. Alternatively, the second EL layer 114 may be a layer containing an inorganic compound.

For example, in the case where the light-emitting element 110R includes the second EL layer 114, a stacked-layer structure of the first EL layer 112R and the second EL layer 114 can function as the EL layer of the light-emitting element 110R. Thus, in this case, at least one of the first EL layer 112R and the second EL layer 114 includes a light-emitting layer. For another example, in the case where the light-emitting element 110G includes the second EL layer 114, a stacked-layer structure of the first EL layer 112G and the second EL layer 114 can function as the EL layer of the light-emitting element 110G. For another example, in the case where the light-emitting element 110B includes the second EL layer 114, a stacked-layer structure of the first EL layer 112B and the second EL layer 114 can function as the EL layer of the light-emitting element 110B. In those structures, the second EL layer 114 includes, for example, an electron-injection layer or a hole-injection layer. Alternatively, the second EL layer 114 may be a stack of an electron-transport layer and an electron-injection layer, or may be a stack of a hole-transport layer and a hole-injection layer.

A conductive film that has a property of transmitting visible light is used for either the respective pixel electrodes 111 or the upper electrode 115, and a reflective conductive film is used for the other. When the pixel electrodes 111 are light-transmitting electrodes and the upper electrode 115 is a reflective electrode, a bottom-emission light-emitting element is obtained. When the pixel electrodes 111 are reflective electrodes and the upper electrode 115 is a light-transmitting electrode, a top-emission light-emitting element is obtained. Note that when both the pixel electrodes 111 and the common electrode 115 transmit light, a dual-emission display device can be obtained.

A protective layer 135 is provided to cover the upper electrode 115.

The protective layer 135 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 135.

As the protective layer 135, a stacked film of an inorganic insulating film and an organic insulating film can also be used. For example, a structure in which an organic insulating film is sandwiched between a pair of inorganic insulating films is preferable.

An insulating layer 133 is provided to cover an end portion of each pixel electrode 111. A portion of each of the pixel electrodes 111 where the insulating layer 133 is not provided functions as a light-emitting region of the light-emitting element 110. End portions of the insulating layer 133 are preferably tapered. Note that the insulating layer 133 is not necessarily provided.

Note that in this specification and the like, an end portion of an object having a tapered shape has a cross-sectional shape in which an angle formed between a side surface of the object and a surface on which the object is in contact (also referred to as a taper angle) is greater than 0° and less than 90°, and the thickness continuously increases from the end portion. By contrast, an object having an inverse tapered shape indicates that an angle formed between a side surface of the object and a surface on which the object is in contact with a formation surface is greater than or equal to 90° and less than 180°.

The insulating layer 133 preferably contains an organic resin. Using an organic resin for the insulating layer 133 can increase adhesion between the insulating layer 133 and the first EL layer 112, so that the manufacturing yield can be improved. In particular, in the case of processing EL layers by etching, it is preferable to use the insulating layer 133 having high adhesion with the EL layers, in which case a defect such as separation of the EL layers after etching can be decreased.

When an organic resin is used for the insulating layer 133, a surface of the insulating layer 133 can be flat and moderately curved. Thus, coverage with a film formed over the insulating layer 133 can be improved.

Examples of materials usable for the insulating layer 133 include an acrylic resin, a polyimide resin, an epoxy resin, a polyamide resin, a polyimide-amide resin, a siloxane resin, a benzocyclobutene-based resin, a phenol resin, and precursors of these resins. In this specification and the like, an acrylic resin refers not only to a polymethacrylic acid ester or a methacrylic resin, but also to all the acrylic polymer in a broad sense in some cases.

The first EL layers 112 each include a region in contact with a top surface of the pixel electrode 111 and a region in contact with a surface of the insulating layer 133. End portions of the first EL layers 112 are positioned over the insulating layer 133.

The partition 120 is provided over the insulating layer 133. The partition 120 has conductivity and an inverse tapered shape.

FIG. 2B is an enlarged view of the light-emitting element 110B, the light-emitting element 110G, the partition 120 positioned therebetween, and the vicinity thereof.

End portions of the first EL layers 112B and 112G are positioned over the insulating layer 133. The upper electrode 115 covers the end portion of the first EL layer 112B and is in contact with a top surface of the insulating layer 133 and part of a side surface of the partition 120. The upper electrode 115 covers the end portion of the first EL layer 112G and is in contact with the top surface of the insulating layer 133 and the side surface of the partition 120.

As shown in FIG. 2B, part of the first EL layer 112B and part of the first EL layer 112G are provided over the partition 120 and have side surfaces facing each other. The upper electrode 115 over the partition 120 covers a top surface of the first EL layer 112B, a top surface of the first EL layer 112G, and the side surfaces of the first EL layer 112B and the first EL layer 112G that face each other.

Although FIG. 2A shows an example in which the height of the partition 120 is larger than the width thereof, the cross-sectional width is actually larger than the height in some cases. FIG. 2B and the like show the case where the cross-sectional width of the partition 120 is larger than the height thereof, as an example. FIG. 2B and the like also show an example in which the width of the EL layer is larger than the width of the partition.

FIG. 3B is an enlarged view of the light-emitting element 110B, the light-emitting element 110G, the partition 120 positioned therebetween, and the vicinity thereof.

The end portions of the first EL layers 112B and 112G are positioned over the insulating layer 133. The upper electrode 115 covers the end portion of the first EL layer 112B and is in contact with the top surface of the insulating layer 133 and part of the side surface of the partition 120. The upper electrode 115 covers the end portion of the first EL layer 112G and is in contact with the top surface of the insulating layer 133 and the side surface of the partition 120. The light-emitting element 110B includes the second EL layer 114 between the first EL layer 112B and the upper electrode 115.

As shown in FIG. 3B, the part of the first EL layer 112B and the part of the first EL layer 112G are provided over the partition 120 and have side surfaces facing each other. The second EL layer 114 over the partition 120 covers the top surface of the first EL layer 112B, the top surface of the first EL layer 112G, and the side surfaces of the first EL layer 112B and the first EL layer 112G that face each other. The upper electrode 115 covers a top surface of the second EL layer 114.

Although FIG. 3A shows an example in which the height of the partition 120 is larger than the width thereof, the cross-sectional width is actually larger than the height in some cases. FIG. 3B and the like show the case where the cross-sectional width of the partition 120 is larger than the height thereof, as an example. FIG. 3B and the like also show an example in which the width of the EL layer is larger than the width of the partition.

The first EL layer 112B has another side surface that does not face the first EL layer 112G, and the side surface is continuous with the side surface of the partition 120 and is covered with the upper electrode 115. The first EL layer 112G also has another side surface that does not face the first EL layer 112B, and the side surface is continuous with the side surface of the partition 120 and is covered with the upper electrode 115.

The upper electrode 115 covers the side surface of the partition 120 and the top surface of the insulating layer 133. A sidewall of the partition 120 preferably has a region in contact with the upper electrode 115. The top surface of the insulating layer 133 preferably has a region in contact with the upper electrode 115.

Note that the side surface of the partition 120 is referred to as a sidewall in some cases.

The upper electrodes 115 of adjacent light-emitting elements (here, the light-emitting element 110B and the light-emitting element 110G are shown as an example) are preferably electrically connected to each other. In the above-described structure, the upper electrode 115 shared by the light-emitting element 110B and the light-emitting element 110G, i.e., a continuous conductive layer, covers the EL layers of the two light-emitting elements; however, the upper electrode 115 may partly disappear on the side surface of the partition 120. Even in such a case, the divided upper electrodes 115 can be electrically connected to each other through the partition 120.

The partition 120 is provided to have a lattice shape filling spaces between the light-emitting elements 110 as shown in FIG. 1A and the like and thus can also function as a wiring for supplying a potential to the upper electrode 115 of each light-emitting element 110.

A height h of the partition 120 is preferably larger than the thickness of the largest film among the first EL layer 112R, the first EL layer 112G, and the first EL layer 112B. A taper angle θ of the partition 120 can be greater than 90° and less than 180°. When the taper angle is closer to 90°, the partition 120 and the upper electrode 115 are more likely to be in contact with each other at the time of forming the upper electrode 115, whereas a gap between the end portion of the first EL layer 112 and the partition 120 is smaller. The closer the taper angle is to 180°, the more easily the first EL layer 112 is disconnected, whereas the upper electrode 115 and the partition 120 are more difficult to contact with each other. Thus, the preferred taper angle θ is, for example, greater than or equal to 95° and less than or equal to 170°, greater than or equal to 95° and less than or equal to 150°, preferably greater than or equal to 100° and less than or equal to 135°.

When the taper angle θ is increased, for example, the EL layer can be prevented from being in contact with the side surface of the partition 120. Thus, the taper angle θ can be greater than or equal to 105° and less than or equal to 175°, preferably greater than or equal to 120° and less than or equal to 170°, for example.

Note that although the taper angle θ is shown here as the angle between a bottom surface and the side surface of the partition 120, an angle (a taper angle θ′) between the side surface of the partition 120 and a top surface of a base film (here, the insulating layer 133) of the partition 120 that is not in contact with the partition 120 can also be used as shown in FIG. 2B. In that case, θ′=180°−θ (each of θ and θ′ is greater than or equal to 0° and less than or equal to 180°) is satisfied. In other words, the preferable range of the taper angle θ′ can be greater than or equal to 30° and less than or equal to 85°, preferably greater than or equal to 45° and less than or equal to 80°, or greater than or equal to 5° and less than or equal to 75°, further preferably greater than or equal to 10° and less than or equal to 60°. As for which angle is used to express the taper angle, the one that is easily measured is selected in consideration of a surface shape of the base film (e.g., the insulating layer 133).

A variety of conductive materials can be used for the partition 120. For example, a metal, an alloy, an oxide conductive material, a nitride conductive material, or the like can be used. For example, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material.

For the partition 120, an oxide conductive material typified by indium tin oxide can be used. Alternatively, indium oxide, indium zinc oxide, indium titanium oxide, indium gallium zinc oxide, indium tin zinc oxide, indium titanium zinc oxide, indium gallium tin zinc oxide, or the like can be used. Further alternatively, indium tin oxide containing silicon can also be used, for example.

With such a structure, EL layers can be formed separately between adjacent light-emitting elements; thus, the leakage current through the EL layers can be reduced to substantially zero as compared with the case where the EL layers are in contact with each other or a common EL layer is used. This can prevent unintended light emission, so that a display device with high contrast and high display quality can be obtained. Furthermore, since the first EL layer 112 is covered with the upper electrode 115 and the protective layer 135 in a region surrounded by the partition 120, diffusion of impurities such as moisture into the first EL layer 112 is prevented, so that a highly reliable display device can be achieved. In this structure, processing of the first EL layer 112 and the like can be performed by a photolithography method without using a metal mask; hence, higher resolution and a higher aperture ratio can be easily achieved as compared with the case of using a metal mask.

The end portion of the first EL layer 112B can be substantially aligned with an end portion of a top surface of the partition 120.

FIG. 2B shows an example in which an end portion P of the first EL layer 112B is aligned with the end portion of the top surface of the partition 120. In the case where the first EL layer 112B is formed by an evaporation method, the first EL layer 112B is preferably deposited by evaporation of a material travelling in a direction perpendicular or substantially perpendicular to a substrate surface from an evaporation source. Here, “a material travelling in a direction perpendicular or substantially perpendicular to a substrate surface” means, for example, that the material travels in a direction at an angle, with respect to the substrate surface, greater than or equal to 75° and less than or equal to 105°, preferably greater than or equal to 80° and less than or equal to 100°, further preferably greater than or equal to 85° and less than or equal to 95°. When the material is controlled to travel in the substantially perpendicular direction from the evaporation source, the first EL layer 112B can be formed so that the end portion P is substantially aligned with the end portion of the top surface of the partition 120.

An end portion Q of the second EL layer 114 is positioned closer to the side surface of the partition 120 than the end portion P of the first EL layer 112B is. FIG. 3B shows a state where the end portion P is aligned with the end portion of the top surface of the partition 120. In the case where the first EL layer 112B and the second EL layer 114 are formed by an evaporation method, the first EL layer 112B is deposited by evaporation of a material travelling in a direction perpendicular or substantially perpendicular to a substrate surface from an evaporation source, and the second EL layer 114 is deposited by evaporation of a material travelling to a region below the side surface of the partition 120 from the evaporation source. Here, “a material travelling in a direction perpendicular or substantially perpendicular to a substrate surface” means, for example, that the material travels in a direction at an angle, with respect to the substrate surface, greater than or equal to 75° and less than or equal to 105°, preferably greater than or equal to 80° and less than or equal to 100°, further preferably greater than or equal to 85° and less than or equal to 95°. In this manner, by controlling the direction in which a material travels from the evaporation source, the first EL layer 112B and the second EL layer 114 can be formed such that the end portion Q is positioned closer to the side surface of the partition 120 than the end portion P is.

Although the above structure shows an example in which the partition 120 is provided over the insulating layer 133, the insulating layer 133 is not necessarily provided.

FIG. 2C is different from FIG. 2B mainly in that the insulating layer 133 is not provided. In FIG. 2C, the partition 120 is provided in contact with a top surface of the insulating layer 132 in a manner similar to that of the pixel electrode 111. The end portion of the first EL layer 112B and the end portion of the first EL layer 112G are each positioned over the insulating layer 132, and the upper electrode 115 is in contact with the insulating layer 132 and the partition 120.

FIG. 3C is different from FIG. 3B mainly in that the insulating layer 133 is not provided. In FIG. 3C, the partition 120 is provided in contact with the top surface of the insulating layer 132 in a manner similar to that of the pixel electrode 111. The end portion of the first EL layer 112B and the end portion of the first EL layer 112G are each positioned over the insulating layer 132, and the upper electrode 115 is in contact with the insulating layer 132 and the partition 120. An end portion of the second EL layer 114 is positioned over the insulating layer 132.

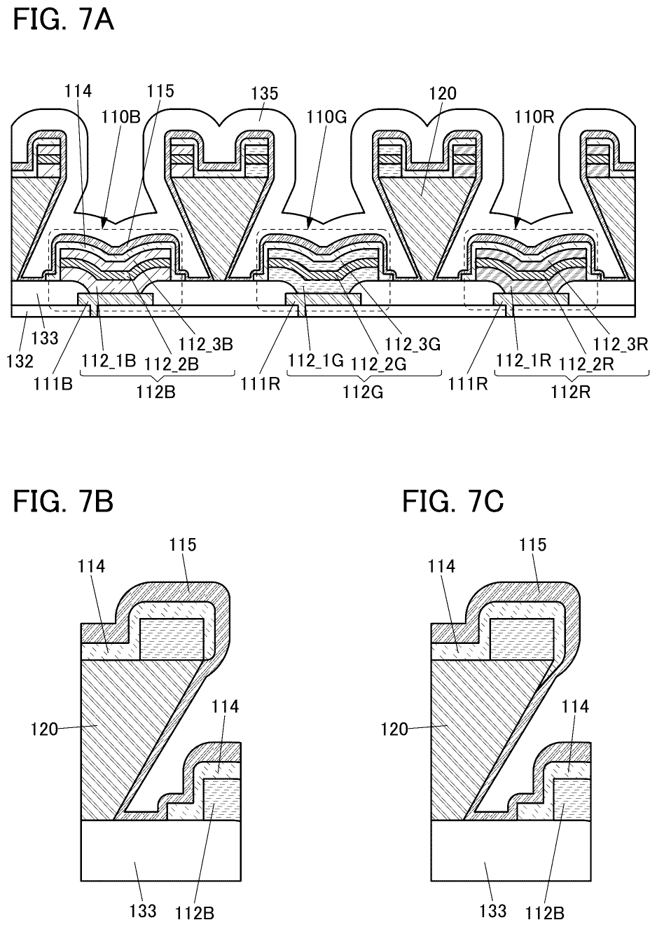

FIGS. 7B and 7C are enlarged views of an upper end of the side surface of the partition 120 and the vicinity thereof in FIG. 3B. As shown in FIG. 7B, the second EL layer 114 is sometimes provided to cover the side surface of the first EL layer 112 over the partition 120.

As shown in FIG. 7C, the second EL layer 114 sometimes covers the upper end of the side surface of the partition 120 and the vicinity thereof. Also in such a case, a lower side surface of the partition 120 is preferably not covered with the second EL layer 114.

Hereinafter, symbols R, G, and B are sometimes omitted in the description common to the light-emitting element 110R, the light-emitting element 110G, and the light-emitting element 110B. The symbols R, G, and B are sometimes omitted also in the description common to the first EL layer 112R, the first EL layer 112G, and the first EL layer 112B.

FIG. 2D is different from FIG. 2B in the shape of the partition 120. In the structure shown in FIG. 2D, the side surface of the partition 120 has different angles: one is an angle close to the top surface of the partition 120 (referred to as an angle θ2); and the other is an angle close to the insulating layer 133 (referred to as an angle θ1). FIG. 2D shows an example in which the angle θ1 is greater than 90° and less than 180° and the angle θ2 is less than or equal to 90°. In FIG. 2D, a cross section of the partition 120 is substantially polygonal, has an upper side and a lower side which are substantially parallel to the formation surface, and has two side surfaces forming different angles with the formation surface. Note that the cross section of the partition 120 may have rounded corners.

FIG. 3D shows a structure example which is different from that in FIG. 3B in the shape of the partition 120, and the angle θ2 of the side surface close to the top surface of the partition 120 is different from the angle θ1 of the side surface close to the insulating layer 133. In FIG. 3D, a cross section of the partition 120 is substantially polygonal, has an upper side and a lower side which are substantially parallel to the formation surface, and has two side surfaces forming different angles with the formation surface. Note that the cross section of the partition 120 may have rounded corners.

The partition 120 shown in FIG. 2B and the like has an inverse tapered shape. The partition 120 shown in FIG. 2B and the like can also be regarded as having a substantially trapezoidal shape in which the length of an upper base is longer than the length of a lower base in a cross-sectional view. Note that the shape of the partition 120 is not limited thereto, and the partition 120 can have a variety of shapes as long as the first EL layer 112 can be disconnected. Note that the partition 120 can have a bilaterally symmetrical shape in a cross-sectional view. In the case where the partition 120 has a flat top surface, the shape of the partition 120 in a cross-sectional view is a polygonal shape with even-numbered corners. Another example of the cross-sectional shape of the partition 120 is described below.

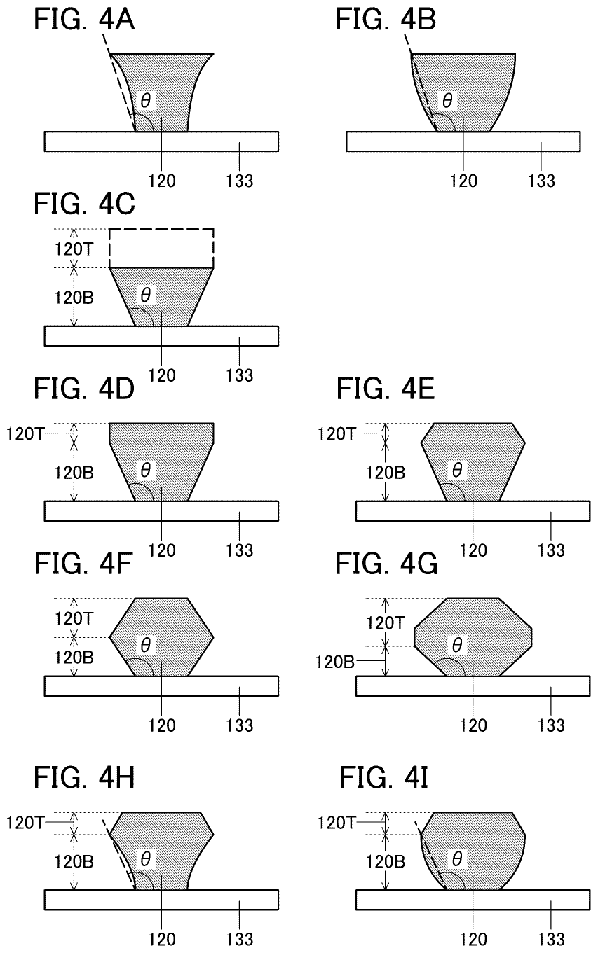

In examples shown in FIGS. 4A and 4B, the side surface of the partition 120 is curved. FIG. 4A shows the side surface having a concave surface, and FIG. 4B shows the side surface having a convex surface.

In the case where the side surface of the partition 120 is curved, it is difficult to uniquely determine the taper angle θ. In that case, as shown in FIGS. 4A and 4B, in a cross-sectional view, a straight line that connects a point on the side surface of a portion with a largest width in the partition 120 and a point of the side surface that is an end portion of the contact surface of the partition 120 with the base film (the insulating layer 133) is assumed to be a virtual side surface of the partition 120; and an angle between the straight line and the contact surface of the partition 120 with the base film (the insulating layer 133) may be the taper angle θ.

Here, an upper portion of the partition 120 may have any shape as long as part of the partition 120 has a tapered shape in a portion in contact with at least the base film. As shown in FIG. 4C, the partition 120 can be divided into a lower portion 120B having a tapered shape and an upper portion 120T positioned above the lower portion 120B. Since the shape of the upper portion 120T can be varied, the shape is not shown here and is denoted by dashed line. Examples of different shapes of the upper portion 120T are described below.

FIG. 4D shows an example of the upper portion 120T having a rectangular shape in a cross-sectional view. FIGS. 4E and 4F each show an example of the upper portion 120T having a trapezoidal shape in which the length of an upper base is longer than the length of a lower base in a cross-sectional view. FIG. 4E shows an example in which the height of the upper portion 120T is smaller than that of the lower portion 120B, and FIG. 4F shows an example in which the height of the upper portion 120T is substantially equal to that of the lower portion 120B. It can also be said that the partition 120 shown in FIGS. 4D, 4E, and 4F has a hexagonal shape in a cross-sectional view.

FIG. 4G shows an example of the partition 120 having an octagonal shape in a cross-sectional view. In FIG. 4G, part of the side surface of the partition 120 is substantially perpendicular to the formation surface.

FIGS. 4H and 4I show modification examples of FIGS. 4A and 4B, respectively, in which the lower portion 120B having a curved surface and the upper portion 120T having a trapezoidal shape in a cross-sectional view are included.

Note that although the side surface of the partition 120 has a corner portion in the above description, the corner is rounded in some cases depending on a processing method of the partition 120. In particular, when the partition 120 is formed by an isotropic etching method such as wet etching, the partition tends to have rounded corners.

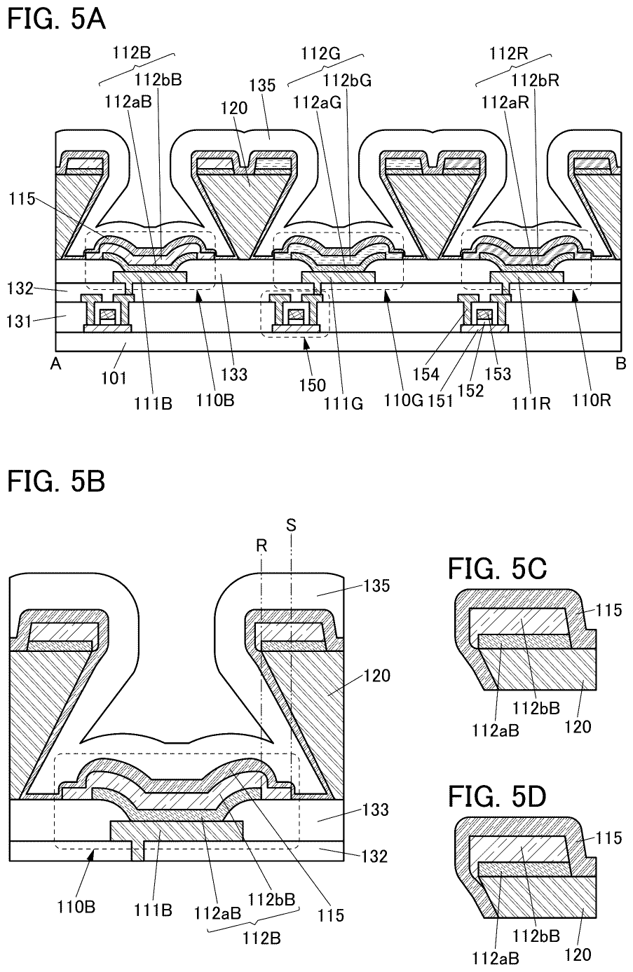

FIG. 5A shows a structure example in which the shape of the first EL layer 112 is different from that in FIG. 2A.

In FIG. 5A, the first EL layer 112R includes a layer 112aR and a layer 112bR over the layer 112aR. The first EL layer 112G includes a layer 112aG and a layer 112bG over the layer 112aG. The first EL layer 112B includes a layer 112aB and a layer 112bB over the layer 112aB.

Hereinafter, symbols R, G, and B are sometimes omitted in description of the layer 112aR, the layer 112aG, and the layer 112aB. The same applies to the layer 112b. In FIG. 5A, the side surface of the layer 112a is covered with the layer 112b.

In the light-emitting element 110, an end portion of the layer 112a is preferably positioned inward from that of the layer 112b. Accordingly, the side surface of the layer 112a can be covered with the layer 112b, so that the upper electrode 115 and the layer 112a are not in contact with each other.

The layer 112a includes at least a hole-injection layer or an electron-injection layer. The layer 112a can have a stacked-layer structure of a hole-injection layer and a hole-transport layer, or can have a stacked-layer structure of an electron-injection layer and an electron-transport layer. The layer 112a can include a light-emitting layer.

For example, the layer 112a includes a hole-injection layer, and the layer 112b includes a hole-transport layer, a light-emitting layer over the hole-transport layer, an electron-transport layer over the light-emitting layer, and an electron-injection layer.

In the case where a side surface of the layer 112a is in contact with the upper electrode 115, leakage current might flow between the upper electrode and a layer of the layer 112a that has high conductivity. Such leakage current might cause a malfunction in the operation of the light-emitting element 110. In particular, when the layer 112a includes a hole-injection layer, the layer 112a is preferably not in contact with the upper electrode 115.

FIG. 5B is an enlarged view of a portion shown in FIG. 5A.

An end portion S of the layer 112bB is positioned closer to the side surface of the partition 120 than an end portion R of the layer 112aB is. FIG. 5B shows a state where the end portion R is aligned with the end portion of the top surface of the partition 120. In the case where the layer 112aB and the layer 112bB are formed by an evaporation method, the layer 112aB is deposited by evaporation of a material travelling in a direction perpendicular or substantially perpendicular to the substrate surface from an evaporation source, and the layer 112bB is deposited by evaporation of a material travelling to a region below the side surface of the partition 120 from the evaporation source. Here, “a material travelling in a direction perpendicular or substantially perpendicular to the substrate surface” means, for example, that the material travels in a direction at an angle, with respect to the substrate surface, greater than or equal to 75° and less than or equal to 105°, preferably greater than or equal to 80° and less than or equal to 100°, further preferably greater than or equal to 85° and less than or equal to 95°. In this manner, by controlling the direction in which a material travels from the evaporation source, the layer 112aB and the layer 112bB can be formed such that the end portion S is positioned closer to the side surface of the partition 120 than the end portion R is.

FIGS. 5C and 5D are enlarged views of an upper end of the side surface of the partition 120 and the vicinity thereof in FIG. 5B. As shown in FIG. 5C, the layer 112bB over the partition 120 is sometimes provided to cover the side surface of the layer 112aB.

As shown in FIG. 5D, the layer 112bB sometimes covers the upper end of the side surface of the partition 120 and the vicinity thereof. Also in such a case, a lower side surface of the partition 120 is preferably not covered with the layer 112bB.

As the EL layer of the light-emitting element, a structure in which a plurality of light-emitting units are stacked can also be used. A structure in which a plurality of light-emitting units are connected in series with a charge-generation layer therebetween is referred to as a tandem structure in some cases.

As the EL layer, for example, a structure including a first light-emitting layer, a second light-emitting layer, and a charge-generation layer positioned between the first light-emitting layer and the second light-emitting layer can be used. The first light-emitting layer and the second light-emitting layer can contain a light-emitting organic compounds that emit light of the same color, for example. The first light-emitting layer and the second light-emitting layer can each contain a light-emitting organic compounds that emit light of different colors, for example.

The first EL layer 112 has a structure in which a hole-injection layer, a hole-transport layer, a first light-emitting layer, an electron-transport layer, a charge-generation layer, a second hole-transport layer, a second light-emitting layer, a second electron-transport layer, and an electron-injection layer are stacked in this order, for example.

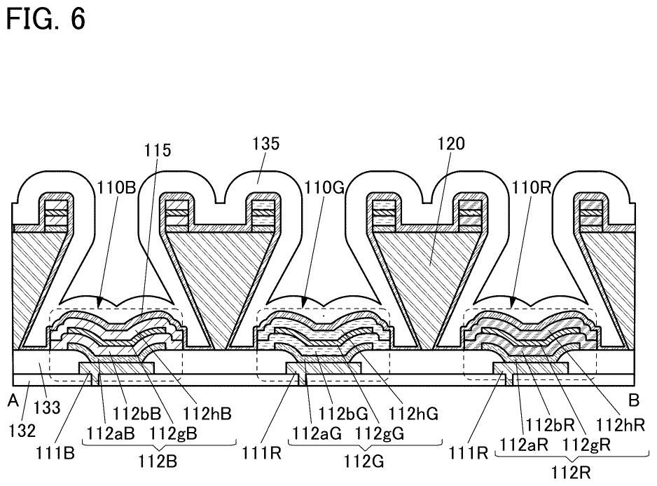

FIG. 6 shows an example in which the first EL layer 112B has a stacked-layer structure of the layer 112aB, the layer 112bB, a layer 112gB, and a layer 112hB; the first EL layer 112G has a stacked-layer structure of the layer 112aG, the layer 112bG, a layer 112gG, and a layer 112hG; and the first EL layer 112R has a stacked-layer structure of the layer 112aR, the layer 112bR, a layer 112gR, and a layer 112hR.

Hereinafter, in some cases, symbols R, G, and B are omitted in the description common to the layer 112gR, the layer 112gG, and the layer 112gB, and the layers are referred to as a “layer 112g”. The same applies to the layer 112h.

The layer 112b includes a second light-emitting layer, the layer 112g includes a charge-generation layer, and the layer 112h includes a second light-emitting layer. The layer 112b, the layer 112g, and the layer 112h may each include one or more of an electron-injection layer, an electron-transport layer, an electron-blocking layer, a hole-injection layer, a hole-transport layer, and a hole-blocking layer. The layer 112a includes one or more of an electron-injection layer, an electron-transport layer, an electron-blocking layer, a hole-injection layer, a hole-transport layer, and a hole-blocking layer.

For example, the layer 112a includes a hole-injection layer; the layer 112b includes a hole-transport layer, a first light-emitting layer, and an electron-transport layer; the layer 112g includes a charge-generation layer; and the layer 112h includes a hole-transport layer, a second light-emitting layer over the hole-transport layer, an electron-transport layer over the second light-emitting layer, and an electron-injection layer.

In that case, the layer 112b may include an electron-blocking layer between the hole-transport layer and the light-emitting layer. The layer 112b may include a hole-blocking layer between the light-emitting layer and the electron-transport layer. In addition, the layer 112h may include an electron-blocking layer between the hole-transport layer and the light-emitting layer. The layer 112h may include a hole-blocking layer between the light-emitting layer and the electron-transport layer.

Since the charge-generation layer has high conductivity, an end portion of the layer 112g is preferably positioned inward from that of the layer 112h as shown in FIG. 6. In that case, leakage current between the upper electrode 115 and the charge-generation layer included in the layer 112g can be reduced.

The structure shown in FIG. 7A is different from that in FIG. 4A mainly in that the first EL layer 112 includes a charge-generation layer and a second light-emitting layer, for example. In FIG. 7A, the first EL layer 112 has a structure in which a layer 112_1, a layer 112_2, and a layer 112_3 are stacked in order. The layer 112_1 includes a first light-emitting layer, the layer 112_2 includes a charge-generation layer, and the layer 112_3 includes a second light-emitting layer.

In addition to a light-emitting layer, the layer 112_1 can include one or more of a hole-injection layer, a hole-transport layer, an electron-blocking layer, a hole-blocking layer, an electron-transport layer, and an electron-injection layer.

In addition to a light-emitting layer, the layer 112_3 can include one or more of a hole-injection layer, a hole-transport layer, an electron-blocking layer, a hole-blocking layer, an electron-transport layer, and an electron-injection layer.

In the case where the second EL layer 114 includes an electron-injection layer, the layer 112_3 includes one or more of a hole-injection layer, a hole-transport layer, an electron-blocking layer, a hole-blocking layer, and an electron-transport layer, for example. In the case where the second EL layer 114 includes a hole-injection layer, the layer 112_3 includes one or more of a hole-transport layer, an electron-blocking layer, a hole-blocking layer, an electron-transport layer, and an electron-injection layer, for example.

In the case where the second EL layer 114 includes an electron-injection layer and an electron-transport layer, the layer 112_3 includes one or more of a hole-injection layer, a hole-transport layer, an electron-blocking layer, and a hole-blocking layer, for example. In the case where the second EL layer 114 includes a hole-injection layer and a hole-transport layer, the layer 112_3 includes one or more of an electron-blocking layer, a hole-blocking layer, an electron-transport layer, and an electron-injection layer, for example.

For example, the layer 112_1 includes a hole-injection layer, a hole-transport layer, a first light-emitting layer, and an electron-transport layer; the layer 112_2 includes a charge-generation layer; the layer 112_3 includes a hole-transport layer, a second light-emitting layer over the hole-transport layer, and an electron-transport layer over the second light-emitting layer; and the second EL layer 114 includes an electron-injection layer.

In that case, the layer 112_1 may include an electron-blocking layer between the hole-transport layer and the light-emitting layer. The layer 112_1 may include a hole-blocking layer between the light-emitting layer and the electron-transport layer. In addition, the layer 112_3 may include an electron-blocking layer between the hole-transport layer and the light-emitting layer. The layer 112_3 may include a hole-blocking layer between the light-emitting layer and the electron-transport layer.

Alternatively, for example, the layer 112_1 includes a hole-injection layer, a hole-transport layer, a first light-emitting layer, and an electron-transport layer; the layer 112_2 includes a charge-generation layer; the layer 112_3 includes a hole-transport layer and a second light-emitting layer over the hole-transport layer; and the second EL layer 114 includes an electron-transport layer and an electron-injection layer over the electron-transport layer.

In that case, the layer 112_1 may include an electron-blocking layer between the hole-transport layer and the light-emitting layer. The layer 112_1 may include a hole-blocking layer between the light-emitting layer and the electron-transport layer. In addition, the layer 112_3 may include an electron-blocking layer between the hole-transport layer and the light-emitting layer. The layer 112_3 may include a hole-blocking layer over the light-emitting layer.

### VARIATION EXAMPLES

In the above example, the display device 100 includes the light-emitting element 110 of three colors (the light-emitting element 110R, the light-emitting element 110G, and the light-emitting element 110B); however, the display device 100 may additionally include an element.

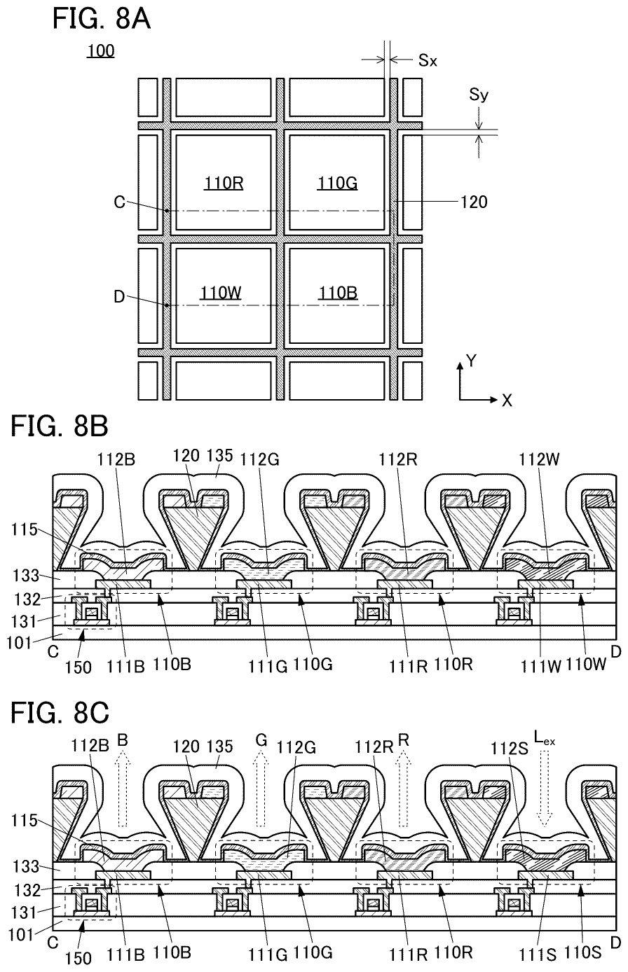

FIGS. 8A and 8B show an example in which a white light-emitting element 110W is included in addition to the red, green, and blue light-emitting elements 110. FIG. 8A is a top view, and FIG. 8B is a schematic cross-sectional view taken along line C-D in FIG. 8A.

The light-emitting element 110W includes a pixel electrode 111W, an EL layer 112W, and the upper electrode 115. The protective layer 135 is provided to cover the light-emitting element 110W.

The EL layer 112W can include two or more light-emitting layers. For example, when two light-emitting layers are combined so as to emit light of complementary colors, white light emission can be obtained. A structure including three or more light-emitting layers may also be employed.

Using the white light-emitting element in addition to the red, green, and blue light-emitting elements can achieve higher contrast and higher reliability.

FIG. 8C shows an example in which a light-receiving element 110S is provided instead of the light-emitting element 110W.

The light-receiving element 110S functions as a photoelectric conversion element and can output an electric signal corresponding to the amount of incident light. Thus, an image sensor can be incorporated in the display device 100. In FIG. 8C, arrows indicate directions of light R, light G, and light B emitted from the light-emitting element 110R, the light-emitting element 110G, and the light-emitting element 110B, respectively, and a direction of light Lex incident on the light-receiving element 110S from the outside.

The light-receiving element 110S includes a pixel electrode 111S, a sensor layer 112S, and the upper electrode 115. The protective layer 135 is provided to cover the light-receiving element 110S.

The sensor layer 112S preferably includes an organic layer that can also be employed for the first EL layer 112R or the like. For example, it is possible to employ the structure of the first EL layer 112R in which the light-emitting layer is replaced with a light-receiving layer (also referred to as an active layer or a photoelectric conversion layer).

The light-receiving layer included in the sensor layer 112S can have a stacked-layer structure in which a p-type semiconductor and an n-type semiconductor are stacked to form a PN junction; or a stacked-layer structure in which a p-type semiconductor, an i-type semiconductor, and an n-type semiconductor are stacked to form a PIN junction, for example.

As the semiconductor used for the light-receiving layer, an inorganic semiconductor such as silicon or an organic semiconductor containing an organic compound can be used. In particular, the use of an organic semiconductor material is preferable, in which case the first EL layer 112R and the light-receiving layer are easily formed by the same vacuum evaporation method, and thus the same manufacturing apparatus can be used.

When an organic semiconductor material is used for the light-receiving layer, an electron-accepting organic semiconductor material such as fullerene (e.g., C₆₀ or C₇₀) or its derivative can be used as an n-type semiconductor material. As a p-type semiconductor material, an electron-donating organic semiconductor material such as copper(II) phthalocyanine (CuPc) or tetraphenyldibenzoperiflanthene (DBP) can be used. The light-receiving layer may have a stacked-layer structure (a p-n structure) including an electron-accepting semiconductor material and an electron-donating semiconductor material, or a stacked-layer structure (a p-i-n structure) in which a bulk heterostructure layer formed by co-evaporation of an electron-accepting semiconductor material and an electron-donating semiconductor material is provided between the materials of the p-n structure. Furthermore, a layer functioning as a hole blocking layer or a layer functioning as an electron blocking layer may be provided around (above or below) the p-n structure or the p-i-n structure, in order to inhibit dark current caused when light is not applied.

The above is the description of the modification examples.

Note that FIG. 8B and FIG. 8C each show an example in which the structure shown in FIG. 2A or the like is used for the light-emitting element 110; however, structures of the light-emitting element 110 described in other drawings and the like in this specification can also be used.

The above is the description of the structure examples.

### Manufacturing Method Example 1

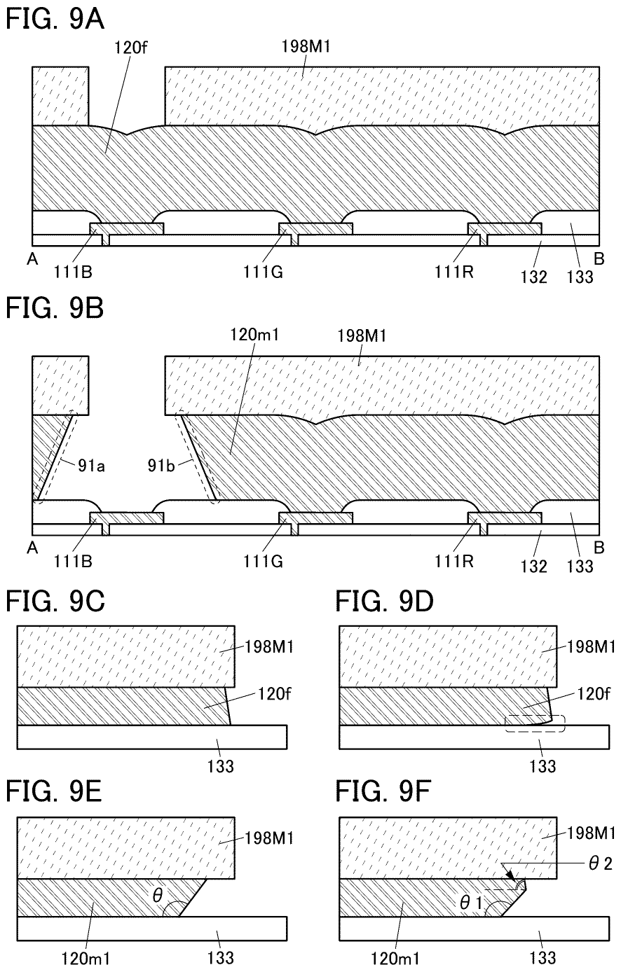

An example of a method for manufacturing the display device of one embodiment of the present invention is described below with reference to the drawings. Here, the description is made with the use of the display device 100 shown above in Structure example. FIGS. 9A to 9F, FIGS. 10A to 10C, FIGS. 11A and 11B, FIGS. 12A to 12D, FIGS. 13A to 13C, FIGS. 14A to 14C, FIGS. 15A to 15C, FIGS. 16A to 16C, FIGS. 17A and 17B, FIGS. 18A and 18B, FIG. 19, FIGS. 20A and 20B, and FIGS. 21A to 21E are schematic cross-sectional views of steps in the method for manufacturing the display device described as an example below.

Note that thin films included in the display device (e.g., insulating films, semiconductor films, or conductive films) can be formed by any of a sputtering method, a chemical vapor deposition (CVD) method, a vacuum evaporation method, a pulsed laser deposition (PLD) method, an atomic layer deposition (ALD) method, and the like.

Alternatively, thin films included in the display device (e.g., insulating films, semiconductor films, and conductive films) can be formed by a method such as spin coating, dipping, spray coating, ink-jetting, dispensing, screen printing, or offset printing or with a doctor knife, a slit coater, a roll coater, a curtain coater, or a knife coater.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used to form a layer of a compound such as an oxide, a nitride, or a carbide by a reactive sputtering method.

CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object. A thermal CVD method yields a film with few defects because of no plasma damage during film formation.

As an ALD method, a thermal ALD method, in which a precursor and a reactant react with each other only by a thermal energy, a PEALD method, in which a reactant excited by plasma is used, or the like can be used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method, in which a plurality of different kinds of precursors are used, enables formation of a film with a desired composition. In the case where a plurality of different kinds of precursors are introduced, the number of cycles for each precursor is controlled, whereby a film with a desired composition can be formed. Furthermore, a film whose composition is continuously changed can be formed as in the CVD method.

The thin films constituting the display device can be processed using a photolithography method or the like. Besides, a nanoimprinting method, a sandblasting method, a lift-off method, or the like may be employed to process the thin films. Alternatively, island-shaped thin films may be directly formed by a film formation method using a shielding mask such as a metal mask. Further alternatively, a directed self-assembly (DSA) method may be used.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. EUV, X-rays, or an electron beam is preferably used to enable extremely minute processing. Note that a photomask is not needed when exposure is performed by scanning with a beam such as the above-described light or an electron beam.

For etching of thin films, a dry etching method, a wet etching method, a sandblast method, or the like can be used. In the dry etching method, isotropic etching or anisotropic etching can be performed when the conditions are controlled. In the wet etching method, isotropic etching can be performed.

### <Formation of Partition, Pixel Electrode, and First EL Layer>

A method for forming a partition, a pixel electrode of a light-emitting element, a first EL layer of the light-emitting element, and the like is described with reference to FIGS. 9A to 9F, FIGS. 10A to 10C, FIGS. 11A and 11B, FIGS. 12A to 12D, FIGS. 13A to 13C, FIGS. 14A to 14C, FIGS. 15A to 15C, FIGS. 16A to 16C, FIGS. 20A and 20B, and FIGS. 21A to 21E.

First, the substrate 101 is prepared, and the transistor 150, the insulating layer 131, the insulating layer 132, and the like are formed. Next, a conductive film is formed over the insulating layer 132 and an unnecessary portion of the conductive film is removed by etching, so that the pixel electrode 111R, the pixel electrode 111G, and the pixel electrode 111B are formed.

As the substrate 101, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

In the case where a conductive film that has a property of reflecting visible light is used as the pixel electrodes 111, it is preferable to use a material having as high a reflectivity as possible in the entire wavelength range of visible light (e.g., silver or aluminum). This can increase both light extraction efficiency and color reproducibility of the light-emitting elements.

Subsequently, the insulating layer 133 is formed to cover an end portion of each pixel electrode 111. An organic insulating film or an inorganic insulating film can be used as the insulating layer 133. The end portions of the insulating layer 133 are preferably tapered to improve step coverage with an EL film. In particular, when an organic insulating film is used, a photosensitive material is preferably used so that the shape of the end portions can be easily controlled by the conditions of light exposure and development.

Next, a conductive film 120f to be the partition 120 later is formed. For the conductive film 120f, a material having high etching selectivity with respect to each pixel electrode 111 is preferably used. The conductive film 120f is preferably formed using a conductive material different from that for the uppermost layer of the pixel electrode 111. Alternatively, a film functioning as an etching stopper may be formed before the formation of the conductive film 120f, and the film positioned over the pixel electrode 111 may be removed after the conductive film 120f is etched. In that case, the pixel electrode 111 and the conductive film 120f can be formed using the same conductive material.

Next, a resist mask 198M1 is formed over the conductive film 120f (FIG. 9A). Subsequently, a portion of the conductive film 120f that is not covered with the resist mask 198M1 is removed by etching to form a partition 120m1 (FIG. 9B). In other words, the partition 120m1 is in a state where a region of the conductive film 120f overlapping with the pixel electrode 111B and part of a region of the conductive film 120f overlapping with the insulating layer 133 are removed. In the etching of the conductive film 120f, part of the insulating layer 133 positioned between the light-emitting element 110B and a light-emitting element adjacent to the light-emitting element 110B is removed, for example. Then, the resist mask 198M1 is removed. The partition 120m1 is formed to surround the pixel electrode 111B. Side surfaces of the partition 120m1 that surround the pixel electrode 111B are formed. FIG. 9B shows an example in which the partition 120m1 has a side surface 91a and a side surface 91b. In a plan view, the pixel electrode 111B is sandwiched between the side surface 91a and the side surface 91b.

The conductive film 120f can be etched by an isotropic etching method. For example, a wet etching method or an isotropic dry etching method can be used. Wet etching is particularly preferable because it excels in isotropic etching and enables favorable processability even when the conductive film 120f has a small thickness. The conductive film 120f is processed so that a lower portion of the conductive film 120f proceeds faster than an upper portion thereof, whereby the partition 120m1 having an inverse tapered shape can be formed.

For example, when a material is selected so that adhesion between the conductive film 120f and the insulating layer 133 is lower than adhesion between the conductive film 120f and the resist mask 198M1, the etching rate at the lower portion can be higher than that at the upper portion, whereby the partition 120m1 having an inverse tapered shape can be formed. In other words, the etching rate of the conductive film 120f is high at the interface with the insulating layer 133 and the vicinity thereof. For example, in the case where a conductive oxide such as indium tin oxide is used for the conductive film 120f, an organic material with low adhesion with indium tin oxide (e.g., an acrylic resin) can be used for the insulating layer 133.

Etching of the conductive film 120f is described with reference to FIGS. 9C to 9F.

As shown in FIG. 9C, the conductive film 120f is processed to have substantially the same width as the resist mask 198M1. Note that in FIG. 9C, an edge of the conductive film 120f is positioned slightly inward from an edge of the resist mask 198M1; for example, in the case of using an isotropic etching method, the etching sometimes proceeds to a region inward from the edge of the resist mask 198M1.

As shown in FIG. 9D, in the case where adhesion between the insulating layer 133 and the conductive film 120f is low, the etching sometimes proceeds gradually from an end portion of a surface (a region surrounded by the dashed line) of the conductive film 120f that is in contact with the insulating layer 133. In particular, in the case of using wet etching, such etching is likely to occur when an etchant enters an interface with low adhesion.

As shown in FIG. 9E, when the etching further proceeds, the partition 120m1 having an inverse tapered shape with the taper angle θ can be formed.

As shown in FIG. 9F, the side surface of the partition 120m1 sometimes has different angles: one is an angle close to the top surface of the partition 120m1 (referred to as the angle θ2 in FIG. 9F); and the other is an angle close to the insulating layer 133 (referred to as the angle θ1 in FIG. 9F). For example, the angle θ1 is greater than 90° and less than 180° and the angle θ2 is less than or equal to 90° in some cases.

As described above, when a material having low adhesion with the conductive film 120f is selected for the insulating layer 133, the partition 120m1 having an inverse tapered shape can be formed.

In the case where an organic insulating layer is used as the insulating layer 133, the adhesion between the conductive film 120f and the insulating layer 133 is preferably lower than that between the inorganic insulating layer and the conductive film 120f, for example.

The adhesion between the insulating layer 133 and the conductive film 120f is preferably lower than that between silicon oxide and the conductive film 120f, for example.

The adhesion can be examined by a separation test, for example.

In the separation test, force required for separation is measured. For example, a tape is attached onto a layer including a layer to be separated and force required for separation of the tape and the layer including the layer to be separated, whereby the force required for separation can be measured.

For the separation test, an adhesive tape/adhesive sheet testing method based on standard number JIS Z0237 of Japanese Industrial Standards (JIS) can be employed.

In the case of the conductive film 120f formed over the insulating layer 133, the force required for separation of the conductive film 120f from the insulating layer 133 can be measured. Note that the structure of the sample to be evaluated is sometimes different from the actual structure in the display device. For example, for the sample to be evaluated, a material usable for the insulating layer 133 is used without patterning.

In the evaluation, the force required for the separation of the conductive film 120f from the insulating layer 133 is lower than 8 N, preferably higher than or equal to 0.1 N and lower than or equal to 5 N, further preferably higher than or equal to 0.1 N and lower than or equal to 2 N.

In the case where the force required for the separation is higher than or equal to 8 N, for example, an etchant is less likely to enter a space between the insulating layer 133 and the conductive film 120f due to high adhesion. This makes it difficult to sufficiently increase the etching rate at the lower portion of the conductive film 120f more than that at the upper portion, so that the inverse tapered shape is less likely to be formed. In the case where the force required for the separation is lower than 0.1 N, for example, adhesion sufficient for the manufacturing process of the display device might not be ensured; and thus the conductive film 120f might be separated in the middle of the manufacturing process.

In the case where indium tin oxide, indium tin oxide containing silicon, indium tin zinc oxide, or the like is used for the conductive film 120f, a chemical solution containing oxalic acid can be used to remove the conductive film 120f.

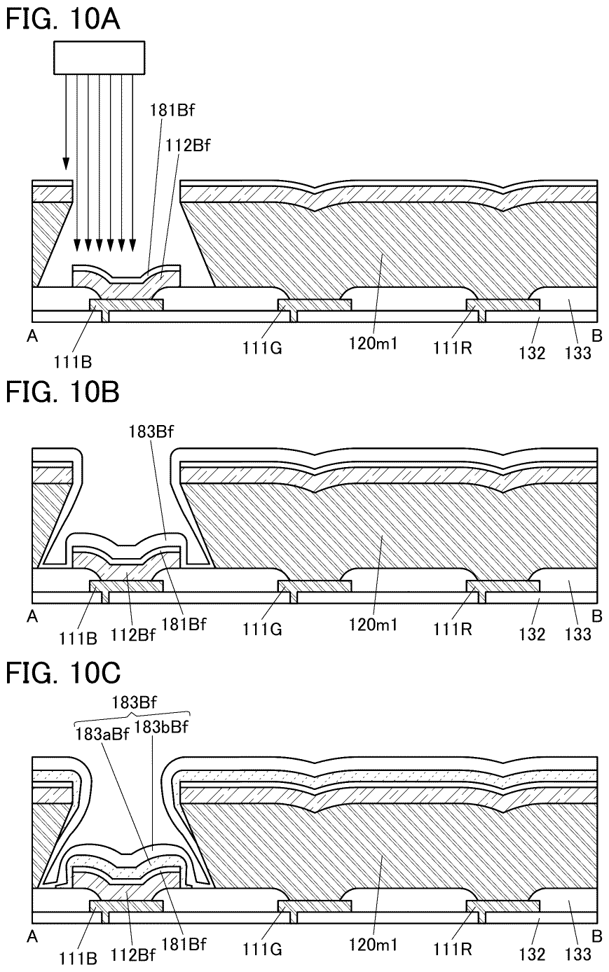

Next, a film 112Bf, which is a film to be the first EL layer 112B, is formed over the pixel electrode 111B and the partition 120m1. After that, a film 181Bf is formed (FIG. 10A). The film 181Bf has a function of protecting the film 112Bf. The film 181Bf is not necessarily formed. At this time, the film 112Bf is disconnected by the partition 120m1 and is formed over the partition 120m1 and in a region surrounded by the partition 120m1.

The film 112Bf includes a first portion over the pixel electrode 111B and a second portion over the partition 120m1, and the first portion and the second portion are separated from each other. The first portion can function as the first EL layer 112B.

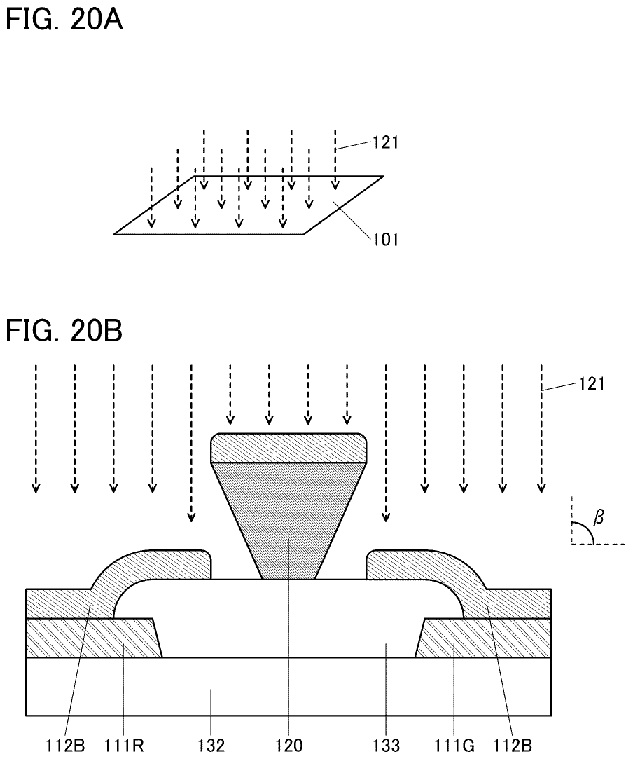

A method for forming the film 112Bf is described with reference to FIGS. 20A and 20B. The film 112Bf is preferably formed by a highly anisotropic film formation method. That is, as shown in FIG. 20A, the film formation is performed such that an angle β formed between the substrate surface and a travelling direction of a film formation material 121 is substantially perpendicular to the top surface of the substrate 101. In this manner, disconnection can be caused by the partition 120 as shown in FIG. 20B. Here, a sufficient space for the upper electrode 115 to enter is preferably provided between the film 112Bf and the partition 120.

The film 112Bf can be formed by, for example, a vacuum evaporation method.

It is preferable that a light-emitting layer not be exposed as the uppermost layer of the film 112Bf. For example, the film 112Bf has a stacked-layer structure of a hole-injection layer, a hole-transport layer, a light-emitting layer, and an electron-transport layer. In that case, the light-emitting layer is covered with the electron-transport layer, so that damage to the light-emitting layer can be reduced in later film formation steps of the film 181Bf and a film 183Bf. Thus, the characteristics and reliability of the light-emitting element 110B can be improved.

The film 181Bf can be formed similarly to the film 112Bf by the highly anisotropic film formation method shown in FIGS. 20A and 20B. With the highly anisotropic film formation method, the film 181Bf formed over the film 112Bf is disconnected by the partition 120m1 and positioned between the partitions 120m1 and over the partition 120m1, as shown in FIG. 10A.

The film 181Bf has a function of protecting a surface of the film 112Bf in a later step.

After the formation of the film 112Bf, the film 181Bf is preferably formed without exposure to an air atmosphere. With the film 181Bf, the adhesion of the film 183Bf to be formed later is improved in some cases. The film 181Bf can be formed by, for example, a vacuum evaporation method.

The film 181Bf is preferably etched by a method that causes less damage to the film 112Bf than the method for the film 183Bf formed later. For example, the etching is preferably performed by a wet etching method. It is also preferable that the film 112Bf not be changed in quality due to a chemical solution used for wet etching of the film 181Bf.

As the film 181Bf, a film containing an organic material or an inorganic insulating material can be used, for example. Specifically, any of water-soluble materials can be used. In other words, a material that will be dissolved in a solvent containing water can be used for the film 181Bf. Specifically, a material having higher water solubility than the film 112Bf can be used for the film 181Bf. For example, a material that will be dissolved in an aqueous solution containing hydrofluoric acid (HF) can be used for the film 181Bf. Furthermore, a material that will be dissolved in an aqueous solution containing tetramethyl ammonium hydroxide (abbreviation: TMAH) can be used for the film 181Bf.

Specifically, the film 181Bf can be formed using a metal complex such as tris(8-quinolinolato)aluminum(III) (abbreviation: Alq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), bis[2-(2-benzothiazolyl)phenolato]zinc(II) (abbreviation: ZnBTZ), 2-methyl-8-hydroxyquinolinato-lithium (abbreviation: Li-mq), 8-quinolinolato-lithium (abbreviation: Liq), 5-methyl-8-quinolinolato-lithium (abbreviation: Li-5mq), 6-methyl-8-quinolinolatolithium (abbreviation: Li-6mq), 7-methyl-8-quinolinolatolithium (abbreviation: Li-7mq), 6-tert-butyl-8-quinolinolato-lithium (abbreviation: Li-6tBuq), 3-methyl-8-quinolinolatolithium (abbreviation: Li-3mq), 3,6-dimethyl-8-quinolinolatolithium (abbreviation: Li-3,6dmq), 4-methyl-8-quinolinolatolithium (abbreviation: Li-4mq), 4,6-dimethyl-8-quinolinolatolithium (abbreviation: Li-4,6dmq), 2,3-dimethyl-8-quinolinolatolithium, 2,5-dimethyl-8-quinolinolatolithium, 2-(1,1-dimethylethyl)-8-quinolinolatolithium, 4-(1,1-dimethylethyl)-8-quinolinolatolithium, 4,5-dimethyl-8-quinolinolatolithium, 5-propyl-8-quinolinolato-lithium, 5,7-dimethyl-8-quinolinolatolithium, 8-hydroxyquinoline sodium salt (abbreviation: Naq), 6-methyl-8-quinolinolato-sodium (abbreviation: Na-6mq), 2-methyl-8-quinolinolatosodium, 8-hydroxyquinolinato-potassium (abbreviation: Kq), 2-methyl-8-quinolinolatopotassium, tetrakis(8-quinolinolato)zirconium(IV) (abbreviation: Zrq4), tetrakis(4-methyl-8-quinolinolato)zirconium(IV), tetrakis(7-propylquinolinolato)zirconium(IV), tetrakis[5-(1,1-dimethylethyl)-8-quinolinolato]zirconium(IV), or tris(8-hydroxyquinolinato)gallium(III) (abbreviation: Gaq₃).

Organic compounds represented below by Structural Formulae (101) to (110) and Structural Formulae (111) to (115) can be used for the film 181Bf.

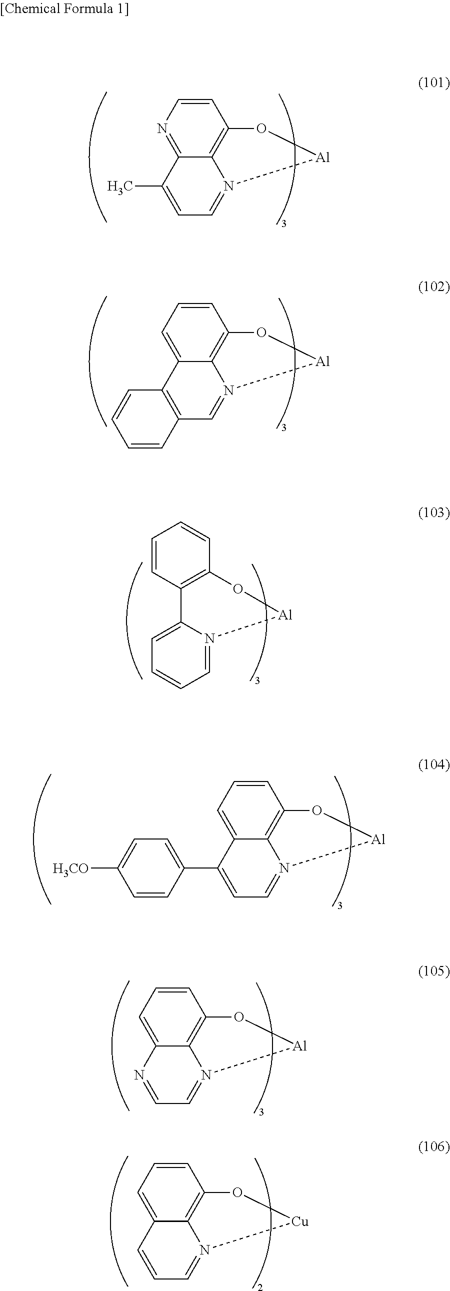

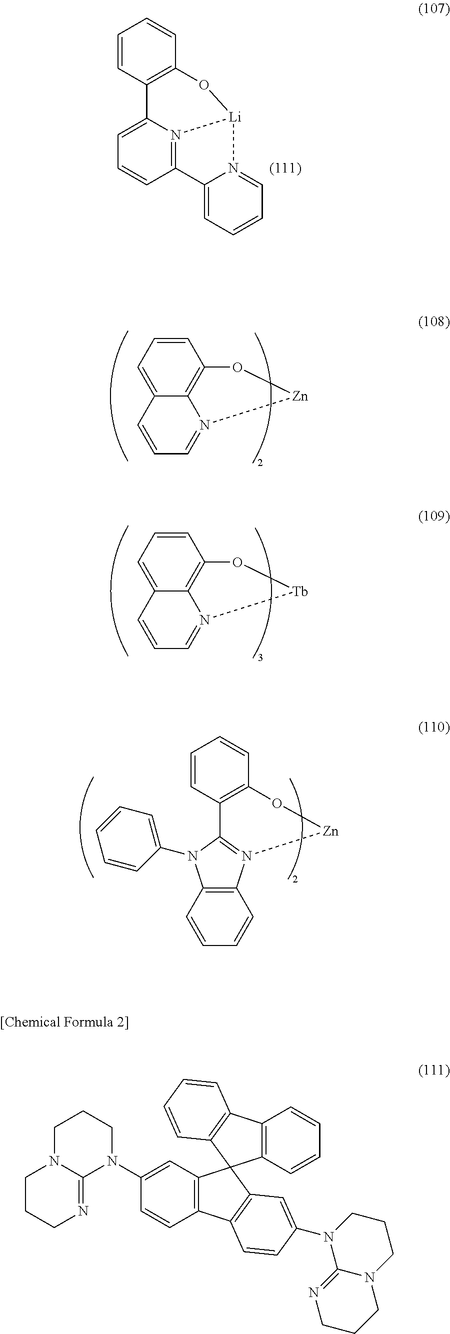

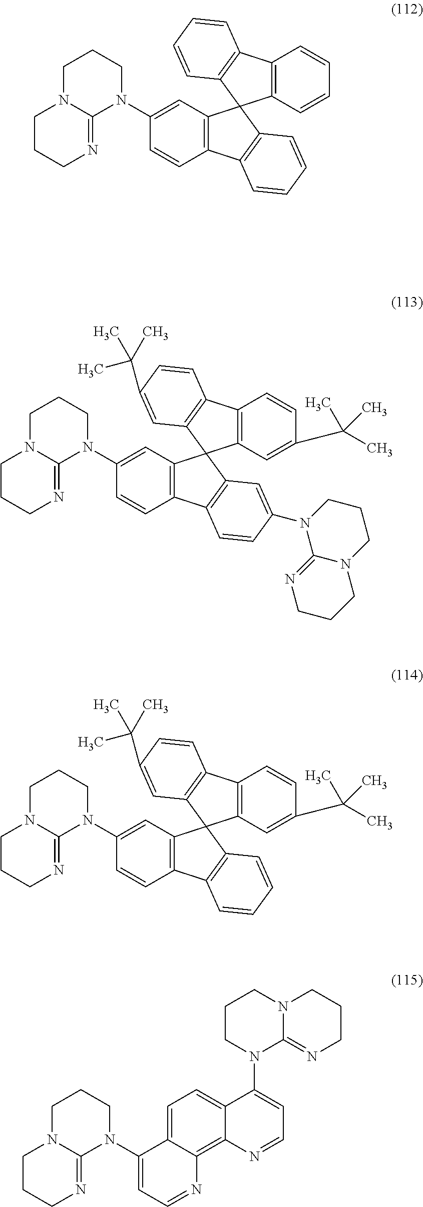 [SMILES: c1ccc2c(c1)-c1ccccc1C21c2ccccc2-c2ccc(N3CCCN4CCCN=C43)cc21 ; CC(C)(C)c1ccc2c(c1)C1(c3cc(N4CCCN5CCCN=C54)ccc3-c3ccc(N4CCCN5CCCN=C54)cc31)c1cc(C(C)(C)C)ccc1-2 ; CC(C)(C)c1ccc2c(c1)C1(c3ccccc3-c3ccc(N4CCCN5CCCN=C54)cc31)c1cc(C(C)(C)C)ccc1-2 ; c1cc(N2CCCN3CCCN=C32)c2ccc3c(N4CCCN5CCCN=C54)ccnc3c2n1]

Among the above materials, tris(8-quinolinolato)aluminum(III) (abbreviation: Alq₃) can be particularly suitably used for the film 181Bf, in which case the film 181Bf can be easily removed due to its solubility and can increase the adhesion with the film 183Bf when provided between the film 112Bf and the film 183Bf.

Next, the film 183Bf is formed over the film 181Bf (FIG. 10B). The film 183Bf has a function of protecting the film 181Bf and the film 112Bf.

In the case where the film 181Bf is formed by a highly anisotropic method, the film 181Bf does not cover a side surface of the film 112Bf in some cases. In the case where the film 112Bf is exposed to an air atmosphere after its formation, providing the film 183Bf before the exposure can inhibit deterioration due to a reaction between the film 112Bf and either oxygen or moisture, for example. Accordingly, an inorganic material, e.g., an inorganic oxide, can be used for the film 183Bf.

As the film 183Bf, a metal film or an alloy film can be used, for example. In that case, deterioration of the film 112Bf due to light irradiation in the manufacturing process can be inhibited. In particular, the use of a metal material capable of shielding ultraviolet rays can inhibit the film 112Bf from being irradiated with ultraviolet rays in light exposure in a photolithography process.

As the film 183Bf, a film that can be removed by a wet etching method or a dry etching method is preferably used. For example, with wet etching, damage to the film 112Bf can be reduced. The film 183Bf can have a single-layer structure or a stacked-layer structure of two or more layers. In the case of the stacked-layer structure, to perform etching of the lower layer closer to the film 112Bf by wet etching can reduce damage to the film 112Bf.

The film 183Bf can be formed by a CVD method, a sputtering method, an ALD method, a vacuum evaporation method, or the like. A CVD method and a sputtering method can be suitably used as a film formation method of the film 183Bf, because they enable high film formation rate and easy film formation on a large substrate, resulting in high productivity.

Note that the film 183Bf can have a stacked-layer structure. Different film formation methods can be used for the stacked films. FIG. 10C shows an example in which the film 183Bf has a stacked-layer structure of a film 183aBf and a film 183bBf over the film 183aBf. The film 183aBf has lower coverage than the film 183bBf and does not cover the lower side surface of the partition 120m1. In addition, the film 183aBf does not cover part of the top surface of the insulating layer 133 which is exposed.

For example, the film 183aBf can be formed by a sputtering method, and the film 183bBf can be formed by a CVD method.

Specifically, as the film 183aBf, a film of a metal oxide such as an In—Ga—Zn oxide is preferably formed by a sputtering method. An In—Ga—Zn oxide can be removed using a chemical solution containing phosphoric acid and thus is preferable.

A film of an inorganic insulator containing silicon such as silicon nitride is preferably formed as the film 183bBf by a CVD method. A film formed by a CVD method has few pinholes and higher coverage than a film formed by a sputtering method. Thus, diffusion of impurities such as oxygen or water into the film 112Bf can be inhibited.

For the film 183Bf, an inorganic material is preferably used, for example. Alternatively, an organic material can be used for the film 183Bf.

As the film 183Bf, one or more of a metal film, an alloy film, a metal compound film, a semiconductor film, an inorganic insulating film, and the like can be used, for example. Alternatively, a stack including two or more layers selected from these can be used.

For the film 183Bf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material, for example. In particular, the use of a low-melting-point material such as aluminum or silver can decrease the temperature in the manufacturing process, which not only increases productivity but also reduces damage to the film 112Bf due to overheating.

For example, the film 183Bf can be formed using a metal or a metal compound such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the metal or the metal compound, in place of gallium, an element M (Mis one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The film 183Bf is preferably formed using a semiconductor material such as silicon or germanium for excellent compatibility with a semiconductor manufacturing process. Alternatively, a compound including the above semiconductor material can be used.

For example, any of a variety of inorganic insulating films can be used as the film 183Bf. An oxide insulating film, a nitride insulating film, or the like can be used, for example.

The film 181Bf and the film 183Bf are each preferably formed using a material different from that for the partition 120m1. Specifically, for example, the materials for the film 181Bf, the film 183Bf, and the partition 120 are preferably selected so as not to reduce the thickness of the partition 120m1 in etching for removing the film 181Bf and the film 183Bf in a later step.

Note that a structure without the film 181Bf can also be employed. For example, in the case where the film 183Bf is formed by a formation method that causes less damage to the film 112Bf, specifically, by an ALD method or the like, the film 181Bf can be omitted. An ALD method with high coverage enables formation of a layer 183 having few pinholes and an excellent function of protecting the film 181Bf. When an ALD method with high coverage is used for the formation of the film 181Bf, the side surface of the partition 120 can be favorably covered. As the film 181Bf formed by an ALD method, a film of aluminum oxide formed by an ALD method can be used, for example.

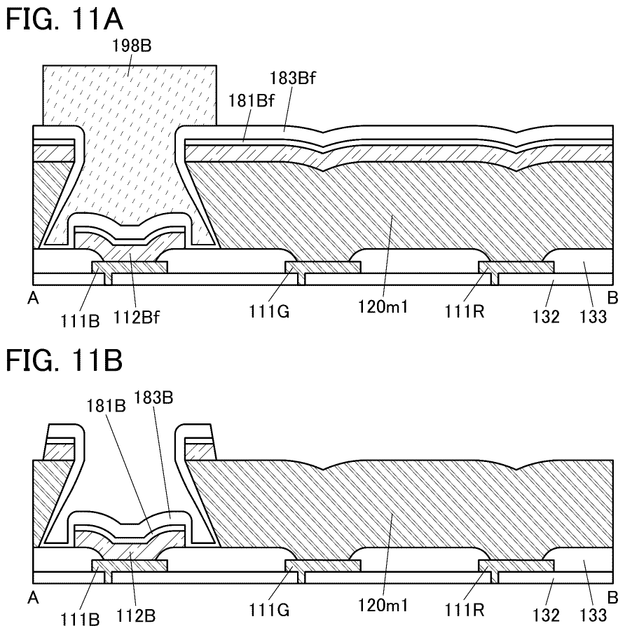

Next, a resist mask 198B is formed over the film 183Bf (FIG. 11A).

Subsequently, part of the film 183Bf is removed using the resist mask 198B, so that a layer 183B is formed. After that, the resist mask 198B is removed.

The layer 183B can function as a hard mask. Providing the layer 183B between the resist mask 198B and the film 181Bf can inhibit reduction in the thickness of the film 181Bf in the step of removing the resist mask and damage to the film 181Bf. The layer 183B is sometimes referred to as a mask layer, a sacrificial layer, or the like.

For the processing of the film 183Bf, a wet etching method or a dry etching method can be used. In the case of using a wet etching method, damage to the film 112Bf in the processing of the film 183Bf can be reduced as compared with the case of using a dry etching method. In the case of using a dry etching method in the processing of the film 183Bf, deterioration of the film 112Bf can be inhibited by not using a gas containing oxygen as the etching gas.

In the case where the film 183Bf includes an In—Ga—Zn oxide layer, the In—Ga—Zn oxide layer can be processed using a chemical solution containing phosphoric acid, for example.

The resist mask 198B can be removed by ashing using oxygen plasma, for example.

Next, part of the film 181Bf and part of the film 112Bf are removed using the layer 183B as a mask, so that the first EL layer 112B and a layer 181B over the first EL layer 112B are formed over the pixel electrode 111B (FIG. 11B). The layer 181B is sometimes referred to as a mask layer, a sacrificial layer, or the like.

Note that in consideration of misalignment in patterning, the resist mask 198B is preferably formed to overlap with part of the top surface of the partition 120. Thus, the film 112Bf, the film 181Bf, and the film 183Bf remain also over the partition 120.

For the processing of the film 181Bf, a wet etching method or a dry etching method can be used. Note that the film 181Bf is also etched in some cases in the etching treatment of the film 183Bf.

Note that in the case where a material usable for the upper layer of the EL layer is used for the film 181Bf, the film 181Bf is not etched or part of the film 181Bf can remain over the first EL layer 112. The material usable for the upper layer of the EL layer is, for example, a material usable for the upper layer of the first EL layer 112 or a material usable for the second EL layer.

The film 112Bf is preferably processed by anisotropic etching. Anisotropic dry etching is particularly preferable. Alternatively, wet etching may be used.

In the case of using a dry etching method, deterioration of the film 112Bf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Accordingly, damage to the part of the film 112Bf can be inhibited. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

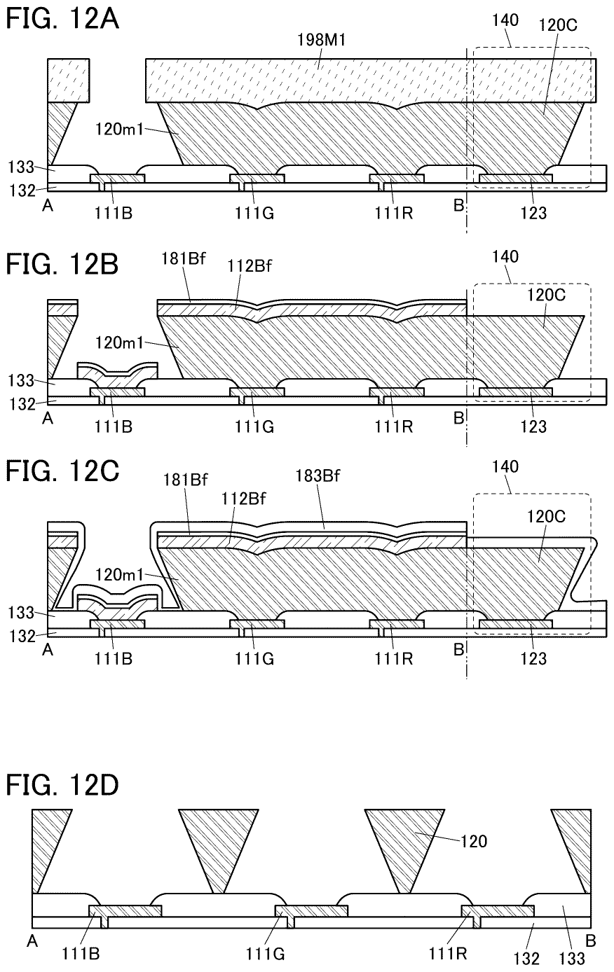

As shown in FIG. 12A, by processing part of the conductive film 120f, a conductive layer 120C can remain over a conductive layer 123 in a connection portion 140. The conductive layer 123 can be formed by processing a conductive film to be the pixel electrode 111. The step shown in FIG. 12A corresponds to the above-described step in FIG. 9A.

The connection portion 140 is formed to surround the display portion and is electrically connected to the upper electrode 115 formed later. The connection portion 140 is referred to as a cathode contact portion in some cases.

As shown in FIG. 12B, the film 112Bf and the film 181Bf are preferably not formed over the conductive layer 120C. The step shown in FIG. 12B corresponds to the above-described step in FIG. 10A. For example, when a mask for defining a film formation area (also referred to as an area mask, a rough metal mask, or the like to be distinguished from a fine metal mask) is used, the film 112Bf and the film 181Bf can be formed in a desired region. Employing a film formation step using an area mask and a processing step using a resist mask enables a light-emitting device to be manufactured by a relatively easy process.

As shown in FIG. 12C, the film 183Bf is also formed over the conductive layer 120C. The step shown in FIG. 12C corresponds to the above-described step shown in FIG. 10B.

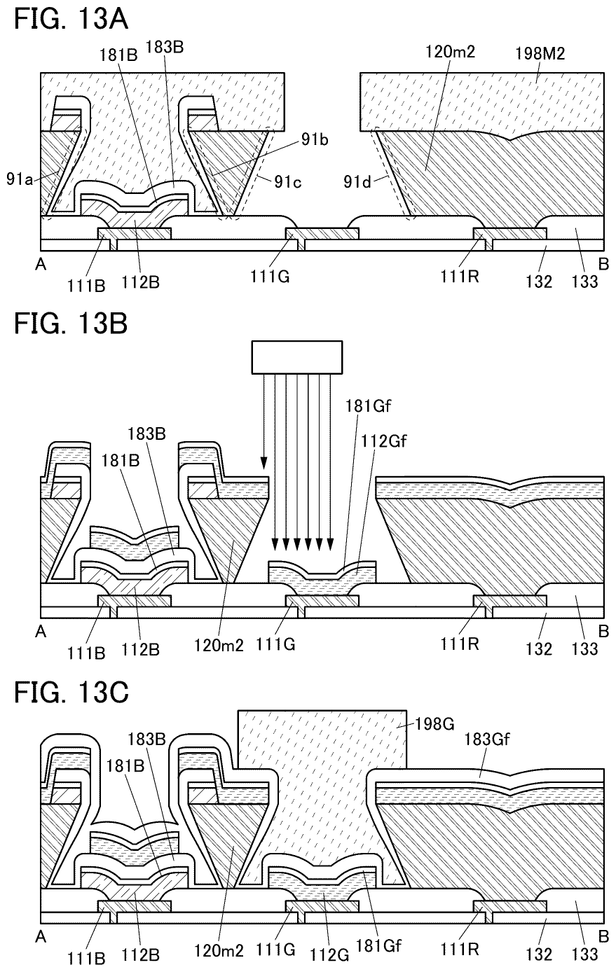

Next, a resist mask 198M2 is formed over the partition 120m1. The resist mask 198M2 has an opening portion overlapping with the pixel electrode 111G. Subsequently, a portion of the partition 120m1 that is not covered with the resist mask 198M2 is removed by etching to form a partition 120m2 (FIG. 13A). The partition 120m2 includes portions that are formed to surround the pixel electrode 111G. Then, the resist mask 198M2 is removed. In other words, the partition 120m2 is in a state where a region of the partition 120m1 overlapping with the pixel electrode 111G and part of a region of the partition 120m1 overlapping with the insulating layer 133 are removed. In the etching of the partition 120m1, part of the insulating layer 133 positioned between the light-emitting element 110G and a light-emitting element adjacent to the light-emitting element 110G is removed, for example.

Side surfaces of the partition 120m2 that surround the pixel electrode 111G are formed. FIG. 13A shows an example in which the partition 120m2 has a side surface 91c and a side surface 91d. In a plan view, the pixel electrode 111G is sandwiched between the side surface 91c and the side surface 91d. The side surface 91c faces the side surface 91b.

For the etching treatment of the partition 120m1, the etching treatment of the conductive film 120f can be referred to.

Next, a film 112Gf to be the first EL layer 112G is formed over the layer 183B, the pixel electrode 111G, and the partition 120m2. Subsequently, a film 181Gf is formed (FIG. 13B). The film 181Gf has a function of protecting the film 112Gf. The film 181Gf is not necessarily formed. At this time, the film 112Gf is disconnected by the partition 120m2 and is formed over the partition 120m2 and in a region surrounded by the partition 120m2. For the method for forming the film 112Gf, the method for forming the film 112Bf can be referred to.

The film 112Gf includes a first portion over the pixel electrode 111G and a second portion over the partition 120m2, and the first portion and the second portion are separated from each other. The first portion can function as the first EL layer 112G.

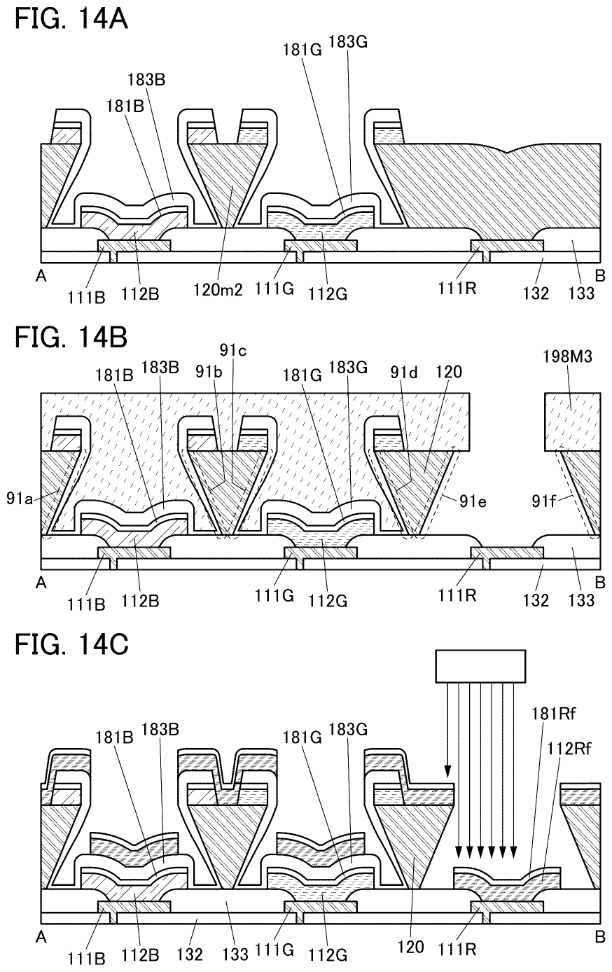

Next, a film 183Gf is formed. Then, a resist mask 198G is formed over the film 183Gf (FIG. 13C). Subsequently, a layer 183G is formed and the resist is removed, and then the layer 183G and the first EL layer 112G are formed using the layer 183G as a mask (FIG. 14A). Here, the layer 183G is provided to cover the film 112Gf and the film 181Gf remaining over the partition 120m2 in some cases.

Next, a resist mask 198M3 is formed over the partition 120m2. The resist mask 198M3 has an opening portion overlapping with the pixel electrode 111R. Subsequently, a portion of the partition 120m2 that is not covered with the resist mask 198M3 is removed by etching to form the partition 120 (FIG. 14B). In other words, the partition 120 is in a state where a region of the partition 120m2 overlapping with the pixel electrode 111R and part of a region of the partition 120m2 overlapping with the insulating layer 133 are removed. In the etching of the partition 120m2, part of the insulating layer 133 positioned between the light-emitting element 110R and a light-emitting element adjacent to the light-emitting element 110R is removed, for example. The partition 120 includes portions that are formed to surround the pixel electrode 111R. Then, the resist mask 198M3 is removed.

Side surfaces of the partition 120 that surround the pixel electrode 111R are formed. FIG. 14B shows an example in which the partition 120 includes a side surface 91e and a side surface 91f. In a plan view, the pixel electrode 111R is sandwiched between the side surface 91e and the side surface 91f. The side surface 91e faces the side surface 91d.

For the etching treatment of the partition 120m2, the etching treatment of the conductive film 120f can be referred to.

Next, a film 112Rf to be the first EL layer 112R is formed over the layer 183B, the layer 183G, the pixel electrode 111R, and the partition 120. Subsequently, a film 181Rf is formed (FIG. 14C). At this time, the film 112Rf is disconnected by the partition 120 and is formed over the partition 120 and in a region surrounded by the partition 120. For the method for forming the film 112Rf, the method for forming the film 112Bf can be referred to.

The film 112Rf includes a first portion over the pixel electrode 111R and a second portion over the partition 120, and the first portion and the second portion are separated from each other. The first portion can function as the first EL layer 112R.

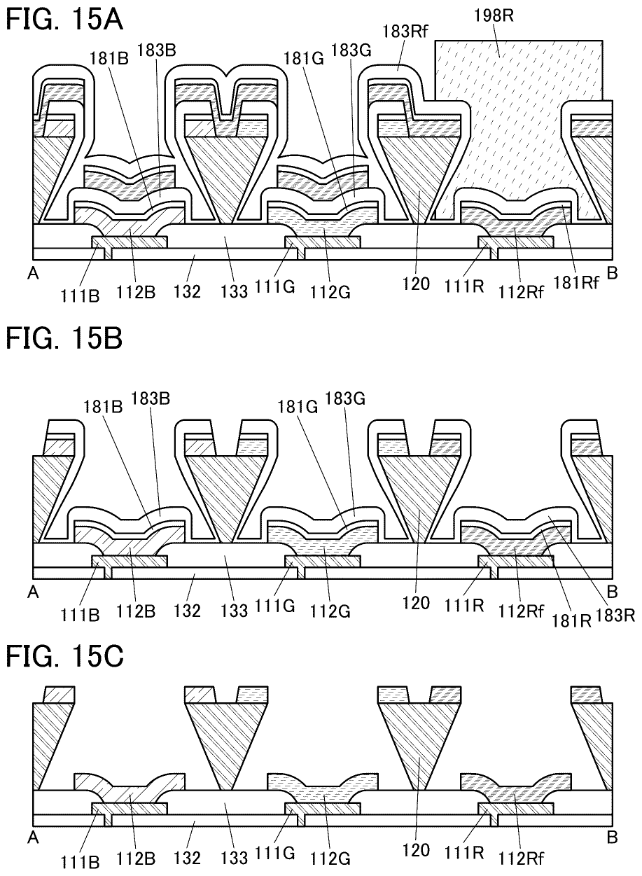

Next, a film 183Rf is formed. Then, a resist mask 198R is formed over the film 183Rf (FIG. 15A). Subsequently, a layer 183R is formed and the resist is removed, and then a layer 181R and the first EL layer 112R are formed using the layer 183G as a mask (FIG. 15B).

Next, the layer 183B, the layer 183G, the layer 183R, the layer 181B, a layer 181G, and the layer 181R are removed (FIG. 15C). The layer 181 and the layer 183 are preferably removed by wet etching. In the case of using a wet etching method, damage to the first EL layer 112 can be reduced as compared with the case of using a dry etching method. The wet etching is preferably performed using an aqueous solution so that the first EL layer 112 is not dissolved; for example, an alkaline solution or an acidic solution can be used.

Through the above steps, the pixel electrode 111, the first EL layer 112 over the pixel electrode, and the partition 120 can be formed.

Next, the upper electrode 115 is formed, whereby the display device of one embodiment of the present invention including a plurality of light-emitting elements over a substrate can be formed.

Note that the above manufacturing method shows an example in which the conductive film 120f is processed through the following three steps: the step shown in FIG. 9B for forming the partition 120 in a region that surrounds the pixel electrode 111B; the step shown in FIG. 13A for forming the partition 120 in a region that surrounds the pixel electrode 111G; and the step shown in FIG. 14B for forming the partition 120 in a region that surrounds the pixel electrode 111R. In the above steps, as shown in FIGS. 11A and 11B, the partition 120m1 over the pixel electrode 111G and the pixel electrode 111R does not have an opening portion, a dent, or the like and is flat.

In the film 112Bf, the film 181Bf, and the film 183Bf, regions overlapping with the pixel electrode 111G and the pixel electrode 111R are removed in the steps shown in FIGS. 11A and 11B. These films are formed over flat regions and thus can be easily etched. In the etching, the pixel electrode 111G and the pixel electrode 111R are covered with the partition 120m1 and are not exposed. Thus, the pixel electrode 111G and the pixel electrode 111R are not exposed in the steps of removing the film 112Bf, the film 181Bf, and the film 183Bf.

Meanwhile, as shown in FIG. 12D, the partition 120 may be formed in the same step in the region that surrounds pixel electrode 111B, the region that surrounds the pixel electrode 111G, and the region that surrounds the pixel electrode 111R in the conductive film 120f. In such a case, the number of masks used in the manufacturing process can be reduced, and the productivity can be increased.

However, in the case of using the step shown in FIG. 12D, the partition 120 has opening portions in regions overlapping with the pixel electrode 111G and the pixel electrode 111R; thus, the pixel electrode 111G and the pixel electrode 111R are exposed by the steps of removing the film 112Bf, the film 181Bf, and the film 183Bf. Depending on the etching conditions of the film 112Bf, the film 181Bf, and the film 183Bf, for example, the pixel electrode 111G or the pixel electrode 111R is exposed in the etching step before the film 112Gf or the film 112Rf is formed over the top surface of the pixel electrode 111G or the top surface of the pixel electrode 111R, which might affect the characteristics of the light-emitting element. Specifically, for example, damage due to etching might be caused. Alternatively, in the wet etching, a by-product of the etching might remain over the pixel electrode 111G or the pixel electrode 111R at the time of removing a region having a dent. Thus, in the case of employing the step shown in FIG. 12D, for example, the etching of the film 183Bf and the film 181Bf are preferably performed by etching treatment in which the films are easily etched and less likely to be damaged.

<Layer 112aB and Layer 112bB>

In the case where the first EL layer 112B includes the layer 112aB and the layer 112bB and an end portion of the layer 112bB is positioned outward from an end portion of the layer 112aB, the layer 112aB is preferably formed by a highly anisotropic film formation method.

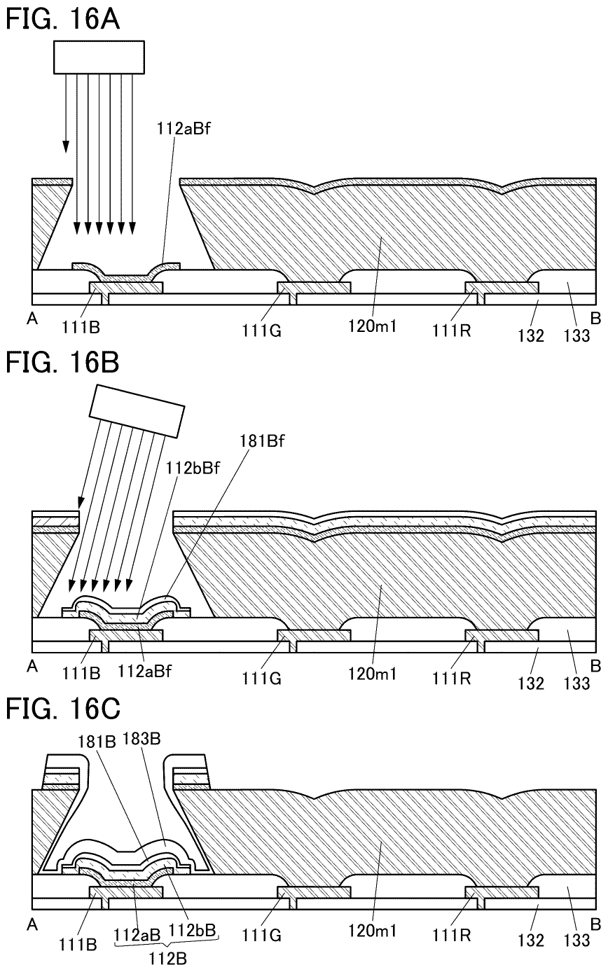

A method for forming the layer 112aB and the layer 112bB is described with reference to FIGS. 16A to 16C.

First, a film 112aBf is formed (FIG. 16A). The film 112aBf is a film to be the layer 112aB. The film 112aBf is preferably formed by a highly anisotropic film formation method. In that case, a sufficient space for the upper electrode 115 to enter is preferably provided between the film 112aBf and the partition 120m1. The film 112aBf can be formed by a vacuum evaporation method, a sputtering method, or both of them, for example.

As a highly anisotropic film formation method, for example, as shown in FIG. 20A, the film formation is preferably performed such that the angle β formed between the substrate surface and the travelling direction of the film formation material 121 is substantially perpendicular to the top surface of the substrate 101. In this manner, disconnection can be caused by the partition 120 as shown in FIG. 20B.

Next, a film 112bBf is formed over the film 112aBf and the partition 120m1 (FIG. 16B). At this time, the film 112bBf is disconnected by the partition 120m1 and is formed over the partition 120m1 and in a region surrounded by the partition 120m1. The film 112bBf is a film to be the layer 112bB. The film 112bBf can be formed by a vacuum evaporation method, a sputtering method, or both of them, for example.

The film 112bBf is preferably formed to cover a side surface of the film 112aBf. Meanwhile, the film 112bBf is preferably formed not to cover the side surface of the partition 120m1. Thus, the film formation method used for the film 112bBf preferably has lower anisotropy than the film formation method used for the film 112aBf and higher anisotropy than a film formation method used for the upper electrode 115. The film formation method used for the upper electrode 115 will be described later.

Next, the layer 183B, the layer 181B, and the first EL layer 112B are formed (FIG. 16C).

### <Formation of Upper Electrode>

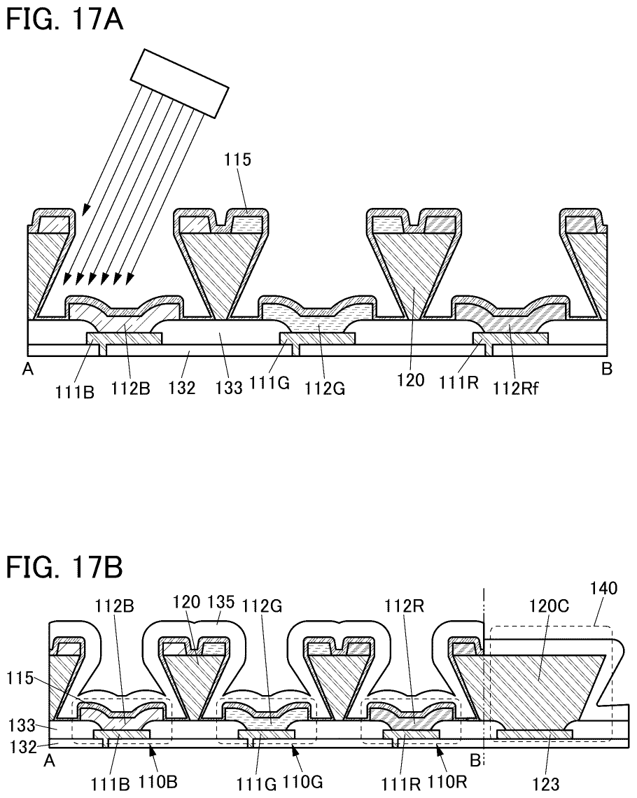

A method for forming the upper electrode 115 or the like is described with reference to FIG. 17A.

The upper electrode 115 is formed after the pixel electrode 111 and the first EL layer over the pixel electrode 111 are formed through the steps shown in FIGS. 9A to 9F, FIGS. 10A to 10C, FIGS. 11A and 11B, FIGS. 12A to 12D, FIGS. 13A to 13C, FIGS. 14A to 14C, and FIGS. 15A to 15C. Specifically, the upper electrode 115 is formed over the first EL layer 112B, the first EL layer 112G, the first EL layer 112R, and the partition 120 (FIG. 17A). The upper electrode 115 can be formed by one or more of a vacuum evaporation method, a sputtering method, and a CVD method. Furthermore, the upper electrode 115 preferably includes a portion in contact with the top surface of the insulating layer 133.

The upper electrode 115 is preferably formed by a less anisotropic film formation method than that for the EL layer 112. It is preferable to employ a film formation method in which the travelling direction of the film formation material of the upper electrode 115 includes not only a component perpendicular to the top surface of the substrate but also a component oblique thereto. A low-anisotropy film formation method can be obtained by, for example, decreasing the distance between an evaporation source (or a sputtering target) and the substrate, using a plurality of evaporation sources (or sputtering targets), or increasing the area of an evaporation source (or a sputtering target).

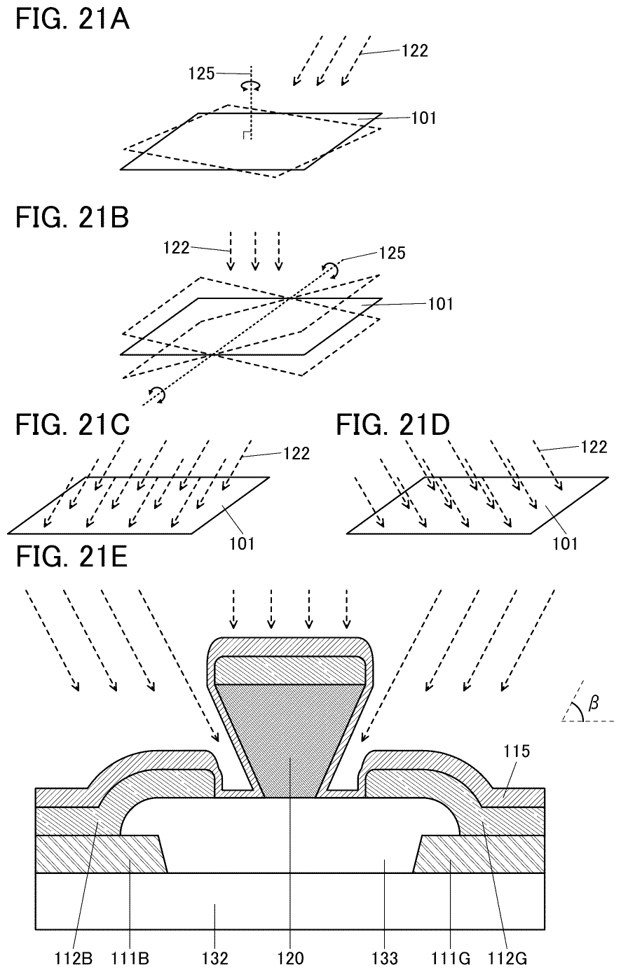

Alternatively, it is possible to use a film formation apparatus including a mechanism by which a film formation material 122 travels in a direction oblique to the top surface of the substrate 101 and the substrate 101 rotates on a rotation axis 125 as shown in FIG. 21A. At this time, the angle β formed between the substrate surface and the travelling direction of the film formation material is less than 90°. Although FIG. 21A shows an example in which the rotation axis 125 passes through the center of the substrate 101, the rotation axis 125 may pass through any point on the substrate 101 or may be positioned outside the substrate 101. The rotation axis 125 is not necessarily perpendicular to the surface of the substrate 101.

In the case where the first EL layer 112 includes the layer 112a and the layer 112b and an end portion of the layer 112b is positioned outward from an end portion of the layer 112a, the angle β formed between the substrate surface and the travelling direction of the film formation material of the layer 112b is smaller than the angle β formed between the substrate surface and the travelling direction of the film formation material of the layer 112a and larger than the angle β formed between the substrate surface and the travelling direction of the film formation material of the upper electrode 115, for example.

Alternatively, it is possible to use a film formation apparatus including a mechanism by which the substrate 101 rotates (or swings) on the rotation axis 125 that is parallel to the substrate surface as shown in FIG. 21B. In this case, the film formation material 122 can travel in a direction perpendicular to the rotation axis 125.

With the use of a film formation apparatus including a mechanism like those shown in FIGS. 21A and 21B, the film formation process for the upper electrode 115 can include a period in which the film formation material 122 travels toward the surface of the substrate 101 in an oblique direction as shown in FIG. 21C and a period in which the film formation material 122 travels in the symmetrically opposite oblique direction as shown in FIG. 21D. Thus, the upper electrode 115 can also be formed on the side surface of the partition 120 having an inverse tapered shape, as shown in FIG. 21E.

Although the cases where the substrate 101 moves are described above as examples, the evaporation source may be moved, or both the substrate 101 and the evaporation source may be moved.

In the formation of the upper electrode 115, the angle β formed between the substrate surface and the travelling direction of the film formation material is smaller than the angle β formed between the substrate surface and the travelling direction of the film formation material of each of the first EL layer 112R, the first EL layer 112G, and the first EL layer 112B, for example.

Next, the protective layer 135 is formed to cover the upper electrode 115 (FIG. 17B). Note that FIG. 17B shows a cross section of the connection portion 140 in addition to a cross section corresponding to line A-B.

The protective layer 135 is preferably formed by a film formation method that provides high step coverage, and is preferably formed by a CVD method or an ALD method. In particular, an ALD method is preferable because of less film formation damage to a layer on which a film is formed.

For example, an aluminum oxide film can be formed as the protective layer 135 by an ALD method. In that case, as a precursor containing aluminum, trimethylaluminum, triethylaluminum, triisobutylaluminum, dimethylaluminum hydride, tris(dimethylamino)aluminum, tris(diethylamino)aluminum, aluminum trichloride, or the like is preferably used. As the oxidizer, any one or two or more of ozone (O₃), oxygen (O₂), water (H₂O), nitrogen dioxide (NO₂), dinitrogen monoxide (N₂O), and hydrogen peroxide (H₂O₂) can be used, for example.

The protective layer 135 may have a stacked-layer structure of a film formed by an ALD method and a film formed by a film formation method other than an ALD method (e.g., a CVD method or a sputtering method). An ALD method provides extremely high step coverage but has a lower film formation rate than other film formation methods; the time taken for the film formation step for the protective layer 135 can be shortened by first forming a film with extremely few defects by an ALD method and then forming a thick insulating film by a CVD method or the like.

### <Formation of Second EL Layer and Upper Electrode>

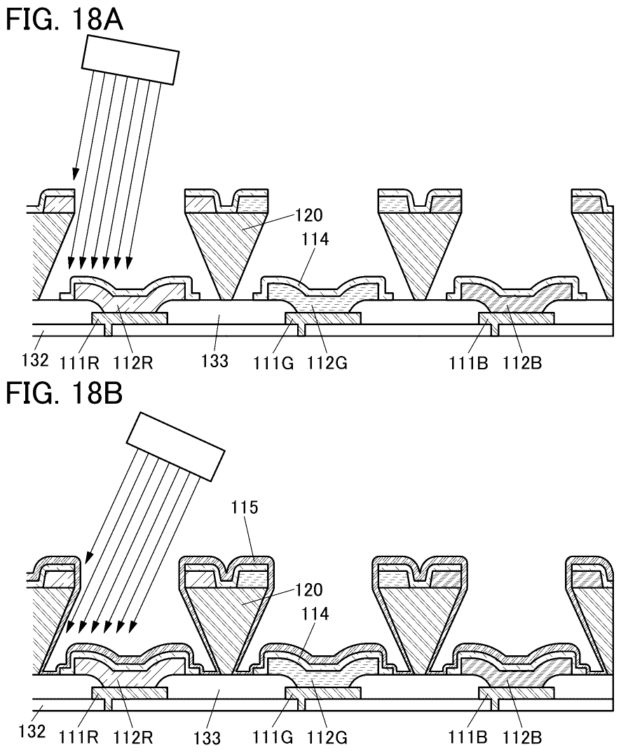

In the case where the light-emitting element includes the second EL layer, the second EL layer is formed before the upper electrode is formed. A method for forming the second EL layer, the upper electrode, and the like is described with reference to FIGS. 18A and 18B.

After the steps shown in FIGS. 7A to 7C, FIG. 8A to 8C, FIGS. 9A to 9F, FIGS. 10A to 10C, FIGS. 11A and 11B, and FIGS. 12A to 12C are performed, the pixel electrode 111 and the first EL layer over the pixel electrode 111 are formed, and then the second EL layer 114 is formed. Specifically, the second EL layer 114 is formed over the first EL layer 112B, the first EL layer 112G, the first EL layer 112R, and the partition 120 (FIG. 18A). The second EL layer 114 can be formed by a vacuum evaporation method, a sputtering method, or both of them, for example.

The second EL layer 114 is preferably formed to cover the side surfaces of the first EL layer 112B, the first EL layer 112G, and the first EL layer 112R. Meanwhile, the second EL layer 114 is preferably formed not to cover the side surface of the partition 120. Thus, the film formation method used for the second EL layer 114 preferably has lower anisotropy than the film formation method used for the first EL layer 112B, the first EL layer 112G, and the first EL layer 112R and higher anisotropy than the film formation method used for the upper electrode 115.

Next, the upper electrode 115 is formed (FIG. 18B). At this time, the upper electrode 115 is formed to cover end portions of the second EL layer 114 and to be in contact with at least part of the side surface of the partition 120. The upper electrode 115 can be formed by one or more of a vacuum evaporation method, a sputtering method, and a CVD method.

The upper electrode 115 is preferably formed by a less anisotropic film formation method than those for the first EL layer 112 and the second EL layer 114. It is preferable to employ a film formation method in which the travelling direction of the film formation material of the upper electrode 115 includes not only a component perpendicular to the top surface of the substrate but also a component oblique thereto. A low-anisotropy film formation method can be obtained by, for example, decreasing the distance between an evaporation source (or a sputtering target) and the substrate, using a plurality of evaporation sources (or sputtering targets), or increasing the area of an evaporation source (or a sputtering target).

Alternatively, it is possible to use a film formation apparatus including a mechanism by which the film formation material 122 travels in a direction oblique to the top surface of the substrate 101 and the substrate 101 rotates on the rotation axis 125 as shown in FIG. 21A. At this time, the angle β formed between the substrate surface and the travelling direction of the film formation material is less than 90°. Although FIG. 17A shows an example in which the rotation axis 125 passes through the center of the substrate 101, the rotation axis 125 may pass through any point on the substrate 101 or may be positioned outside the substrate 101. The rotation axis 125 is not necessarily perpendicular to the surface of the substrate 101.

Alternatively, it is possible to use a film formation apparatus including a mechanism by which the substrate 101 rotates (or swings) on the rotation axis 125 that is parallel to the substrate surface as shown in FIG. 21B. In this case, the film formation material 122 can travel in a direction perpendicular to the rotation axis 125.

With the use of a film formation apparatus including a mechanism like those shown in FIGS. 21A and 21B, the film formation process for the upper electrode 115 can include a period in which the film formation material 122 travels toward the surface of the substrate 101 in an oblique direction as shown in FIG. 21C and a period in which the film formation material 122 travels in the symmetrically opposite oblique direction as shown in FIG. 21D. Thus, the upper electrode 115 can also be formed on the side surface of the partition 120 having an inverse tapered shape, as shown in FIG. 21E. Note that for simplification of the drawing, the second EL layer 114 is not shown in FIG. 21E.

Although the cases where the substrate 101 moves are described above as examples, the evaporation source may be moved, or both the substrate 101 and the evaporation source may be moved.

In the formation of the second EL layer 114, the angle β formed between the substrate surface and the travelling direction of the film formation material is smaller than the angle β formed between the substrate surface and the travelling direction of the film formation material of each of the first EL layer 112R, the first EL layer 112G, and the first EL layer 112B and larger than the angle β formed between the substrate surface and the travelling direction of the film formation material of the upper electrode 115, for example.

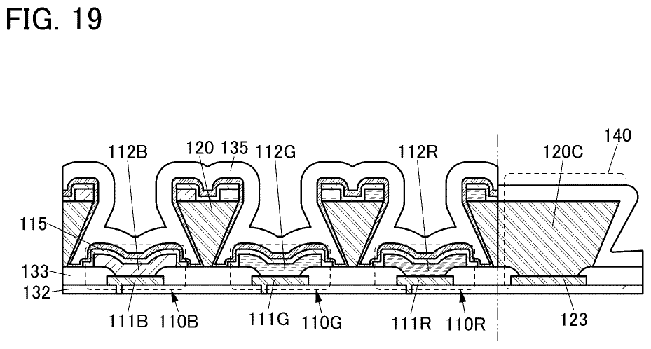

Next, the protective layer 135 is formed to cover the upper electrode 115. Note that FIG. 19 shows a cross section of the connection portion 140 in addition to a cross section corresponding to line A-B. The protective layer 135 is preferably formed by a film formation method that provides high step coverage, and is preferably formed by a CVD method or an ALD method. In particular, an ALD method is preferable because of less film formation damage to a layer on which a film is formed.

For example, an aluminum oxide film can be formed as the protective layer 135 by an ALD method. In that case, as a precursor containing aluminum, trimethylaluminum, triethylaluminum, triisobutylaluminum, dimethylaluminum hydride, tris(dimethylamino)aluminum, tris(diethylamino)aluminum, aluminum trichloride, or the like is preferably used. As the oxidizer, any one or two or more of ozone (O₃), oxygen (O₂), water (H₂O), nitrogen dioxide (NO₂), dinitrogen monoxide (N₂O), and hydrogen peroxide (H₂O₂) can be used, for example.

The protective layer 135 may have a stacked-layer structure of a film formed by an ALD method and a film formed by a film formation method other than an ALD method (e.g., a CVD method or a sputtering method). An ALD method provides extremely high step coverage but has a lower film formation rate than other film formation methods; the time taken for the film formation step for the protective layer 135 can be shortened by first forming a film with extremely few defects by an ALD method and then forming a thick insulating film by a CVD method or the like.

Through the above-described steps, the display device 100 can be manufactured.

### [Example of Film Formation Apparatus]

Described below are examples of film formation apparatuses capable of forming an EL layer, an upper electrode, and a protective layer successively without exposure to the air. The film formation apparatuses described below as examples can be used as manufacturing apparatuses for a display device. The film formation apparatus described below as an example can be used to form the first EL layer 112, the second EL layer 114, the upper electrode 115, and the protective layer 135 for each of the light-emitting elements 110.

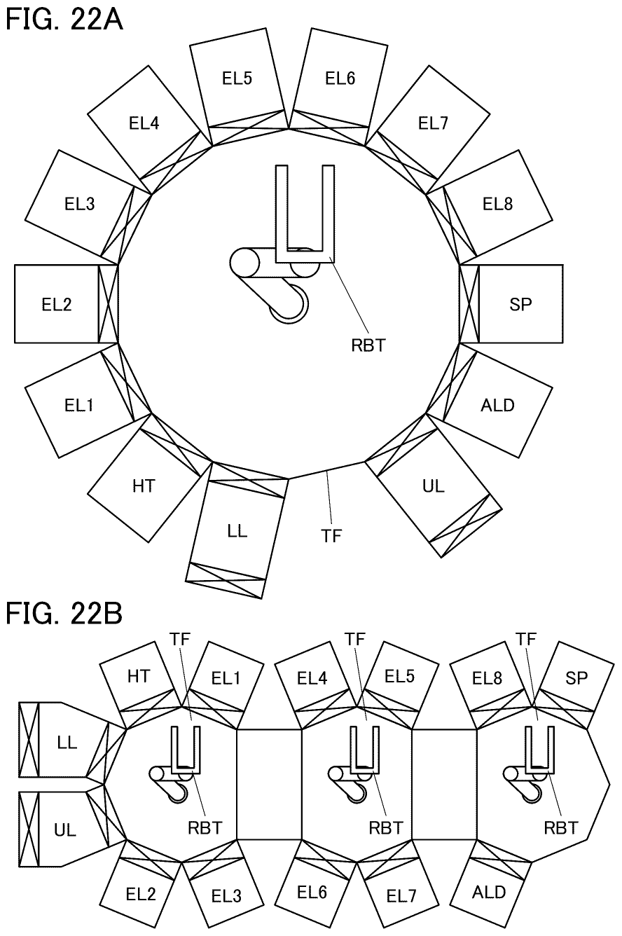

FIG. 22A is a schematic view of a film formation apparatus. The film formation apparatus includes a loading chamber LL, an unloading chamber UL, a treatment chamber HT, film formation chambers EL1 to EL8, a film formation chamber ALD, and a film formation chamber SP around a transfer chamber TF. The transfer chamber TF includes a transfer robot RBT, and the transfer robot RBT can load and unload the substrate 101 into and from each chamber.

The transfer chamber TF and each chamber are connected to a vacuum pump and are kept under reduced pressure. A gate valve is provided between the transfer chamber TF and each chamber to separately control the atmosphere, e.g., the pressure or the temperature, of each chamber.

The loading chamber LL is a chamber for loading the substrate 101, and the unloading chamber UL is a chamber for unloading the substrate 101. The loading chamber LL and the unloading chamber UL are each provided with a gate valve that connects to the outside.

In the treatment chamber HT, treatment for heating the substrate 101 can be performed. The treatment chamber HT includes a baking apparatus. For example, a hot plate baking apparatus or a baking apparatus including a resistive heater or an infrared lamp may be used.

In the film formation chambers EL1 to EL8, films included in the EL layer 112 can be formed. The film formation chambers EL1 to EL8 each include a vacuum evaporation apparatus or a sputtering apparatus, for example.

For example, the film formation chamber EL1 includes an apparatus for forming a hole-injection layer; the film formation chamber EL2, a hole-transport layer; the film formation chamber EL3, an electron-blocking layer; the film formation chamber EL4, a light-emitting layer; the film formation chamber EL5, a hole-blocking layer; the film formation chamber EL6, an electron-transport layer; the film formation chamber EL7, an electron-injection layer; and the film formation chamber EL8, a charge-generation layer. The film formation chambers EL1 to EL8 each preferably include an apparatus for forming the mask layer described above. For example, in the case where the electron-transport layer is the uppermost layer of the first EL layer 112, the film formation chamber EL6 includes an apparatus for forming the electron-transport layer and a mask layer. Since the electron-transport layer is formed and then the mask layer is formed over the electron-transport layer in the film formation chamber EL6, a top surface of the first EL layer 112 can be prevented from being exposed to the air.

In the film formation chamber SP, the upper electrode 115 can be formed. For example, the film formation chamber SP includes a sputtering apparatus.

In the film formation chamber ALD, the layer 183 and the protective layer 135 can be formed. For example, the film formation chamber ALD includes an ALD apparatus.

Although FIG. 22A shows an example in which one transfer chamber TF is provided, a plurality of transfer chambers TF may be joined together. FIG. 22B shows an example in which three transfer chambers TF are joined. Each of the transfer chambers TF is provided with one transfer robot RBT. In the example shown in FIG. 22B, each of the transfer chambers TF can be connected to four to six chambers excluding the loading chamber LL and the unloading chamber UL. In FIG. 22B, up to three more chambers can be provided depending on the application.

Next, an example of a film formation method using either of the film formation apparatuses is described. First, the substrate 101 provided with components up to the partition 120 as shown in FIG. 22B is loaded into the film formation apparatus from the loading chamber LL, and heat treatment is performed in the treatment chamber HT. Through this heat treatment, moisture or the like adsorbed on the surface can be removed. Next, the hole-injection layer, the hole-transport layer, the electron-blocking layer, the light-emitting layer, the hole-blocking layer, the electron-transport layer, and the electron-injection layer are sequentially formed in the film formation chambers EL1 to EL7. Then, the upper electrode is formed in the film formation chamber SP. Subsequently, the protective layer 135 is formed in the film formation chamber ALD, and then the substrate 101 is unloaded to the outside from the unloading chamber UL. In the above manner, the first EL layer 112, the second EL layer 114, the upper electrode 115, and the protective layer 135 can be formed successively without exposure of the substrate 101 to the air.

The above-described film formation apparatus can also be used to form a light-emitting element having what is called a tandem structure, which includes a plurality of light-emitting layers with a charge-generation layer(s) therebetween.

First, as described above, after heat treatment is performed in the treatment chamber, the substrate 101 is sequentially transferred to the film formation chambers EL1 to EL7, so that hole-injection to electron-injection layers are sequentially formed. Next, a charge-generation layer is formed in the film formation chamber EL8. After that, hole-injection to electron-injection layers are sequentially formed again in the film formation chambers EL1 to EL7. Then, as described above, the upper electrode 115 is formed in the film formation chamber SP, the protective layer 135 is formed in the film formation chamber ALD, and the substrate 101 is unloaded from the unloading chamber UL. This makes it possible to manufacture a light-emitting element having a two-unit tandem structure in which the two light-emitting layers are stacked with the charge-generation layer therebetween.

In the film formation chamber EL8, at least one layer included in the charge-generation layer is formed. At least one of the electron-injection layer and the hole-injection layer formed before and after the film formation step in the film formation chamber EL8 can also serve as a layer included in the charge-generation layer. For example, in the case where the charge-generation layer has a stacked-layer structure of an electron-injection buffer layer, an electron-relay layer, and a p-type layer, the electron-injection layer may have a function of the electron-injection buffer layer, and the hole-injection layer may have a function of the p-type layer. In that case, the electron-relay layer may be formed in the film formation chamber EL8.

In the case of manufacturing a light-emitting element having an N-unit tandem structure (N is a natural number greater than or equal to 2), the film formation in the film formation chambers EL1 to EL8 is repeated N−1 times, the film formation in the film formation chamber EL8 is omitted for the last N-th time, and then the upper electrode 115 and the protective layer 135 are formed.

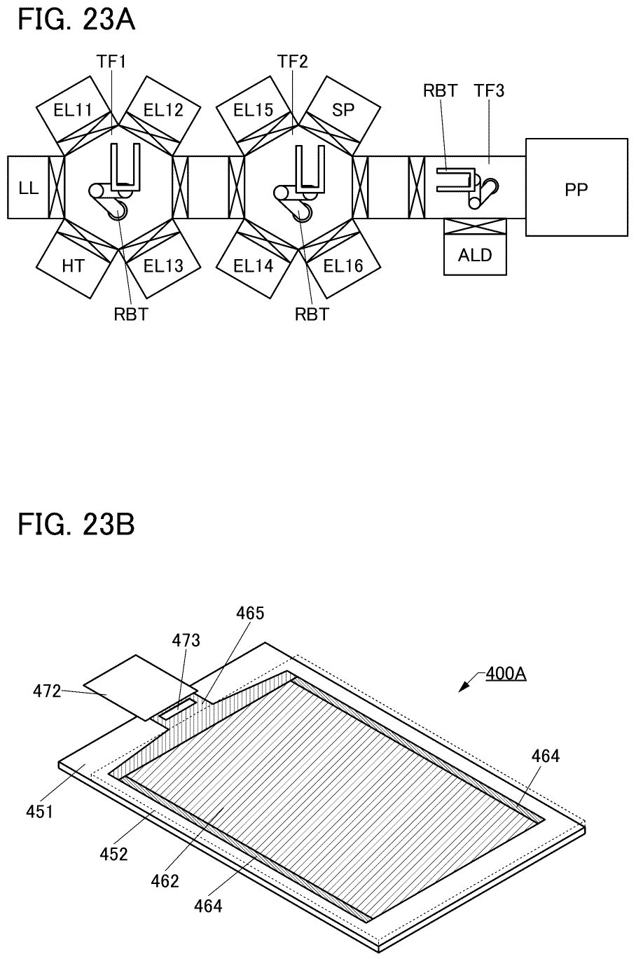

FIG. 23A shows a structure example of a film formation apparatus different from the above. The film formation apparatus shown in FIG. 23A has a structure in which three transfer chambers (a transfer chamber TF1, a transfer chamber TF2, and a transfer chamber TF3) are joined.

The transfer chamber TF1 is connected to the loading chamber LL, three film formation chambers (a film formation chamber EL11, a film formation chamber EL12, and a film formation chamber EL13), and the treatment chamber HT. The transfer chamber TF2 is connected to four film formation chambers (a film formation chamber EL14, a film formation chamber EL15, a film formation chamber EL16, and the film formation chamber SP). The transfer chamber TF3 is connected to the film formation chamber ALD and a treatment chamber PP that performs later steps such as sealing. In the structure shown in FIG. 23A, the loading chamber LL also serves as the unloading chamber, and a substrate can be loaded and unloaded through the loading chamber LL.

The film formation chambers EL11 to EL16 each include a vacuum evaporation apparatus, and an organic film or an inorganic film can be formed. The above description can be referred to for the film formation chamber SP, the film formation chamber ALD, the treatment chamber HT, and the like.

Here, the transfer chamber TF1 and the transfer chamber TF2 preferably have a reduced-pressure atmosphere. Meanwhile, the transfer chamber TF3 preferably has an atmospheric pressure atmosphere or a pressured (positive pressure) atmosphere. The inside of the transfer chamber TF3 is preferably maintained in an atmosphere that contains an inert gas such as nitrogen or a noble gas as its main component and contains no water as much as possible.

A sealing apparatus included in the treatment chamber PP, an ALD apparatus included in the film formation chamber ALD, and the like sometimes perform treatment in a reduced-pressure atmosphere; however, the treatment does not require a vacuum degree as high as that for a vacuum evaporation apparatus in some cases. For example, while the vacuum evaporation apparatus keeps pressure inside its chamber reduced and performs film formation treatment in a reduced-pressure atmosphere, the ALD apparatus, the sealing apparatus, and the like greatly changes their pressure during the treatment in some cases. Thus, the transfer chamber TF3 does not need to set to a reduced-pressure atmosphere. The inside of the transfer chamber TF3 is preferably set to under positive pressure, in which case entry of minute dust from the outside can be prevented and thus the inside can be kept clean. Furthermore, the transfer chamber TF1 and the transfer chamber TF2 each have a structure that can withstand a high vacuum degree by using a metal member for the exterior, for example. Meanwhile, the transfer chamber TF3 does not require high airtightness, and thus can be formed using a lightweight member such as acrylic.

One or both of the treatment chamber PP and the transfer chamber TF3 may be provided with a mechanism for unloading the substrate. In that case, the substrate processed in the treatment chamber PP or the film formation chamber ALD does not need to be transferred to the transfer chamber TF1, the transfer chamber TF2, or the like in a reduced-pressure atmosphere again, so that the time for unloading the substrate can be shortened. At this time, it is preferable to use a container with high hermeticity, such as front opening unified pod (FOUP) or front opening shipping box (FOSB) for unloading the substrate, in which case the substrate can be transferred to an external apparatus without exposure to the air.

In the film formation apparatus shown in FIG. 23A, the substrate is loaded from the loading chamber LL; heat treatment is performed in the treatment chamber HT; thin films constituting the light-emitting elements are formed in the film formation chambers connected to the transfer chamber TF1 and the transfer chamber TF2; the substrate is transferred to the transfer chamber TF3; and then a protective film can be formed in the film formation chamber ALD. Since the substrate is not exposed to the air until the formation of the protective film in this manner, a light-emitting element with extremely high reliability can be manufactured. Furthermore, even after all the light-emitting elements are formed, processing can be successively performed without exposure of the substrate to the air between the step of forming a protective film in the film formation chamber ALD and the sealing step in the treatment chamber PP. This can prevent generation of a defect such as defective sealing due to dust and increase the manufacturing yield.

The above is the description of the film formation apparatuses and the film formation methods using the film formation apparatuses.

### Embodiment 2

In this embodiment, structure examples of the display device of one embodiment of the present invention will be described.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a smart phone, a wristwatch terminal, a tablet terminal, a portable information terminal, and an audio reproducing device, in addition to display portions of electronic devices with a relatively large screen, such as a television apparatus, a desktop or laptop personal computer, a monitor of a computer or the like, digital signage, and a large game machine like a pachinko machine.

### [Display Device 400A]

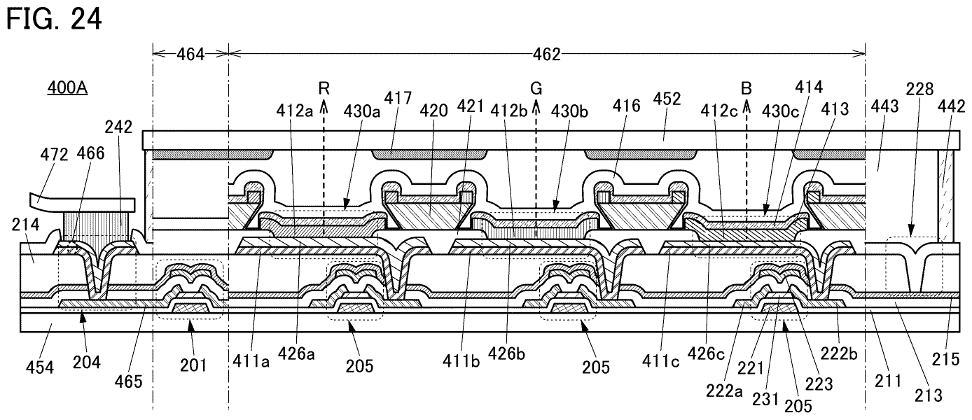

FIG. 23B is a perspective view of a display device 400A, and FIG. 24 is a cross-sectional view of the display device 400A.

In the display device 400A, a substrate 452 and a substrate 451 are bonded to each other. In FIG. 23B, the substrate 452 is denoted by a dashed line.

The display device 400A includes a display portion 462, a circuit 464, a wiring 465, and the like. FIG. 23B shows an example where an integrated circuit (IC) 473 and an FPC 472 are mounted on the display device 400A. Thus, the structure shown in FIG. 23B can be regarded as a display module including the display device 400A, the IC, and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 23B shows an example where the IC 473 is provided over the substrate 451 by a chip on glass (COG) method, a chip on film (COF) method, or the like. An IC including a scan line driver circuit, a signal line driver circuit, or the like can be used as the IC 473, for example. Note that the display device 400A and the display module are not necessarily provided with an IC. Alternatively, the IC may be mounted on the FPC by a COF method or the like.

FIG. 24 shows an example of cross sections of part of a region including the FPC 472, part of the circuit 464, part of the display portion 462, and part of a region including an end portion in the display device 400A.

The display device 400A includes a transistor 201, a transistor 205, a light-emitting element 430a which emits red light, a light-emitting element 430b which emits green light, a light-emitting element 430c which emits blue light, and the like between the substrate 451 and the substrate 452.

The light-emitting element exemplified in Embodiment 1 can be employed for the light-emitting element 430a, the light-emitting element 430b, and the light-emitting element 430c.

A protective layer 416 and the substrate 452 are bonded to each other with an adhesive layer 442. A solid sealing structure, a hollow sealing structure, or the like can be employed to seal the light-emitting elements. In FIG. 24, a hollow sealing structure is employed in which a space 443 surrounded by the substrate 452, the adhesive layer 442, and the substrate 451 is filled with an inert gas (e.g., nitrogen or argon). The adhesive layer 442 may overlap with the light-emitting element. The space 443 surrounded by the substrate 452, the adhesive layer 442, and the substrate 451 may be filled with a resin different from that of the adhesive layer 442.

FIG. 24 shows an example in which each light-emitting element 430 includes any one of a pixel electrode 411a, a pixel electrode 411b, and a pixel electrode 411c; any one of an island-shaped first EL layer 412a, an island-shaped first EL layer 412b, and an island-shaped first EL layer 412c which include light-emitting layers emitting light of different colors; and an upper electrode 414 over the first EL layers 412a, 412b, and 412c.

In the case where a pixel of the display device includes three kinds of subpixels including light-emitting elements emitting light of different colors, the three subpixels can be of three colors of R, G, and B or of three colors of yellow (Y), cyan (C), and magenta (M). In the case where four subpixels are included, the four subpixels can be of four colors of R, G, B, and white (W) or of four colors of R, G, B, and Y.

The light-emitting devices 430a, 430b, and 430c each have an optical adjustment layer between the pixel electrode and the EL layer. The light-emitting device 430a includes an optical adjustment layer 426a, the light-emitting device 430b includes an optical adjustment layer 426b, and the light-emitting device 430c includes an optical adjustment layer 426c. Embodiment 1 can be referred to for the details of the light-emitting elements. The optical adjustment layers 426 have different thicknesses. The optical adjustment layers 426 preferably contain the same material having a light-transmitting property and conductivity. For the optical adjustment layers 426, a conductive metal oxide film containing indium or zinc is preferably used.

The pixel electrodes 411a, 411b, and 411c are each electrically connected to a conductive layer 222b included in the transistor 205 through an opening provided in an insulating layer 214.

End portions of the pixel electrodes and the optical adjustment layers are covered with an insulating layer 421. The pixel electrodes contain a material that reflects visible light, and the counter electrodes contain a material that transmits visible light.

Light emitted from the light-emitting element is emitted to the substrate 452 side. For the substrate 452, a material having a high visible-light-transmitting property is preferably used.

A partition 420 is provided over the insulating layer 421. For the partition 420, the description of the partition 120 in Embodiment 1 can be referred to. The partition 420 is provided in a region overlapping with a light-blocking layer 417. Part of upper electrodes of two light-emitting elements adjacent to each other with the partition 420 therebetween and a layer containing the same material as the EL layers are provided over the partition 420. The protective layer 416 is provided to cover the partition 420.

The transistor 201 and the transistor 205 are formed over the substrate 451. These transistors can be manufactured using the same materials through the same process.

An insulating layer 211, the insulating layer 213, the insulating layer 215, and the insulating layer 214 are provided in this order over the substrate 451. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

A material through which impurities such as water and hydrogen are less likely to diffuse is preferably used for at least one of the insulating layers covering the transistors. This is because such an insulating layer can function as a barrier layer. Such a structure can effectively inhibit diffusion of impurities into the transistors from the outside and improve the reliability of the display device.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

Here, an organic insulating film often has a lower barrier property than an inorganic insulating film. Thus, the organic insulating film preferably has an opening in the vicinity of the end portion of the display device 400A. This can inhibit entry of impurities from the end portion of the display device 400A through the organic insulating film. Alternatively, the organic insulating film may be formed such that its end portion is positioned inward from the end portion of the display device 400A, to prevent the organic insulating film from being exposed at the end portion of the display device 400A.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

In a region 228 shown in FIG. 24, an opening is formed in the insulating layer 214. This can inhibit entry of impurities into the display portion 462 from the outside through the insulating layer 214 even when an organic insulating film is used as the insulating layer 214. Consequently, the reliability of the display device 400A can be increased.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor contain a metal oxide (also referred to as an oxide semiconductor). That is, a transistor containing a metal oxide in its channel formation region (hereinafter referred to as an OS transistor) is preferably used in the display device of this embodiment. Alternatively, the semiconductor layer of the transistor may contain silicon. Examples of silicon include amorphous silicon and crystalline silicon (e.g., low-temperature polysilicon or single crystal silicon).

The semiconductor layer preferably contains a metal oxide containing indium. In particular, the semiconductor layer preferably contains indium oxide.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer.

When the semiconductor layer is an In-M-Zn oxide, the atomic proportion of In is preferably higher than or equal to the atomic proportion of M in the In-M-Zn oxide. Examples of the atomic ratio of the metal elements in such an In-M-Zn oxide include In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and an atomic ratio in the neighborhood thereof. Note that the neighborhood of the atomic ratio includes ±30% of an intended atomic ratio.

For example, when the atomic ratio is described as In:Ga:Zn=4:2:3 or being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or being in the neighborhood thereof, the case is included where the atomic proportion of Ga is greater than 0.5 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or being in the neighborhood thereof, the case is included where the atomic proportion of Ga is greater than 0.5 and less than or equal to 2 and the atomic proportion of Zn is greater than 0.1 and less than or equal to 2 with the atomic proportion of In being 1.

The transistor included in the circuit 464 and the transistor included in the display portion 462 may have the same structure or different structures. One structure or two or more kinds of structures may be employed for a plurality of transistors included in the circuit 464. Similarly, one structure or two or more kinds of structures may be employed for a plurality of transistors included in the display portion 462.

A connection portion 204 is provided in a region of the substrate 451 where the substrate 452 does not overlap. In the connection portion 204, the wiring 465 is electrically connected to the FPC 472 through a conductive layer 466 and a connection layer 242. An example is shown in which the conductive layer 466 has a stacked-layer structure of a conductive film obtained by processing the same conductive film as the pixel electrode and a conductive film obtained by processing the same conductive film as the optical adjustment layer. On the top surface of the connection portion 204, the conductive layer 466 is exposed. Thus, the connection portion 204 and the FPC 472 can be electrically connected to each other through the connection layer 242.

The light-blocking layer 417 is preferably provided on the surface of the substrate 452 on the substrate 451 side. A variety of optical members can be arranged on the outer surface of the substrate 452. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 452.

Providing the protective layer 416 that covers the light-emitting element can inhibit impurities such as water from entering the light-emitting element and increase the reliability of the light-emitting element.

In the region 228 in the vicinity of the end portion of the display device 400A, the insulating layer 215 and the protective layer 416 are preferably in contact with each other through the opening in the insulating layer 214. In particular, the inorganic insulating film included in the insulating layer 215 and an inorganic insulating film included in the protective layer 416 are preferably in contact with each other. This can inhibit entry of impurities into the display portion 462 from the outside through the organic insulating film. Consequently, the reliability of the display device 400A can be increased.

The protective layer 416 may have a stacked-layer structure of an organic insulating film and an inorganic insulating film. In that case, an end portion of the inorganic insulating film preferably extends beyond an end portion of the organic insulating film.

For each of the substrates 451 and 452, glass, quartz, ceramics, sapphire, a resin, a metal, an alloy, a semiconductor, or the like can be used. The substrate on the side from which light from the light-emitting element is extracted is formed using a material that transmits the light. When the substrates 451 and 452 are formed using a flexible material, the flexibility of the display device can be increased. Furthermore, a polarizing plate may be used as the substrate 451 or the substrate 452.

For each of the substrates 451 and 452, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrates 451 and 452.

In the case where a circularly polarizing plate overlaps with the display device, a highly optically isotropic substrate is preferably used as the substrate included in the display device. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are caused. Thus, as the substrate, a film with a low water absorption rate is preferably used. For example, the water absorption rate of the film is preferably 1% or lower, further preferably 0.1% or lower, still further preferably 0.01% or lower.

The adhesive layer can be formed using any of a variety of curable adhesives, e.g., a reactive curable adhesive, a thermosetting adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component resin may be used. An adhesive sheet or the like may be used.

For the connection layer 242, an anisotropic conductive film (ACF), an anisotropic conductive paste (ACP), or the like can be used.

As materials for the gates, the source, and the drain of each transistor and conductive layers functioning as wirings and electrodes included in the display device, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

Examples of light-transmitting conductive materials include graphene and a conductive oxide such as indium oxide, indium tin oxide, indium zinc oxide, zinc oxide, or zinc oxide containing gallium. Other examples include a metal material such as gold, silver, platinum, magnesium, nickel, tungsten, chromium, molybdenum, iron, cobalt, copper, palladium, or titanium, and an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, a stacked film of any of the above materials can be used for the conductive layers. For example, a stacked film of indium tin oxide and an alloy of silver and magnesium is preferably used because conductivity can be increased. These can also be used for conductive layers such as wirings and electrodes included in the display device, and conductive layers (e.g., a conductive layer functioning as a pixel electrode or a common electrode) included in a light-emitting element.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

### [Display Device 400A2]

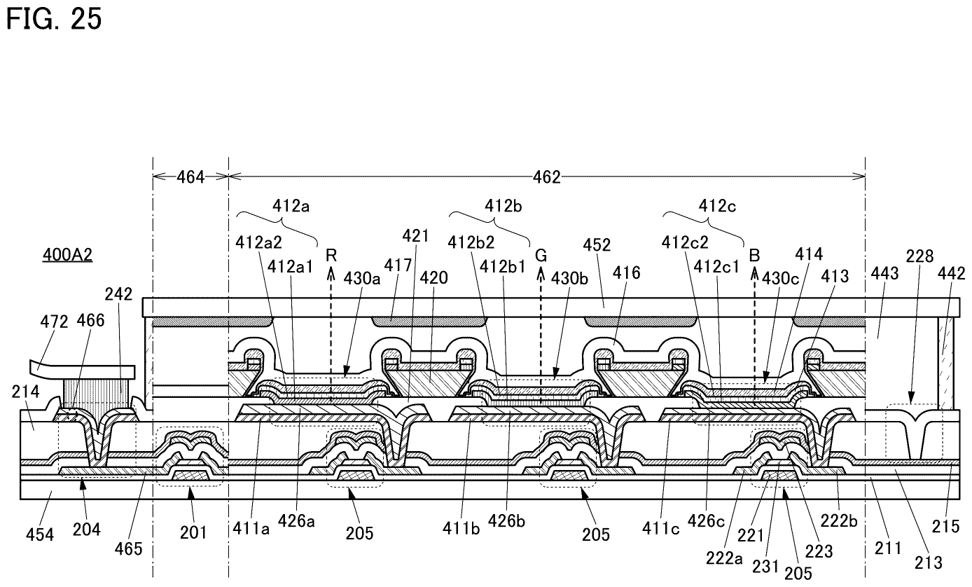

FIG. 25 shows a display device 400A2 including the light-emitting elements 430 having structures different from those in the display device 400A, as a modification example of the display device 400A. FIG. 25 shows an example in which each light-emitting element 430 includes any one of the pixel electrode 411a, the pixel electrode 411b, and the pixel electrode 411c; any one of the island-shaped first EL layer 412a, the island-shaped first EL layer 412b, and the island-shaped first EL layer 412c which include light-emitting layers emitting light of different colors; and the upper electrode 414 over the first EL layers 412a, 412b, and 412c. The first EL layer 412a has a stacked-layer structure of a layer 412al and a layer 412a2; the first EL layer 412b has a stacked-layer structure of a layer 412b1 and a layer 412b2; and the first EL layer 412c has a stacked-layer structure of a layer 412cl and a layer 412c2. The layer 412a1, the layer 412b1, and the layer 412cl include light-emitting layers that emit light of different colors, for example.

### [Display Device 400A3]

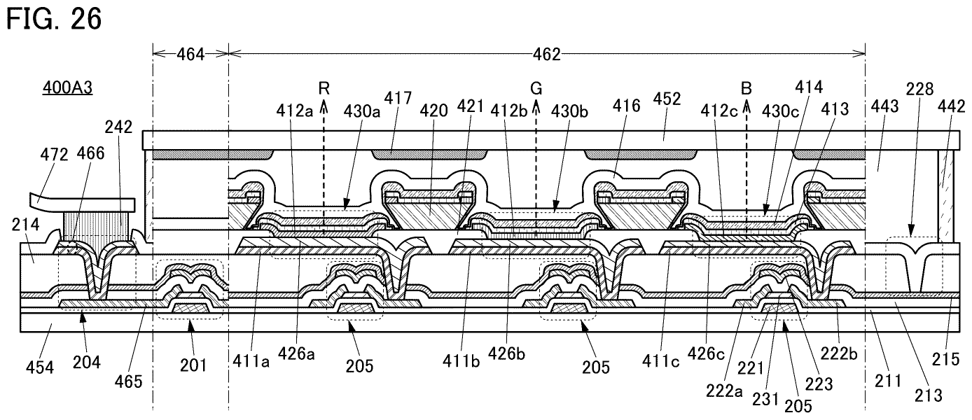

FIG. 26 shows a display device 400A3 including the light-emitting elements 430 having structures different from those in the display device 400A, as a modification example of the display device 400A. FIG. 26 shows an example in which each light-emitting element 430 includes any one of the pixel electrode 411a, the pixel electrode 411b, and the pixel electrode 411c; any one of the island-shaped first EL layer 412a, the island-shaped first EL layer 412b, and the island-shaped first EL layer 412c which include light-emitting layers emitting light of different colors; a second EL layer 413 over the first EL layer; and the upper electrode over the second EL layer.

### [Display Device 400B]

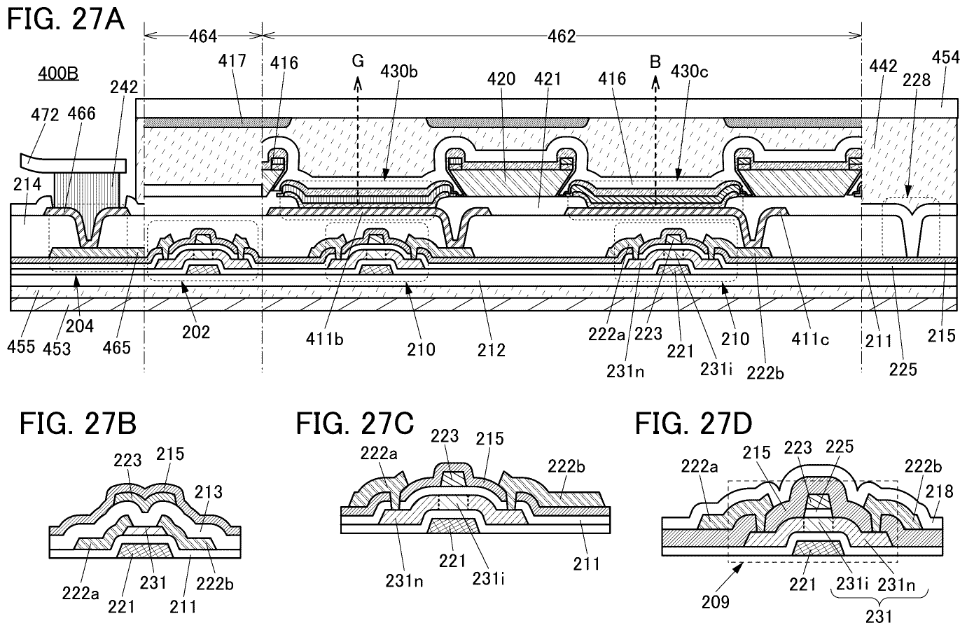

FIG. 27A is a cross-sectional view of a display device 400B. A perspective view of the display device 400B is similar to that of the display device 400A (FIG. 23B). FIG. 27A shows an example of cross sections of part of a region including the FPC 472, part of the circuit 464, and part of the display portion 462 in the display device 400B. FIG. 27A specifically shows an example of a cross section of a region including the light-emitting element 430b, which emits green light, and the light-emitting element 430c, which emits blue light, in the display portion 462. Note that portions similar to those in the display device 400A2 shown in FIG. 24 are not described in some cases.

The display device 400B shown in FIG. 27A includes a transistor 202, a transistor 210, the light-emitting element 430b, the light-emitting element 430c, and the like between a substrate 453 and a substrate 454.

The substrate 454 and the protective layer 416 are bonded to each other with the adhesive layer 442. The adhesive layer 442 is provided so as to overlap with the light-emitting element 430b and the light-emitting element 430c; that is, the display device 400B employs a solid sealing structure.

The substrate 453 and an insulating layer 212 are bonded to each other with an adhesive layer 455.

As a method for manufacturing the display device 400B, first, a formation substrate provided with the insulating layer 212, the transistors, the light-emitting elements, and the like and the substrate 454 provided with the light-blocking layer 417 are bonded to each other with the adhesive layer 442. Then, the substrate 453 is attached to a surface exposed by separation of the formation substrate, whereby the components formed over the formation substrate are transferred to the substrate 453. The substrates 453 and 454 are preferably flexible. Accordingly, the display device 400B can be highly flexible.

The inorganic insulating film that can be used as each of the insulating layers 211, 213, and 215 can be used as the insulating layer 212.

The pixel electrode is connected to the conductive layer 222b included in the transistor 210 through the opening provided in the insulating layer 214. The conductive layer 222b is connected to a low-resistance region 231n through an opening provided in the insulating layer 215 and an insulating layer 225. The transistor 210 has a function of controlling the driving of the light-emitting element.

The transistor 202 and the transistor 210 will be described with reference to FIG. 27B described later.

An end portion of each pixel electrode is covered with the insulating layer 421.

Light emitted from the light-emitting elements 430b and 430c is emitted to the substrate 454 side. For the substrate 454, a material having a high visible-light-transmitting property is preferably used.

The connection portion 204 is provided in a region of the substrate 453 where the substrate 454 does not overlap. In the connection portion 204, the wiring 465 is electrically connected to the FPC 472 through the conductive layer 466 and the connection layer 242. The conductive layer 466 can be obtained by processing the same conductive film as the pixel electrode. Thus, the connection portion 204 and the FPC 472 can be electrically connected to each other through the connection layer 242.

### [Display Device 400B2]

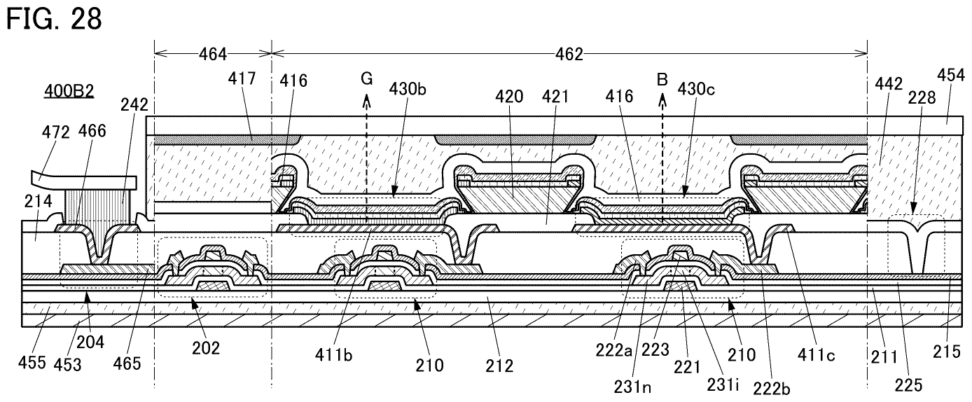

FIG. 28 is a cross-sectional view of a display device 400B2. A perspective view of the display device 400B2 is similar to that of the display device 400A (FIG. 23B). FIG. 28 shows an example of cross sections of part of a region including the FPC 472, part of the circuit 464, and part of the display portion 462 in the display device 400B. FIG. 28 specifically shows an example of a cross section of a region including the light-emitting element 430b, which emits green light, and the light-emitting element 430c, which emits blue light, in the display portion 462. Note that portions similar to those in the display device 400A3 shown in FIG. 20 are not described in some cases.

The display device 400B2 shown in FIG. 28 includes the transistor 202, the transistor 210, the light-emitting element 430b, the light-emitting element 430c, and the like between the substrate 453 and the substrate 454.

The substrate 454 and the protective layer 416 are bonded to each other with the adhesive layer 442. The adhesive layer 442 is provided so as to overlap with the light-emitting element 430b and the light-emitting element 430c; that is, the display device 400B employs a solid sealing structure.

The substrate 453 and the insulating layer 212 are bonded to each other with the adhesive layer 455.

As a method for manufacturing the display device 400B2, first, a formation substrate provided with the insulating layer 212, the transistors, the light-emitting elements, and the like and the substrate 454 provided with the light-blocking layer 417 are bonded to each other with the adhesive layer 442. Then, the substrate 453 is attached to a surface exposed by separation of the formation substrate, whereby the components formed over the formation substrate are transferred to the substrate 453. The substrates 453 and 454 are preferably flexible. Accordingly, the display device 400B can be highly flexible.

The inorganic insulating film that can be used as each of the insulating layers 211, 213, and 215 can be used as the insulating layer 212.

The pixel electrode is connected to the conductive layer 222b included in the transistor 210 through the opening provided in the insulating layer 214. The conductive layer 222b is connected to a low-resistance region 231n through an opening provided in the insulating layer 215 and an insulating layer 225. The transistor 210 has a function of controlling the driving of the light-emitting element.

The transistor 202 and the transistor 210 will be described with reference to FIG. 27B described later.

An end portion of the pixel electrode is covered with the insulating layer 421.

Light emitted from the light-emitting elements 430b and 430c is emitted to the substrate 454 side. For the substrate 454, a material having a high visible-light-transmitting property is preferably used.

The connection portion 204 is provided in a region of the substrate 453 where the substrate 454 does not overlap. In the connection portion 204, the wiring 465 is electrically connected to the FPC 472 through the conductive layer 466 and the connection layer 242. The conductive layer 466 can be obtained by processing the same conductive film as the pixel electrode. Thus, the connection portion 204 and the FPC 472 can be electrically connected to each other through the connection layer 242.

### [Transistor]

As a transistor in the display device of one embodiment of the present invention, the transistor shown in FIG. 27B can be used. The transistor shown in FIG. 27B is similar to the above-described transistor shown in FIG. 24, and thus detailed description is omitted. As the transistor in the display device of one embodiment of the present invention, the transistor shown in FIGS. 27C and 27D can also be used.

The transistor shown in FIG. 27C includes the conductive layer 221 functioning as a gate, the insulating layer 211 functioning as a gate insulating layer, a semiconductor layer including a channel formation region 231i and a pair of low-resistance regions 231n, the conductive layer 222a connected to one of the low-resistance regions 231n, the conductive layer 222b connected to the other low-resistance region 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the corresponding low-resistance regions 231n through openings provided in the insulating layer 215. One of the conductive layers 222a and 222b functions as a source, and the other functions as a drain.

FIG. 27C shows an example where the insulating layer 225 covers the top and side surfaces of the semiconductor layer. The conductive layer 222a and the conductive layer 222b are connected to the corresponding low-resistance regions 231n through the openings provided in the insulating layer 225 and the insulating layer 215.

In a transistor 209 shown in FIG. 27D, the insulating layer 225 overlaps with the channel formation region 231i of the semiconductor layer 231 and does not overlap with the low-resistance regions 231n. The structure shown in FIG. 27C is obtained by processing the insulating layer 225 with the conductive layer 223 as a mask, for example. In FIG. 27D, the insulating layer 215 is provided to cover the insulating layer 225 and the conductive layer 223, and the conductive layer 222a and the conductive layer 222b are connected to the low-resistance regions 231n through the openings in the insulating layer 215. Furthermore, an insulating layer 218 covering the transistor may be provided.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 3

In this embodiment, a structure example of a display device different from the above will be described.

The display device in this embodiment can be a high-resolution display device. Thus, the display device in this embodiment can be used for display portions of information terminals (wearable devices) such as watch-type or bracelet-type information terminals and display portions of wearable devices capable of being worn on a head, such as a VR device like a head-mounted display and a glasses-type AR device.

### [Display Module]

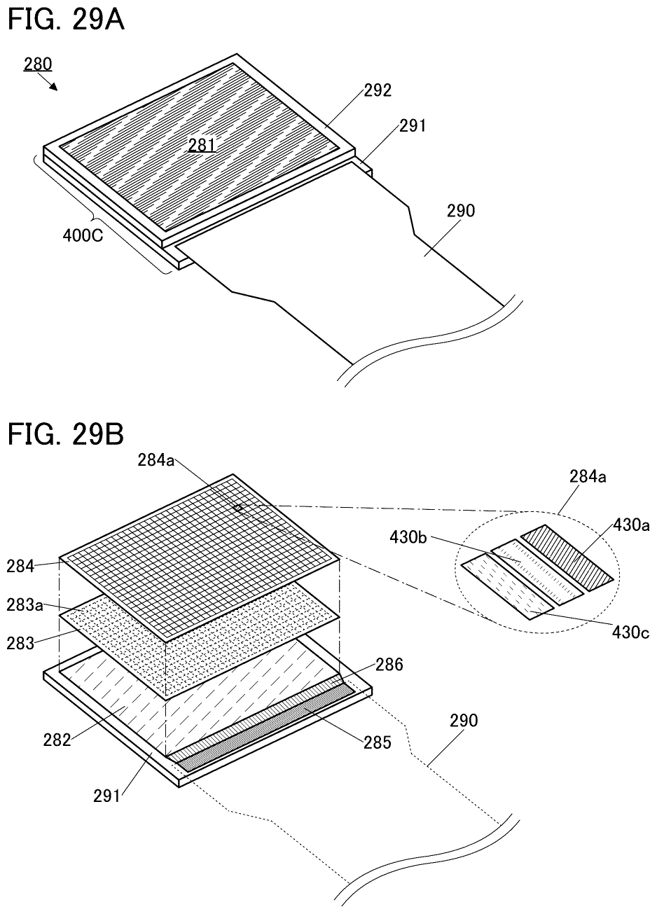

FIG. 29A is a perspective view of a display module 280. The display module 280 includes a display device 400C and an FPC 290. Note that the display device included in the display module 280 is not limited to the display device 400C and may be a display device 400D or a display device 400E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 29B is a perspective view schematically showing the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is shown on the right side in FIG. 29B. The pixel 284a includes the light-emitting devices 430a, 430b, and 430c emitting light of different colors. The plurality of light-emitting elements may be arranged in a stripe pattern as shown in FIG. 29B. With the stripe arrangement that enables high-density arrangement of pixel circuits, a high-resolution display device can be provided. Alternatively, a variety of arrangement methods such as a delta arrangement or a pentile arrangement can be employed.

The pixel circuit portion 283 includes a plurality of pixel circuits 283a arranged periodically.

One pixel circuit 283a is a circuit that controls light emission of three light-emitting elements included in one pixel 284a. One pixel circuit 283a may be provided with three circuits each of which controls light emission of one light-emitting element. For example, the pixel circuit 283a can include at least one selection transistor, one current control transistor (driving transistor), and a capacitor for one light-emitting element. A gate signal is input to a gate of the selection transistor, and a source signal is input to one of a source and a drain of the selection transistor. Thus, an active-matrix display device is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure where one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as a head-mounted display or a glasses-type device for AR. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Device 400C]

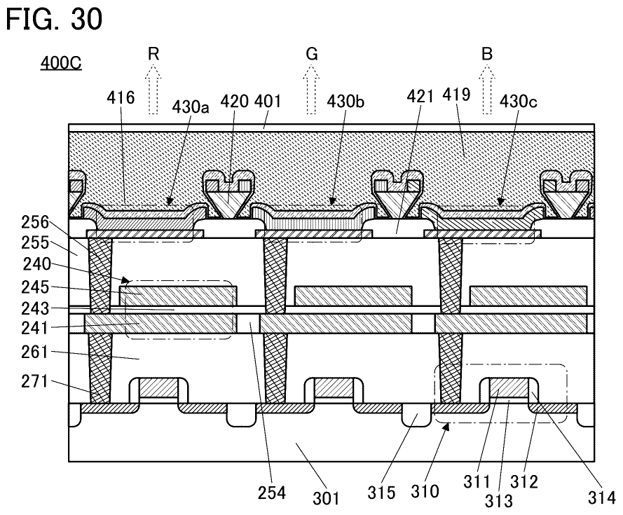

The display device 400C shown in FIG. 30 includes a substrate 301, the light-emitting elements 430a, 430b, and 430c, a capacitor 240, and a transistor 310.

The substrate 301 corresponds to the substrate 291 in FIGS. 29A and 29B.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, and the light-emitting elements 430a, 430b, and 430c and the like are provided over the insulating layer 255. The protective layer 416 is provided over the light-emitting elements 430a, 430b, and 430c, and a substrate 401 is bonded to a top surface of the protective layer 416 with a resin layer 419. The substrate 401 corresponds to the substrate 292 in FIG. 29A.

The pixel electrode of the light-emitting element is electrically connected to the one of the source and the drain of the transistor 310 through a plug 256 embedded in the insulating layer 255, the conductive layer 241 embedded in the insulating layer 254, and the plug 271 embedded in the insulating layer 261.

The insulating layer 421 is provided to cover the end portion of each pixel electrode. An inorganic insulating material is preferably used for the insulating layer 421. For example, an inorganic insulating material such as silicon oxide, silicon nitride, or aluminum oxide can be used.

The partition 420 is provided over the insulating layer 421. For the partition 420, the description of the partition 120 in Embodiment 1 can be referred to. A layer containing the same material as the EL layers and part of the upper electrodes of two light-emitting elements adjacent to each other with the partition 420 therebetween are provided over the partition 420.

### [Display Device 400C2]

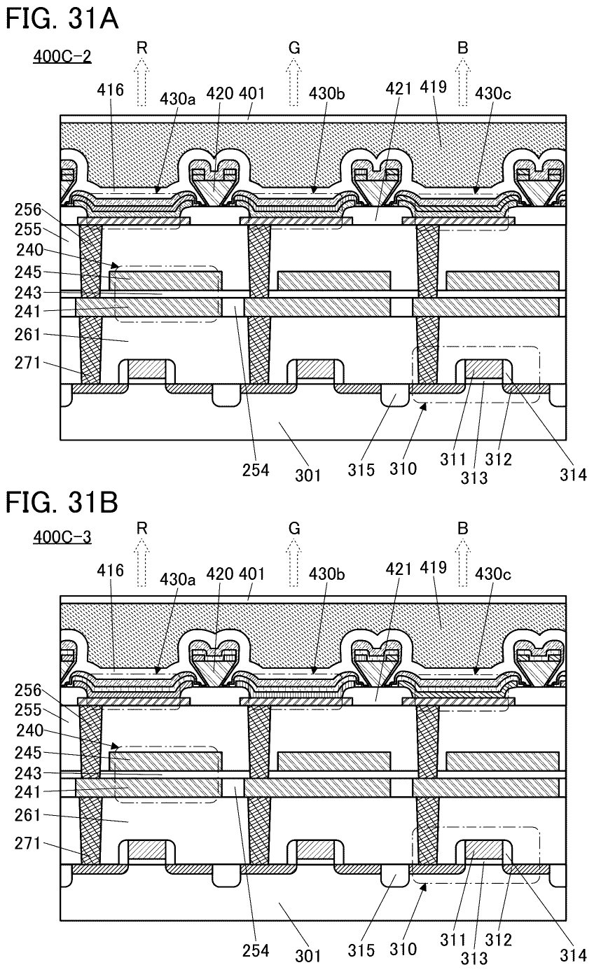

FIG. 30 shows an example in which the light-emitting element 110 shown in FIG. 2A or the like is used as each of the light-emitting elements 430a, 430b, and 430c; FIG. 31A shows an example in which the light-emitting element 110 shown in FIG. 5A or the like is used as the light-emitting element 430.

### [Display Device 400C3]

FIG. 31B shows an example in which the light-emitting element 110 shown in FIG. 4A or the like is used as each of the light-emitting elements 430a, 430b, and 430c.

### [Display Device 400D]

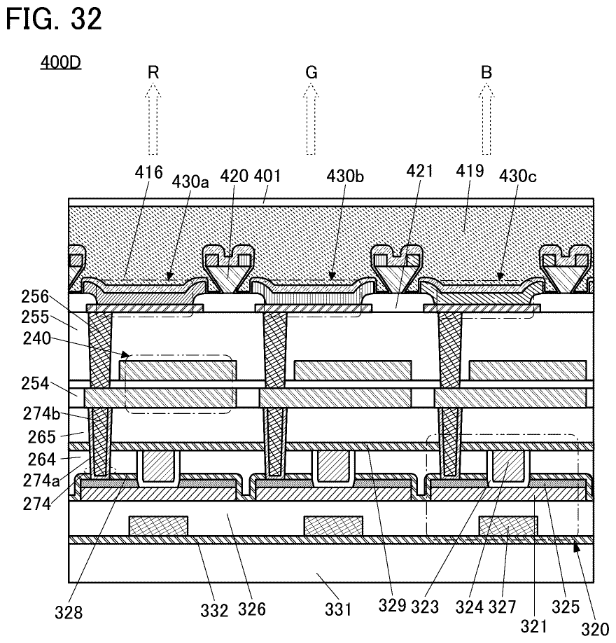

The display device 400D shown in FIG. 32 differs from the display device 400C mainly in transistor structure. Note that portions similar to those in the display device 400C are not described in some cases.

A transistor 320 contains a metal oxide (also referred to as an oxide semiconductor) in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 shown in FIGS. 29A and 29B. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 which is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used for the semiconductor layer 321. A material that can be used for the semiconductor layer 321 is described in detail later.

The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layers 328 and 264. The insulating layer 323 that is in contact with the side surfaces of the insulating layers 264 and 328, the side surface of the conductive layer 325, and the top surface of the semiconductor layer 321 and the conductive layer 324 fill the inside of the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and an insulating layer 265 are provided to cover these layers.

The insulating layers 264 and 265 each function as an interlayer insulating layer. The insulating layer 329 functions as a barrier layer that prevents diffusion of impurities such as water or hydrogen from the insulating layer 265 or the like into the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, and 264. Here, the plug 274 preferably includes a conductive layer 274a that covers the side surface of an opening formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

Components from the insulating layer 254 to the substrate 401 in the display device 400D are similar to those in the display device 400C.

### [Display Device 400E]

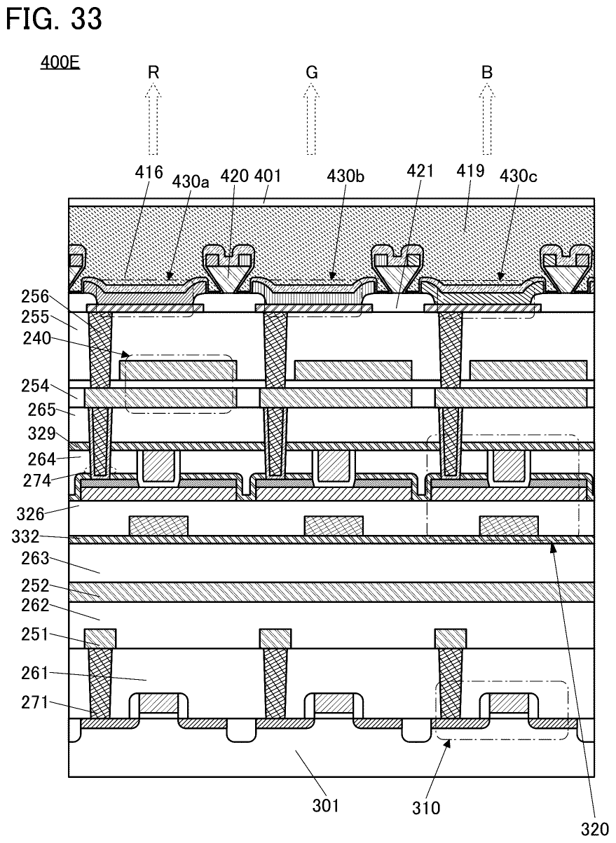

The display device 400E shown in FIG. 33 has a structure in which the transistor 310 whose channel is formed in the substrate 301 and the transistor 320 containing a metal oxide in the semiconductor layer where the channel is formed are stacked. Note that portions similar to those in the display devices 400C and 400D are not described in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layers 251 and 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistors 310 and 320 can also be used as transistors included in a variety of circuits such as an arithmetic circuit and a memory circuit.

With such a structure, not only the pixel circuit but also the driver circuit or the like can be formed directly under the light-emitting element; thus, the display device can be downsized as compared with the case where the driver circuit is provided around a display region.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 4

In this embodiment, a light-emitting element (also referred to as a light-emitting device) that can be used in the display device of one embodiment of the present invention will be described.

In this specification and the like, a light-emitting device (also referred to as a light-emitting element) includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

In this specification and the like, a structure in which light-emitting layers in light-emitting devices of different colors (here, blue (B), green (G), and red (R)) are separately formed or separately patterned may be referred to as a side-by-side (SBS) structure. The SBS structure can optimize materials and structures of light-emitting devices and thus can extend the freedom of choices of materials and structures, whereby the luminance and the reliability can be easily improved. In this specification and the like, a light-emitting device capable of emitting white light may be referred to as a white-light-emitting device. Note that a combination of white light-emitting devices with coloring layers (e.g., color filters) enables a full-color display device.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

### [Light-Emitting Device]

Structures of light-emitting devices can be classified roughly into a single structure and a tandem structure. A light-emitting device having a single structure includes one light-emitting unit between a pair of electrodes. The light-emitting unit includes one or more light-emitting layers. To obtain white light emission with a single structure, two or more light-emitting layers are selected such that emission of the light-emitting layers can produce white color. For example, in the case of two colors, when emission colors of a first light-emitting layer and a second light-emitting layer are complementary colors, the light-emitting device can be configured to emit white light as a whole. To obtain white light emission by using three or more light-emitting layers, the light-emitting device is configured to emit white light as a whole by combining emission colors of the three or more light-emitting layers.

A light-emitting device having a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the light-emitting device is configured to emit white light by combining light from light-emitting layers of a plurality of light-emitting units. Note that a combination of emission colors for obtaining white light emission is similar to that for a single structure. In the light-emitting device with a tandem structure, it is preferable that an intermediate layer such as a charge-generation layer be provided between the plurality of light-emitting units.

When a white-light-emitting device and a light-emitting device with an SBS structure are compared to each other, the latter can have lower power consumption than the former. Meanwhile, the white-light-emitting device is preferable in terms of lower manufacturing cost and higher manufacturing yield because the manufacturing process of the white-light-emitting device is simpler than that of the light-emitting device with the SBS structure.

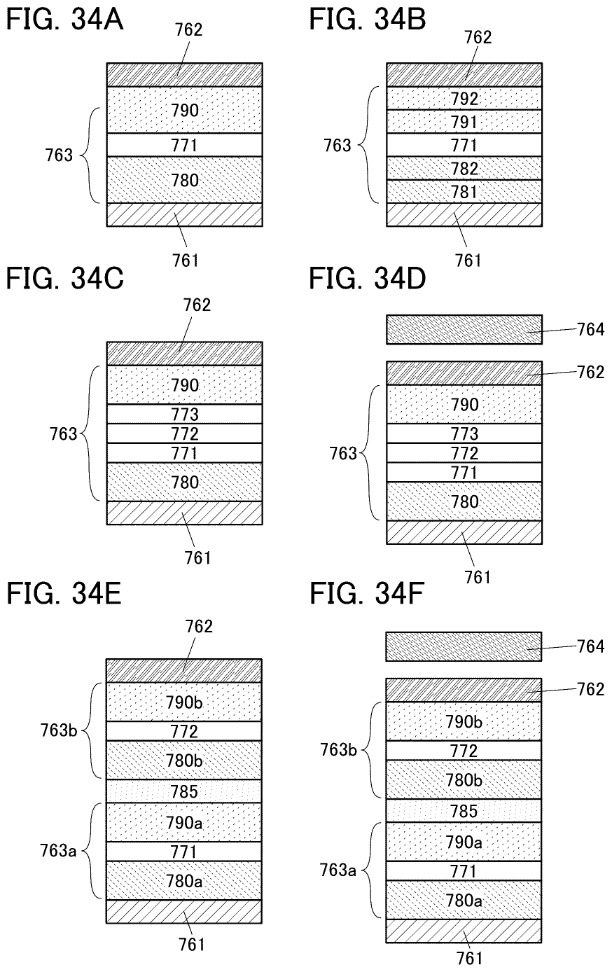

As shown in FIG. 34A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 34A is referred to as a single structure in this specification.

FIG. 34B is a modification example of the EL layer 763 included in the light-emitting device shown in FIG. 34A. Specifically, the light-emitting device shown in FIG. 34B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected into the light-emitting layer 771, and the efficiency of the recombination of carriers in the light-emitting layer 771 can be enhanced.

Note that structures in which a plurality of light-emitting layers (the light-emitting layer 771 and light-emitting layers 772 and 773) are provided between the layer 780 and the layer 790 as shown in FIGS. 34C and 34D are variations of a single structure. Although FIGS. 34C and 34D each show an example in which three light-emitting layers are included, the number of light-emitting layers in a light-emitting device with a single structure may be two or four or more.

In addition, the light-emitting device with a single structure may include a buffer layer between two light-emitting layers.

A structure in which a plurality of light-emitting units (a light-emitting unit 763a and a light-emitting unit 763b) are connected in series through a charge-generation layer 785 (also referred to as an intermediate layer) as shown in FIGS. 34E and 34F is referred to as a tandem structure in this specification. The tandem structure can be referred to as a stack structure. The tandem structure enables a light-emitting device to emit light with high luminance. Furthermore, the amount of current needed for obtaining a predetermined luminance can be smaller in the tandem structure than in the single structure; thus, the tandem structure enables higher reliability.

Note that FIGS. 34D and 34F each show an example in which the display device includes a layer 764 overlapping with the light-emitting device. FIG. 34D is an example in which the layer 764 overlaps with the light-emitting device shown in FIG. 34C, and FIG. 34F shows an example in which the layer 764 overlaps with the light-emitting device shown in FIG. 34E. In FIGS. 34D and 34F, a conductive film that transmits visible light is used for the upper electrode 762 so that light is extracted from the upper electrode 762 side.

One or both of a color conversion layer and a color filter (coloring layer) can be used as the layer 764.

In FIGS. 34C and 34D, light-emitting substances that emit light of the same color or the same light-emitting substance may be used for the light-emitting layers 771, 772, and 773. For example, a light-emitting substance that emits blue light may be used for the light-emitting layers 771, 772, and 773. In a subpixel that exhibits blue light, blue light from the light-emitting device can be extracted as it is. In a subpixel that exhibits red light and a subpixel that exhibits green light, respective color conversion layers are provided as the layer 764 shown in FIG. 34D, whereby blue light emitted by light-emitting devices can be converted into light with a longer wavelength and thus red light or green light can be extracted. As the layer 764, both a color conversion layer and a coloring layer are preferably used. In some cases, part of light emitted from the light-emitting device is transmitted through the color conversion layer without being converted. When light passing through the color conversion layer is extracted through the coloring layer, light other than light of a desired color can be absorbed by the coloring layer, and color purity of light exhibited by a subpixel can be improved.

In FIGS. 34C and 34D, light-emitting substances that emit light of different colors may be used for the light-emitting layers 771, 772, and 773. When the light-emitting layers 771, 772, and 773 emit light of complementary colors, white light emission can be obtained. The light-emitting device with a single structure preferably includes a light-emitting layer containing a light-emitting substance that emits blue light and a light-emitting layer containing a light-emitting substance that emits visible light with a longer wavelength than blue light, for example.

A color filter may be provided as the layer 764 shown in FIG. 34D. When white light passes through a color filter, light of a desired color can be obtained.

In the case where the light-emitting device with a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be RGB or RBG from an anode side, for example. In that case, a buffer layer may be provided between R and G or between R and B.

In the case where the light-emitting device with a single structure includes two light-emitting layers, for example, a light-emitting layer containing a light-emitting substance that emits blue (B) light and a light-emitting layer containing a light-emitting substance that emits yellow (Y) light are preferably included. Such a structure may be referred to as a BY single structure.

In the light-emitting device that emits white light, two or more kinds of light-emitting substances are preferably contained. To obtain white light emission, the two or more kinds of light-emitting substances are selected so as to emit light of complementary colors. For example, when emission colors of a first light-emitting layer and a second light-emitting layer are complementary colors, the light-emitting device can emit white light as a whole. The same applies to a light-emitting device including three or more light-emitting layers.

In FIGS. 34C and 34D, the layers 780 and 790 may each have a stacked-layer structure of two or more layers as shown in FIG. 34B.

In FIGS. 34E and 34F, light-emitting substances that emit light of the same color, or moreover, the same light-emitting substance may be used for the light-emitting layers 771 and 772. For example, in light-emitting devices included in subpixels that exhibit light of different colors, a light-emitting substance that emits blue light can be used for each of the light-emitting layers 771 and 772. In a subpixel that exhibits blue light, blue light from the light-emitting device can be extracted as it is. In each of the subpixel that exhibits red light and the subpixel that exhibits green light, a color conversion layer is provided as the layer 764 shown in FIG. 34F for converting blue light from the light-emitting device into light with a longer wavelength, so that red light or green light can be extracted. As the layer 764, both a color conversion layer and a coloring layer are preferably used.

In FIGS. 34E and 34F, light-emitting substances that emit light of different colors may be used for the light-emitting layers 771 and 772. When the light-emitting layers 771 and 772 emit light of complementary colors, white light emission can be obtained. As the layer 764 shown in FIG. 34F, a color filter may be provided. When white light passes through a color filter, light of a desired color can be obtained.

Although FIGS. 34E and 34F each show an example in which the light-emitting unit 763a includes one light-emitting layer 771 and the light-emitting unit 763b includes one light-emitting layer 772, one embodiment of the present invention is not limited thereto. Each of the light-emitting units 763a and 763b may include two or more light-emitting layers.

Although FIGS. 34E and 34F each show an example of a light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In each of FIGS. 34E and 34F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layers 780a and 780b each include one or more of a hole-injection layer, a hole-transport layer, and an electron-blocking layer. Furthermore, the layers 790a and 790b each include one or more of an electron-injection layer, an electron-transport layer, and a hole-blocking layer. In the case where the lower electrode 761 is a cathode and the upper electrode 762 is an anode, the structures of the layers 780a and 790a are interchanged and the structures of the layers 780b and 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 has a function of injecting electrons into one of the two light-emitting units and injecting holes into the other when voltage is applied between the pair of electrodes.

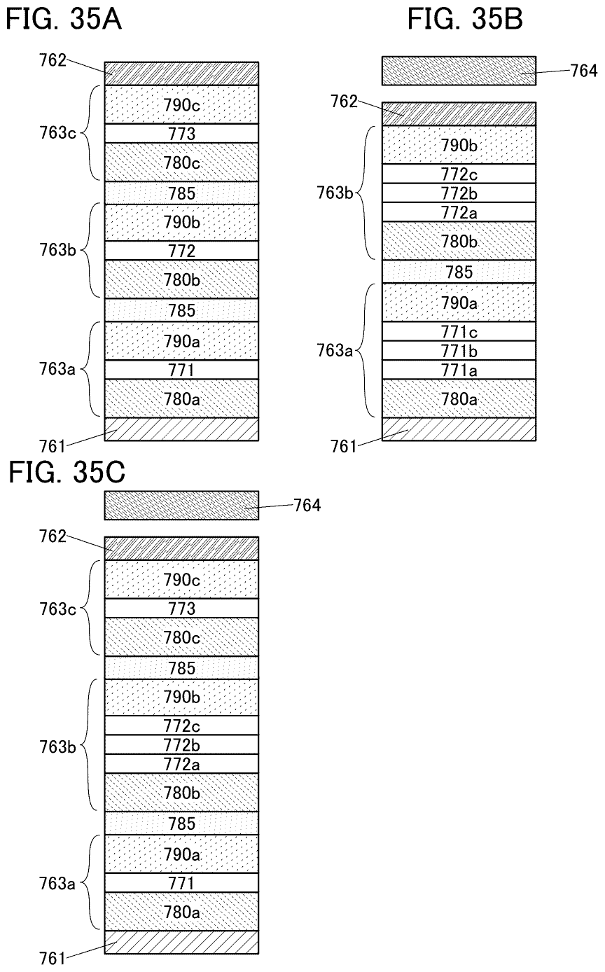

Examples of the light-emitting device with a tandem structure are structures shown in FIGS. 35A to 35C.

FIG. 35A shows a structure including three light-emitting units. In the structure shown in FIG. 35A, a plurality of light-emitting units (the light-emitting units 763a and 763b and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 35A, the light-emitting layers 771, 772, and 773 can contain light-emitting substances that emit light of the same color. Specifically, the light-emitting layers 771, 772, and 773 can each contain a blue (B) light-emitting substance (i.e., a B/B/B three-unit tandem structure). Note that “b/a” means that a light-emitting unit containing a light-emitting substance that emits light of the color “b” is provided over a light-emitting unit containing a light-emitting substance that emits light of the color “a” with a charge-generation layer therebetween.

In FIG. 35A, light-emitting substances that emit light of different colors may be used for some or all of the light-emitting layers 771, 772, and 773. Examples of the combination of emission colors for the light-emitting layers 771, 772, and 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as shown in FIG. 35B. FIG. 35B shows a structure in which two light-emitting units (the light-emitting units 763a and 763b) are connected in series through the charge-generation layer 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 35B, the light-emitting unit 763a is configured to emit white (W) light by selecting light-emitting substances for the light-emitting layers 771a, 771b, and 771c such that their emission colors are complementary colors. Furthermore, the light-emitting unit 763b is configured to emit white (W) light by selecting light-emitting substances for the light-emitting layers 772a, 772b, and 772c such that their emission colors are complementary colors. That is, the structure shown in FIG. 35B is a two-unit tandem structure of W/W. Note that there is no particular limitation on the stacking order of the light-emitting substances having complementary emission colors. The practitioner can select the optimal stacking order as appropriate. Although not shown, a W/W/W three-unit tandem structure or a tandem structure with four or more units may be employed.

In the case of a light-emitting device with a tandem structure, any of the following structures may be employed, for example: a B/Y or Y/B two-unit tandem structure including a light-emitting unit that emits yellow (Y) light and a light-emitting unit that emits blue (B) light; a B/R·G or R·G/B two-unit tandem structure including a light-emitting unit that emits red (R) and green (G) light and a light-emitting unit that emits blue (B) light; a B/Y/B three-unit tandem structure including a light-emitting unit that emits blue (B) light, a light-emitting unit that emits yellow (Y) light, and a light-emitting unit that emits blue (B) light in this order; a B/YG/B three-unit tandem structure including a light-emitting unit that emits blue (B) light, a light-emitting unit that emits yellow-green (YG) light, and a light-emitting unit that emits blue (B) light in this order; and a B/G/B three-unit tandem structure including a light-emitting unit that emits blue (B) light, a light-emitting unit that emits green (G) light, and a light-emitting unit that emits blue (B) light in this order. Note that “a·b” means that one light-emitting unit contains a light-emitting substance that emits light of the color “a” and a light-emitting substance that emits light of the color “b”.

As shown in FIG. 35C, a light-emitting unit including one light-emitting layer and a light-emitting unit including a plurality of light-emitting layers may be used in combination.

Specifically, in the structure shown in FIG. 35C, a plurality of light-emitting units (the light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure shown in FIG. 35C can be, for example, a B/R·G·YG/B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film that transmits visible light is used for the electrode through which light is extracted, which is either the lower electrode 761 or the upper electrode 762. A conductive film that reflects visible light is preferably used for the electrode through which light is not extracted. In the case where the display device includes a light-emitting device that emits infrared light, it is preferable that a conductive film that transmits visible light and infrared light be used for the electrode through which light is extracted, and a conductive film that reflects visible light and infrared light be used for the electrode through which light is not extracted.

A conductive film that transmits visible light may be used also for the electrode through which light is not extracted. In that case, the electrode is preferably provided between a reflective layer and the EL layer 763. In other words, light emitted from the EL layer 763 may be reflected by the reflective layer to be extracted from the display device.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Thus, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with high electron- and hole-transport properties), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellowish green, yellow, orange, red, or the like is appropriately used. As the light-emitting substance, a substance that emits near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

A hole-injection layer injects holes from an anode to a hole-transport layer and contains a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material that contains a hole-transport material and the above-described oxide of a metal belonging to Group 4 to Group 8 of the periodic table (typified by molybdenum oxide) may be used, for example.

The hole-transport layer transports holes, which are injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. The hole-transport material is preferably a material with a high hole-transport property, such as a x-electron rich heteroaromatic compound (e.g., a carbazole derivative, a thiophene derivative, and a furan derivative) or an aromatic amine (a compound having an aromatic amine skeleton).

The electron-blocking layer is provided in contact with the light-emitting layer. The electron-blocking layer has a hole-transport property and contains a material that can block an electron. Among the above-described hole-transport materials, a material with an electron-blocking property can be used for the electron-blocking layer.

Since the electron-blocking layer has a hole-transport property, the electron-blocking layer can also be referred to as a hole-transport layer. A hole-transport layer with an electron-blocking property can be referred to as an electron-blocking layer.

The electron-transport layer transports electrons, which are injected from the cathode by the electron-injection layer, to the light-emitting layer. The electron-transport layer contains an electron-transport material. The electron-transport material preferably has an electron mobility higher than or equal to 1×10⁻⁶ cm²/Vs. Note that other substances can also be used as long as the substances have an electron-transport property higher than a hole-transport property. The electron-transport material can be a material with a high electron-transport property, e.g., a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a T-electron deficient heteroaromatic compound such as a nitrogen-containing heteroaromatic compound.

The hole-blocking layer is provided in contact with the light-emitting layer. The hole-blocking layer has an electron-transport property and contains a material that can block a hole. Among the above-described electron-transport materials, a material with a hole-blocking property can be used for the hole-blocking layer.

Since the hole-blocking layer has an electron-transport property, the hole-blocking layer can also be referred to as an electron-transport layer. An electron-transport layer with a hole-blocking property can be referred to as a hole-blocking layer.

An electron-injection layer injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The lowest unoccupied molecular orbital (LUMO) level of the material with a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. An example of the stacked-layer structure is a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c]phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition temperature (T_{g}) than BPhen and thus has high heat resistance.

The charge-generation layer preferably includes a p-type layer. The p-type layer preferably contains an acceptor material. For example, the p-type layer preferably contains the above-described hole-transport material and acceptor material that can be used for the hole-injection layer.

The charge-generation layer preferably includes a layer containing a material with a high electron-injection property. The layer can also be referred to as an electron-injection buffer layer or an n-type layer. The electron-injection buffer layer is preferably provided between the p-type layer and the electron-transport layer. With use of the electron-injection buffer layer, an injection barrier between the p-type layer and the electron-transport layer can be lowered; thus, electrons generated in the p-type layer can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, the above-described material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the p-type layer and the electron-injection buffer layer. In the case where the charge-generation layer does not include an electron-injection buffer layer, the electron-relay layer is preferably provided between the p-type layer and the electron-transport layer. The electron-relay layer has a function of preventing an interaction between the p-type layer and the electron-injection buffer layer (or the electron-transport layer) and transferring electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the p-type layer, the electron-injection buffer layer, and the electron-relay layer cannot be clearly distinguished from one another on the basis of the cross-sectional shape or properties in some cases.

When the charge-generation layer is provided between two light-emitting units to be stacked, an increase in driving voltage can be inhibited.

At least part of this embodiment can be implemented as appropriate in combination with any of the other embodiments described in this specification.

### Embodiment 5

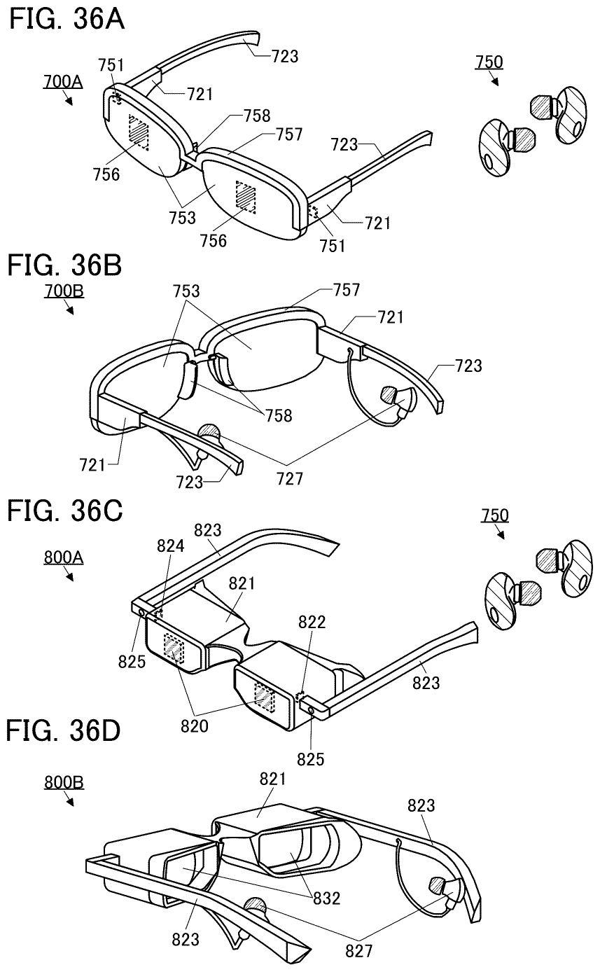

In this embodiment, electronic devices of one embodiment of the present invention will be described with reference to FIGS. 36A to 36D, FIGS. 37A to 37F, and FIGS. 38A to 38G.

Electronic devices in this embodiment each include the display panel (display device) of one embodiment of the present invention in a display portion. The display panel of one embodiment of the present invention can be easily increased in resolution and definition and can achieve high display quality. Thus, the display panel of one embodiment of the present invention can be used for display portions of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television apparatus, desktop and laptop personal computers, a monitor of a computer and the like, digital signage, and a large game machine like a pachinko machine.

In particular, the display panel of one embodiment of the present invention can have high resolution, and thus can be favorably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display panel having one or both of such high definition and high resolution can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices capable of being worn on a head are described with reference to FIGS. 36A to 36D. The wearable devices have one or both of a function of displaying AR content and a function of displaying VR content. Note that these wearable devices may have a function of displaying SR or MR content, in addition to AR and VR content. The electronic device having a function of displaying content of at least one of AR, VR, SR, MR, and the like enables the user to feel a higher level of immersion.

An electronic device 700A shown in FIG. 36A and an electronic device 700B shown in FIG. 36B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display panel of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are capable of AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A shown in FIG. 36C and an electronic device 800B shown in FIG. 36D each include a pair of display portions 820, a housing 821, a communication portion 822, a pair of wearing portions 823, a control portion 824, a pair of image capturing portions 825, and a pair of lenses 832.

The display panel of one embodiment of the present invention can be used in the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user who wears the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 36C and the like show examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance to an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not shown) and have a wireless communication function. The earphones 750 can receive information (e.g., audio data) from the electronic device with the wireless communication function. For example, the electronic device 700A in FIG. 36A has a function of transmitting information to the earphones 750 with the wireless communication function. As another example, the electronic device 800A in FIG. 36C has a function of transmitting information to the earphones 750 with the wireless communication function.

The electronic device may include an earphone portion. The electronic device 700B shown in FIG. 36B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B shown in FIG. 36D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

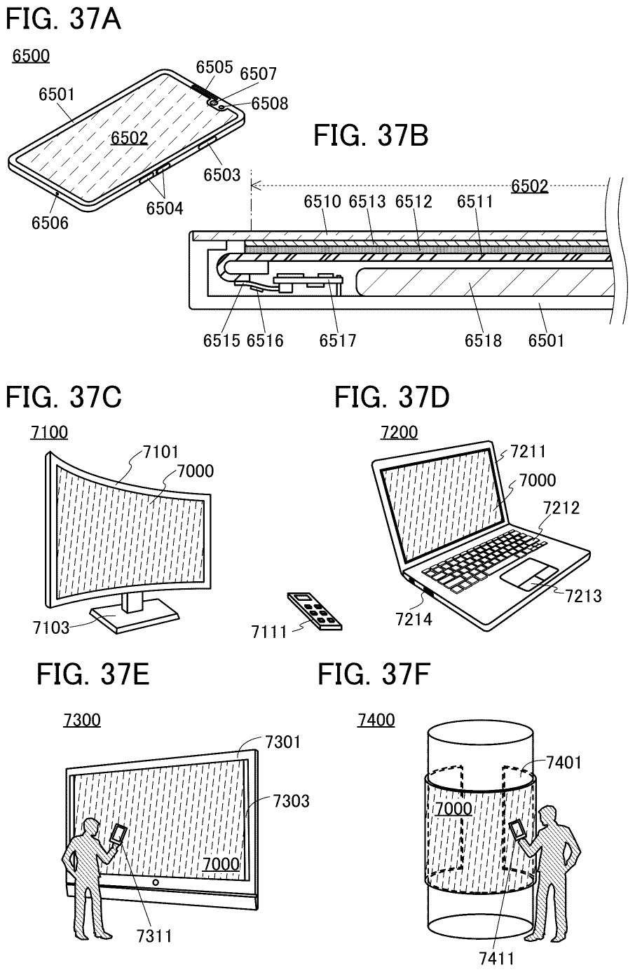

An electronic device 6500 shown in FIG. 37A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be used in the display portion 6502.

FIG. 37B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 37C shows an example of a television apparatus. In a television apparatus 7100, a display portion 7000 is incorporated in a housing 7101. Here, the housing 7101 is supported by a stand 7103.

Operation of the television apparatus 7100 shown in FIG. 37C can be performed with an operation switch provided in the housing 7101 and a separate remote control 7111. Alternatively, the display portion 7000 may include a touch sensor, and the television apparatus 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television apparatus 7100 includes a receiver, a modem, and the like. A general television broadcast can be received with the receiver. When the television apparatus is connected to a communication network by wire or wirelessly via the modem, one-way (from a transmitter to a receiver) or two-way (between a transmitter and a receiver or between receivers, for example) information communication can be performed.

FIG. 37D shows an example of a laptop personal computer. A laptop personal computer 7200 includes a housing 7211, a keyboard 7212, a pointing device 7213, an external connection port 7214, and the like. The display portion 7000 is incorporated in the housing 7211.

FIGS. 37E and 37F show examples of digital signage.

Digital signage 7300 shown in FIG. 37E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 37F shows digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As shown in FIGS. 37E and 37F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The display panel of one embodiment of the present invention can be used in the display portion 7000 shown in each of FIGS. 37C to 37F.

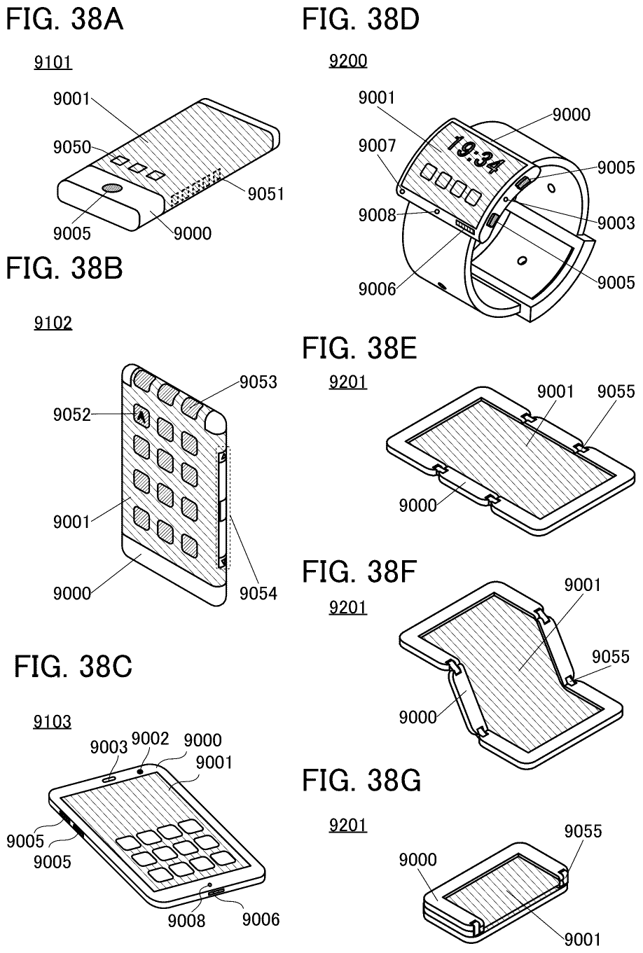

Electronic devices shown in FIGS. 38A to 38G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices shown in FIGS. 38A to 38G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image and storing the captured image in a storage medium (an external storage medium or a storage medium incorporated in the camera), a function of displaying the captured image on the display portion, and the like.

The electronic devices shown in FIGS. 38A to 38G are described in detail below.

FIG. 38A is a perspective view of a portable information terminal 9101. The portable information terminal 9101 can be used as a smartphone, for example. The portable information terminal 9101 may include the speaker 9003, the connection terminal 9006, the sensor 9007, and the like. The portable information terminal 9101 can display text and image information on its plurality of surfaces. FIG. 38A shows an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 38B is a perspective view of a portable information terminal 9102. The portable information terminal 9102 has a function of displaying information on three or more surfaces of the display portion 9001. In the example shown here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 38C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 38D is a perspective view of a watch-type portable information terminal 9200. The portable information terminal 9200 can be used as a watch-type wearable device, for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 38E to 38G are perspective views of a foldable portable information terminal 9201. FIG. 38E is a perspective view showing the portable information terminal 9201 that is opened. FIG. 38G is a perspective view showing the portable information terminal 9201 that is folded. FIG. 38F is a perspective view showing the portable information terminal 9201 that is shifted from one of the states in FIGS. 38E and 38G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

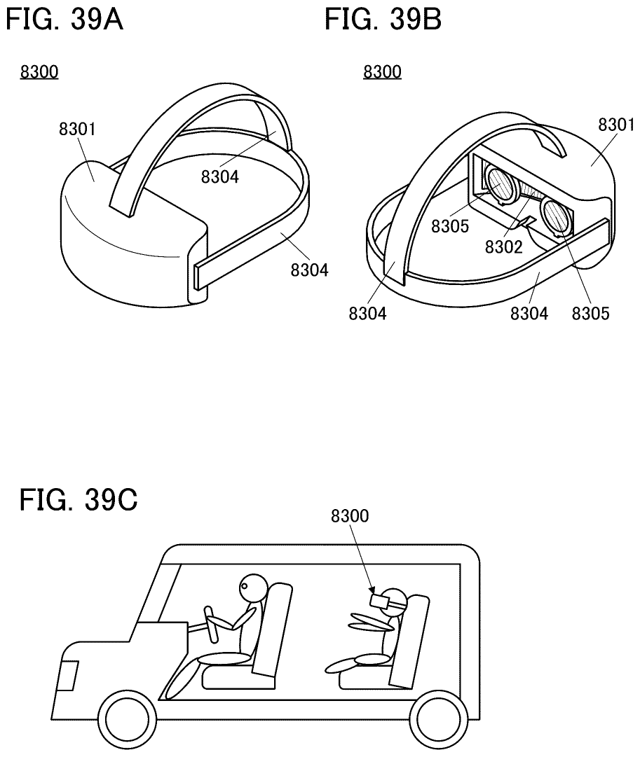

FIG. 39A and FIG. 39B are external views of a head-mounted display 8300. The head-mounted display 8300 includes a housing 8301, a display portion 8302, a band-like fixing member 8304, and a pair of lenses 8305.

A user can see display on the display portion 8302 through the lenses 8305. The display portion 8302 is preferably curved because the user can feel a high realistic sensation. When another image displayed in another region of the display portion 8302 is viewed through the lenses 8305, three-dimensional display using parallax or the like can be performed. Note that the number of the display portions 8302 is not limited to one; two display portions 8302 may be provided for user's respective eyes.

The display device of one embodiment of the present invention can be used for the display portion 8302. The display device of one embodiment of the present invention can have an extremely high resolution. Thus, a pixel is not easily seen by the user even when the user sees display that is magnified by the use of the lenses 8305. In other words, an image with a strong sense of reality can be seen by the user with use of the display portion 8302.

The head-mounted display 8300 preferably has a head tracking function and an eye tracking function. Accordingly, an image displayed can be moved in accordance with the movement of the user and the line of sight of the user. Thus, a highly immersive image can be provided to the user. For example, as shown in FIG. 39C, a passenger in the rear seat of a car can wear the head-mounted display 8300. In that case, moving an image in synchronization with the shaking of the car body and not fixing the line of sight, for example, can reduce car sickness as compared with the case where the passenger sees an image with a smartphone, a tablet terminal, or the like.

At least part of this embodiment can be implemented as appropriate in combination with any of the other embodiments described in this specification.

This application is based on Japanese Patent Application Serial No. 2025-018673 filed with Japan Patent Office on Feb. 6, 2025, Japanese Patent Application Serial No. 2025-018751 filed with Japan Patent Office on Feb. 6, 2025, and Japanese Patent Application Serial No. 2025-202873 filed with Japan Patent Office on Nov. 25, 2025, the entire contents of which are hereby incorporated by reference.

What is claimed is:

1. A method for manufacturing a display device comprising:
forming a first pixel electrode and a second pixel electrode over a substrate;
forming an insulating layer between the first pixel electrode and the second pixel electrode;
forming a conductive film over the first pixel electrode, the second pixel electrode, and the insulating layer;
removing a portion of the conductive film overlapping with the first pixel electrode to form a first side surface of the conductive film;
forming a first organic compound layer over the first pixel electrode and the conductive film;
forming a sacrificial layer over the first organic compound layer;
removing a portion of the conductive film overlapping with the second pixel electrode to form a second side surface of the conductive film;
forming a second organic compound layer over the sacrificial layer and the second pixel electrode;
removing the sacrificial layer; and
forming an upper electrode over the first organic compound layer and the second organic compound layer to be in contact with the first side surface and the second side surface.

2. The method for manufacturing a display device according to claim 1,
wherein the first side surface and the second side surface are formed by etching the conductive film by a wet etching method, and
wherein an etching rate of the conductive film is higher in a lower portion than in an upper portion of the conductive film.

3. The method for manufacturing a display device according to claim 1,
wherein the first side surface formed over the insulating layer has an angle greater than or equal to 105° and less than or equal to 175° with respect to a top surface of the insulating layer.

4. The method for manufacturing a display device according to claim 1,
wherein the conductive film comprises indium and oxygen.

5. The method for manufacturing a display device according to claim 1,
wherein force required for separation of a material used for the conductive film from a material used for the insulating layer is lower than 8 N.

6. The method for manufacturing a display device according to claim 1,
wherein the conductive film has a larger thickness than at least one of the first organic compound layer and the second organic compound layer.

7. The method for manufacturing a display device according to claim 1,
wherein the first organic compound layer is formed by a first material traveling with a first angle with respect to a perpendicular direction to a formation surface of the substrate,
wherein the upper electrode is formed by a second material traveling with a second angle with respect to the perpendicular direction,
wherein the first angle is greater than or equal to 0°, and
wherein the second angle is larger than the first angle.

8. The method for manufacturing a display device according to claim 7,
wherein the first material travels from an evaporation source, and
wherein a direction and a position of the evaporation source with respect to the substrate are determined so that the first material travels from the evaporation source with the first angle with respect to the perpendicular direction.

9. A method for manufacturing a display device comprising:
forming a first pixel electrode and a second pixel electrode over a substrate;
forming an insulating layer between the first pixel electrode and the second pixel electrode;
forming a conductive film over the first pixel electrode, the second pixel electrode, and the insulating layer;
removing a portion of the conductive film overlapping with the first pixel electrode to form a first side surface of the conductive film;
forming a first organic compound layer over the first pixel electrode and the conductive film;
forming a sacrificial layer over the first organic compound layer;
removing a portion of the conductive film overlapping with the second pixel electrode to form a second side surface of the conductive film;
forming a second organic compound layer over the sacrificial layer and the second pixel electrode;
removing the sacrificial layer;
forming a third organic compound layer over the first organic compound layer and the second organic compound layer; and
forming an upper electrode over the third organic compound layer to be in contact with the first side surface and the second side surface.

10. The method for manufacturing a display device according to claim 9,
wherein the first side surface and the second side surface are formed by etching the conductive film by a wet etching method, and
wherein an etching rate of the conductive film is higher in a lower portion than in an upper portion of the conductive film.

11. The method for manufacturing a display device according to claim 9,
wherein the first side surface formed over the insulating layer has an angle greater than or equal to 105° and less than or equal to 175° with respect to a top surface of the insulating layer.

12. The method for manufacturing a display device according to claim 9,
wherein the conductive film comprises indium and oxygen.

13. The method for manufacturing a display device according to claim 9,
wherein force required for separation of a material used for the conductive film from a material used for the insulating layer is lower than 8 N.

14. The method for manufacturing a display device according to claim 9,
wherein the conductive film has a larger thickness than at least one of the first organic compound layer and the second organic compound layer.

15. The method for manufacturing a display device according to claim 9,
wherein the first organic compound layer is formed by a first material traveling with a first angle with respect to a perpendicular direction to a formation surface of the substrate,
wherein the third organic compound layer is formed by a second material traveling with a second angle with respect to the perpendicular direction,
wherein the upper electrode is formed by a third material traveling with a third angle with respect to the perpendicular direction,
wherein the first angle is greater than or equal to 0°,
wherein the second angle is larger than the first angle, and
wherein the third angle is larger than the second angle.
